(19) United States
(12) Patent Application Publication
(10) Pub. No.: US 2025/0311342 A1
(43) Pub. Date: Oct. 2, 2025

(54) SYSTEMS AND METHODS FOR QUANTUM COMPUTING

(71) Applicant: NVISION IMAGING TECHNOLOGIES GMBH, Ulm (DE)

(72) Inventors: Ilai SCHWARTZ, Neu-Ulm (DE); Tobias SCHAUB, Ulm (DE); Tim EICHHORN, Stuttgart (DE)

(73) Assignee: NVISION IMAGING TECHNOLOGIES GMBH, Ulm (DE)

(21) Appl. No.: 18/864,313

(22) PCT Filed: May 11, 2024
(86) PCT No.: PCT/IB2023/054886

§ 371 Date: Nov. 8, 2024

Related U.S. Application Data
(60) Provisional application No. 63/364,540, filed on May 11, 2022.
(60) Provisional application No. 63/379,905, filed on Oct. 18, 2022.

(51) Int. Cl. H10D 62/81; H10D 62/00

(52) U.S. Cl. CPC H10D 62/812; H10D 62/01

(57) ABSTRACT

The present disclosure describes non-classical (e.g., quantum) computing systems and methods that utilize dopant molecules contained in host materials as qubits. The dopant molecules generally comprise ground-state triplet (GST) molecules, such as carbenes or nitrenes. The host materials generally comprise organic molecules. Precursors to the dopant molecules can be embedded in the host materials and then subjected to ultraviolet (UV) or visible light to form dilute molecular crystals comprising the dopant molecules embedded in the host materials. The triplet sub-levels of the dopant molecules may be manipulated using electromagnetic (EM) radiation such as optical, radiofrequency (RF), and/or microwave (MW) radiation to conduct non-classical computing operations.

### CROSS-REFERENCE TO RELATED APPLICATIONS

The present application claims priority to U.S. Provisional Patent Application No. 63/364,540, filed on May 11, 2022, and U.S. Provisional Patent Application No. 63/379,905, filed on Oct. 18, 2022, each of which is incorporated herein by reference in its entirety for all purposes.

### TECHNICAL FIELD

The disclosed embodiments generally relate to non-classical (e.g., quantum) computing systems and methods that utilize dopant molecules contained in host materials as qubits.

### BACKGROUND

Non-classical computers (e.g., quantum computers) typically exploit quantum mechanical phenomena, such as superposition, entanglement, and interference, to perform computational operations on data. In comparison to classical computers, which utilize binary digits (bits) that always have a defined state (0 or 1), non-classical computers utilize quantum bits (qubits) that can exist in a superposition of basis states (i.e., some linear combination of basis state |0> and basis state |1>, where basis states |0> and |1> are orthonormal). Various qubits of the non-classical computer may be entangled with other qubits (i.e., the quantum states of two or more qubits may be correlated such that operations on one qubit affect the state of an entangled qubit). Quantum operations may be performed to direct the states of the qubits to probabilistically converge on a particular final state, which represents the solution to some problem. For certain classes of problems, the non-classical computer may converge to the solution faster than is possible using any known algorithm on a classical computer. In some cases, this “quantum advantage” may allow the non-classical computer to solve problems that would be intractable using any known classical computer. Such problems include the factoring of large relatively prime numbers (e.g., for breaking modern cryptographic hash functions), searching for particular items in large quantities of data, and simulating the chemical behavior of drugs, materials, or other molecules.

### SUMMARY

In some embodiments, the present disclosure describes non-classical (e.g., quantum) computing systems and methods that utilize dopant molecules contained in host materials as qubits.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which comprise a part of this specification, illustrate several embodiments and, together with the description, serve to explain certain principles and features of the disclosed embodiments. In the drawings:

FIG. 1A shows a top view of a system for performing a non-classical computation, in accordance with various embodiments.

FIG. 1B shows a side view of the system of FIG. 1A, in accordance with various embodiments.

FIG. 2 shows an example of an electronic energy level diagram for a ground state triplet (GST) molecule, in accordance with various embodiments.

FIG. 3 shows a system for performing a non-classical computation using the system depicted in FIG. 1A or 1B, in accordance with various embodiments.

FIG. 4 shows a flowchart depicting a method for performing a non-classical computation, in accordance with various embodiments.

FIG. 5 shows a flowchart depicting a method for generating, producing, or constructing a non-classical computer, in accordance with various embodiments.

FIG. 6A shows exemplary continuous wave (cw) EPR signals associated with stepwise photoactivation of di(naphthalen-2-yl) carbene in di(naphthalen-2-yl) methanone at a temperature of 25 K using a green laser, in accordance with various embodiments.

FIG. 6B shows the double integral of the cw EPR signals from FIG. 6A as a function of the applied light energy, in accordance with various embodiments.

FIG. 7A shows exemplary cw EPR signals associated with the conversion of freshly photoactivated di(naphthalen-2-yl) carbene in di(naphthalen-2-yl) methanone to an annealed form at a temperature of 140 K, in accordance with various embodiments.

FIG. 7B shows the double integral of the cw EPR signals from FIG. 7A as a function of the annealing time, in accordance with various embodiments.

FIG. 8A shows an exemplary spin-lattice (T₁) relaxation decay curve for di(naphthalen-2-yl) carbene-d₁₄ in di(naphthalen-2-yl) methanone-d₁₄ at a single temperature, in accordance with various embodiments.

FIG. 8B shows an exemplary plot of the T₁ temperature dependence for di(naphthalen-2-yl) carbene-d₁₄ in di(naphthalen-2-yl) methanone-d₁₄, in accordance with various embodiments.

FIG. 9 shows exemplary spin-spin (T₂) relaxation decay curves for protonated and deuterated dilute molecular crystals of di(naphthalen-2-yl) carbene in di(naphthalen-2-yl) methanone, in accordance with various embodiments.

FIG. 10 shows exemplary double electron-electron resonance (DEER) decay curves for partially and fully activated di(naphthalen-2-yl) carbene-d₁₄ in di(naphthalen-2-yl) methanone-d₁₄, in accordance with various embodiments.

FIG. 11A shows exemplary cw EPR signals associated with stepwise photoactivation of 4-nitrenebenzoic acid in 4-iodobenzoic acid at a temperature of 25 K using light with a wavelength of 370 nm, in accordance with various embodiments.

FIG. 11B shows the double integral of the cw EPR signals from FIG. 11A as a function of the activation time, in accordance with various embodiments.

FIG. 12 shows an exemplary cw EPR signal associated with the conversion of freshly photoactivated 4-nitrenebenzoic acid in 4-iodobenzoic acid to an annealed form at room temperature, in accordance with various embodiments.

### DETAILED DESCRIPTION

Reference will now be made in detail to exemplary embodiments, discussed with regards to the accompanying drawings. Unless otherwise defined, technical and/or scientific terms have the meaning commonly understood by one of ordinary skill in the art. The disclosed embodiments are described in sufficient detail to enable those skilled in the art to practice the disclosed embodiments. It is to be understood that other embodiments may be utilized and that changes may be made without departing from the scope of the disclosed embodiments. Thus, the materials, methods, and examples are illustrative only and are not intended to be necessarily limiting.

As used herein, the term “or” shall convey both disjunctive and conjunctive meanings to the extent that any such meaning is possible. For instance, the phrase “A or B” shall be interpreted to include element A alone, element B alone, and the combination of elements A and B to the extent that such meanings are possible. As another example, the phrase “A, B, or C” shall be interpreted to include element A alone, element B alone, element C alone, the combination of elements A and B but not element C, the combination of elements A and C but not element B, the combination of elements B and C but not element A, and the combination of elements A, B, and C to the extent that such meanings are possible.

In the Figures (also, “FIGS.” or “Figs.”), like numbers refer to like elements.

Non-classical computers (e.g., quantum computers) typically exploit quantum mechanical phenomena, such as superposition, entanglement, and interference, to perform computational operations on data. In comparison to classical computers, which utilize binary digits (bits) that always have a defined state (0 or 1), non-classical computers utilize quantum bits (qubits) that can exist in a superposition of basis states (i.e., some linear combination of basis state |0> and basis state |1>). Various qubits of the non-classical computer may be entangled with other qubits (i.e., the quantum states of two or more qubits may be correlated such that operations on one qubit affect the state of an entangled qubit). Quantum operations may be performed to direct the states of the qubits to probabilistically converge on a solution to some problem. For certain classes of problems, the non-classical computer may converge to the solution faster than is possible using any known algorithm on a classical computer. In some cases, this “quantum advantage” may allow the non-classical computer to solve problems that would be intractable using any known classical computer. Such problems include the factoring of large relatively prime numbers (e.g., for breaking modern cryptographic hash functions), searching for particular items in large quantities of data, and simulating the chemical behaviors of drugs, materials, or other molecules.

Numerous chemical and physical systems have been proposed for use as qubits in non-classical computers. For instance, significant resources have been directed to superconducting qubits utilizing Josephson junctions (i.e., a superconductor-insulator-superconductor transition). Such superconducting qubits utilize the different quantum tunneling modes through the Josephson junction as basis states. These superconducting qubits can be manufactured using well-known semiconductor fabrication techniques, permitting relatively straightforward circuit design. However, superconducting qubits suffer from a number of disadvantages. For instance, the superconducting qubits must generally be cooled to a fraction of a degree above absolute zero, necessitating a complicated cryogenic system. The use of such complicated cryogenics also makes it difficult to entangle more than a few qubits and limits the ultimate computational power of a superconducting qubit-based non-classical computer.

Numerous other systems have been used as qubits, including arrays of trapped ions, arrays of trapped neutral atoms, and chemical defects in solid-state lattices. One system proposed for use in quantum computing is the so-called nitrogen vacancy (NV) center in diamonds. An electron spin associated with an NV center can be optically initialized and its spin state can be read out by fluorescence detection. In addition, the electron spin can be manipulated by microwave (MW) or radio-frequency (RF) irradiation, and can exhibit a relatively long relaxation and coherence time. However, existing NV quantum computers can only support a limited number of qubits before deleterious effects associated with increasing the number of qubits leads to a decrease in the relaxation and coherence times, negating the very properties that make NV quantum computers attractive in the first place. This is due to the fact that the natural abundance of carbon-13 (¹³C) spins in diamond is 1.1%. Increasing the isotopic concentration of ¹³C spins in the diamond leads to worse NV center properties due to an increase in the number of nearby ¹³C spins. Moreover, the random distribution of the ¹³C spins will lead to couplings on a very wide scale, with some ¹³C spins very strongly coupled to the NV centers (e.g., for the case of neighboring ¹³C spins). This can make the NV centers hard to manipulate and control. In addition, as every NV center has a different associated ¹³C spin bath due to the random distribution of the ¹³C spins, NV qubits work almost exclusively with single NV spins, leading to low signal-to-noise ratio (SNR) and requiring non-classical computations to be performed multiple times to achieve a measurable signal. Moreover, it may be difficult to prepare diamonds that are controllably doped with NV centers, as it can be difficult to prepare highly crystalline diamonds with controlled NV doping rates.

Thus, there is a need for qubits based on chemical or physical systems that avoid the problems associated with known qubits. Ideally, such chemical or physical systems should be relatively simple to manufacture, support hundreds or thousands of qubits on a single device, allow each qubit to be manipulated independently from every other qubit, and have a coherence lifetime that is substantially longer than the time required to perform quantum operations on each qubit. Systems consistent with disclosed embodiments can meet some or all of these criteria and therefore provide technical improvements in performing non-classical computations.

As used herein, the terms “non-classical computation,” “non-classical procedure,” “non-classical operation,” and “non-classical computer” generally refer to any system or method for performing computational procedures outside of the paradigm of classical computing. A non-classical computation, non-classic procedure, non-classical operation, or non-classical computer may comprise a quantum computation, quantum procedure, quantum operation, or quantum computer.

As used herein, the terms “quantum computation,” “quantum procedure,” “quantum operation,” and “quantum computer” generally refer to any method or system for performing computations using quantum mechanical operations (such as unitary transformations or completely positive trace-preserving (CPTP) maps on quantum channels) on a Hilbert space represented by a quantum device. As such, quantum and classical (or digital) computation may be similar in the following aspect: both computations may comprise sequences of instructions performed on input information to then provide an output. Various paradigms of quantum computation may break the quantum operations down into sequences of basic quantum operations that affect a subset of qubits of the quantum device simultaneously. The quantum operations may be selected based on, for instance, their locality or their ease of physical implementation. A quantum procedure or computation may then consist of a sequence of such instructions that in various applications may represent different quantum evolutions on the quantum device. For example, procedures to compute or simulate quantum chemistry may represent the quantum states and the annihilation and creation operators of electron spin orbitals by using qubits (such as two-level quantum systems) and a universal quantum gate set (such as the Hadamard, controlled-not (CNOT), and π/8 rotation) through the so-called Jordan-Wigner transformation or Bravyi-Kitaev transformation.

Additional examples of quantum procedures or computations may include procedures for optimization such as quantum approximate optimization algorithm (QAOA) or quantum minimum finding. QAOA may comprise performing rotations of single qubits and entangling gates of multiple qubits. In quantum adiabatic computation, the instructions may carry stochastic or non-stochastic paths of evolution of an initial quantum system to a final one. Quantum-inspired procedures may include simulated annealing, parallel tempering, master equation solver, Monte Carlo procedures, quantum algorithms for approximating maximum independent sets, and the like. Quantum-classical or hybrid algorithms or procedures may comprise such procedures as variational quantum eigensolver (VQE) and the variational and adiabatically navigated quantum eigensolver (VanQver).

In general, examples of quantum procedures or computations may include any procedures or computations described in M. A. Nielsen and I. L. Chuang, Quantum Computation and Quantum Information, Cambridge University Press (2013), which is incorporated herein by reference in its entirety for all purposes.

A quantum computer may comprise one or more adiabatic quantum computers, quantum gate arrays, one-way quantum computers, topological quantum computers, quantum Turing machines, quantum annealers, Ising solvers, or gate models of quantum computing.

### Doped Host Materials as Qubits for Performing Non-Classical Computations

Provided herein are systems and methods for performing non-classical computations. The systems and methods generally utilize dopant molecules contained in organic host materials. The dopant molecules generally function as qubits and are associated with electronic energy level structures that include a triplet electronic manifold. The triplet electronic manifold may comprise a ground state triplet (GST) electronic manifold. The triplet electronic manifold generally comprises three triplet states, which can be linearly combined to form qubit basis states (e.g., with respect to a laboratory frame of reference, a rotating frame of reference, or another suitable time-independent or time-dependent frame of reference). The basis states generally have long lifetimes at the temperatures obtainable using liquid helium-based cryogenic systems. The dopant molecules may be arranged in the host material to permit relatively strong couplings between nearest neighbor dopant molecules, allowing the proliferation of information across the qubit network through entanglement. The quantum states of the various dopant molecules may be individually manipulated using optical, MW, or RF techniques, allowing individual control of each qubit to perform the non-classical computation.

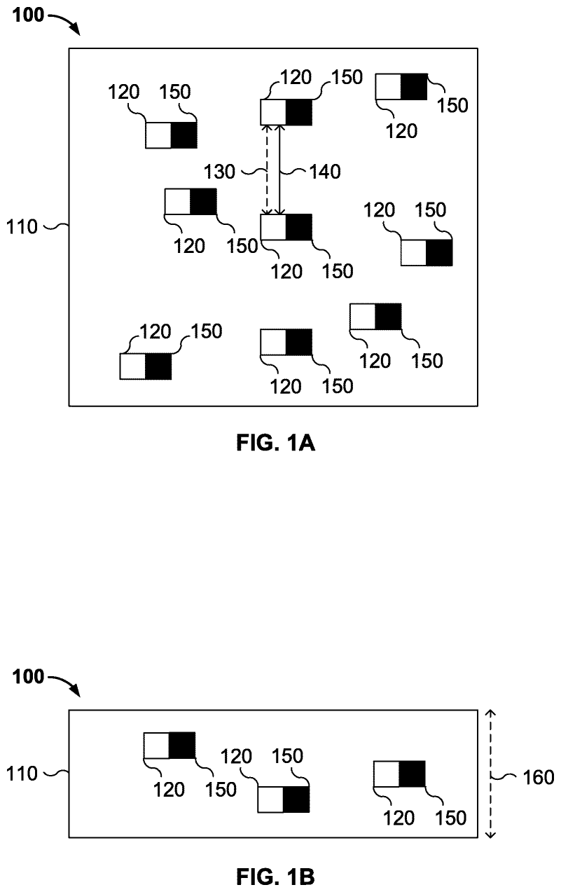

FIG. 1A shows a top view of a system 100 for performing a non-classical computation, in accordance with various embodiments. In the example shown, the system 100 comprises at least one host material 110. In some embodiments, the host material 110 comprises at least one organic molecule. In some embodiments, the host material 110 is referred to herein as a “matrix”

In some embodiments, the host material 110 comprises a crystalline host material. In some embodiments, the host material 110 comprises a single crystalline host material. In some embodiments, the host material 110 comprises a polycrystalline host material. In some embodiments, the host material 110 comprises a liquid crystalline host material. In some embodiments, the host material 110 comprises an amorphous host material. In some embodiments, the host material 110 comprises a powder host material. In some embodiments, the host material 110 comprises a frozen solution host material. In some embodiments, the frozen solution host material comprises a solution that is frozen at cryogenic temperatures. For instance, in some embodiments, the frozen solution host material is frozen at a temperature of at least about 1 Kelvin (K), 2 K, 3 K, 4 K, 5 K, 6 K, 7 K, 8 K, 9 K, 10 K, 15 K, 20 K, 25 K, 30 K, 35 K, 40 K, 45 K, 50 K, or more, at most about 50 K, 45 K, 40 K, 35 K, 30 K, 25 K, 20 K, 15 K, 10 K, 9 K, 8 K, 7 K, 6 K, 5 K, 4 K, 3 K, 2 K, 1 K, or less, or a temperature that is between any two of the preceding values.

In some embodiments, the host material 110 comprises a linear or branched alkane. In some embodiments, the linear or branched alkane comprises a C4-C20 linear or branched alkane. In some embodiments, the linear or branched alkane comprises a C4 linear or branched alkane, a C5 linear or branched alkane, a C6 linear or branched alkane, a C7 linear or branched alkane, a C8 linear or branched alkane, a C9 linear or branched alkane, a C10 linear or branched alkane, a C11 linear or branched alkane, a C12 linear or branched alkane, a C13 linear or branched alkane, a C14 linear or branched alkane, a C15 linear or branched alkane, a C16 linear or branched alkane, a C17 linear or branched alkane, a C18 linear or branched alkane, a C19 linear or branched alkane, or a C20 linear or branched alkane. In some embodiments, the host material 110 comprises an aromatic hydrocarbon. In some embodiments, the host material 110 comprises a polyaromatic hydrocarbon. In some embodiments, the polyaromatic hydrocarbon is optionally substituted with a methylene, nitrile, carbonyl, carboxylate, alkyl, deuterated alkyl, aryl, deuterated aryl, heteroaryl, deuterated heteroaryl, borane, imine, amine, nitro, phosphine, thioether, ether, fluoro, chloro, bromo, iodo, or thiocarbonyl group. In some embodiments, the host material 110 comprises a diarylketone. In some embodiments, the host material 110 comprises octasulfur. In some embodiments, the host material 110 comprises naphthalene, anthracene, para-terphenyl, benzoic acid, fluorene, biphenyl, benzene, n-hexane, biphenylene, ortho-terphenylene, meta-terphenylene, para-terphenylene, di(phenyl) methanone, phenanthrene, or di(napthalen-2-yl) methanone. In some embodiments, the host material 110 comprises any partially or fully isotopically labeled derivative of any of the foregoing.

In some embodiments, the host material 110 is at least partially deuterated. That is, in some embodiments, the host material 110 contains one or more deuterium atoms where hydrogen atoms would otherwise be expected. In some embodiments, the host material 110 contains at least about 1, 2, 3, 4, 5, 6, 7, 8, 9, 10, 11, 12, 13, 14, 15, 16, 17, 18, 19, 20, or more deuterium atoms, at most about 20, 19, 18, 17, 16, 15, 14, 13, 12, 11, 10, 9, 8, 7, 6, 5, 4, 3, 2, or one deuterium atoms, or a number of deuterium atoms that is within a range defined by any two of the preceding values. In some embodiments, the host material 110 is fully deuterated. That is, in some embodiments, the host material 110 contains deuterium atoms at every site where hydrogen atoms would otherwise be expected. In some embodiments, the host material 110 is at least partially labeled with carbon-13. That is, in some embodiments, the host material 110 contains one or more carbon-13 atoms where carbon-12 atoms would otherwise be expected. In some embodiments, the host material 110 contains at least about 1, 2, 3, 4, 5, 6, 7, 8, 9, 10, 11, 12, 13, 14, 15, 16, 17, 18, 19, 20, or more carbon-13 atoms, at most about 20, 19, 18, 17, 16, 15, 14, 13, 12, 11, 10, 9, 8, 7, 6, 5, 4, 3, 2, or one carbon-13 atoms, or a number of carbon-13 atoms that is within a range defined by any two of the preceding values.

In some embodiments, the host material 110 comprises an isotopically enriched host material. In some embodiments, the host material 110 is isotopically enriched with a particular atomic isotope. In some embodiments, the isotope comprises hydrogen (¹H), deuterium (²H), carbon-13 (¹³C), nitrogen-15 (¹⁵N), fluorine-19 (¹⁹F), silicon-29 (²⁹Si), or phosphorous-31 (³¹P). In some embodiments, the host material 110 is isotopically enriched to feature the isotope at an abundance of at least about 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 91%, 92%, 93%, 94%, 95%, 96%, 97%, 98%, 99%, or more, at most about 99%, 98%, 97%, 96%, 95%, 94%, 93%, 92%, 91%, 90%, 85%, 80%, 75%, 70%, 65%, 60%, 55%, 50%, 45%, 40%, 35%, 30%, 25%, 20%, 15%, 10%, 9%, 8%, 7%, 6%, 5%, 4%, 3%, 2%, 1%, or less, or an abundance that is within a range defined by any two of the preceding values. In some embodiments, isotopic enrichment allows improved control over the magnetic environment of the dopant molecules 120 described herein.

In some embodiments, the host material 110 does not include diamond or graphite.

In some embodiments, the host material 110 is configured to contain at least one dopant molecule 120 described herein.

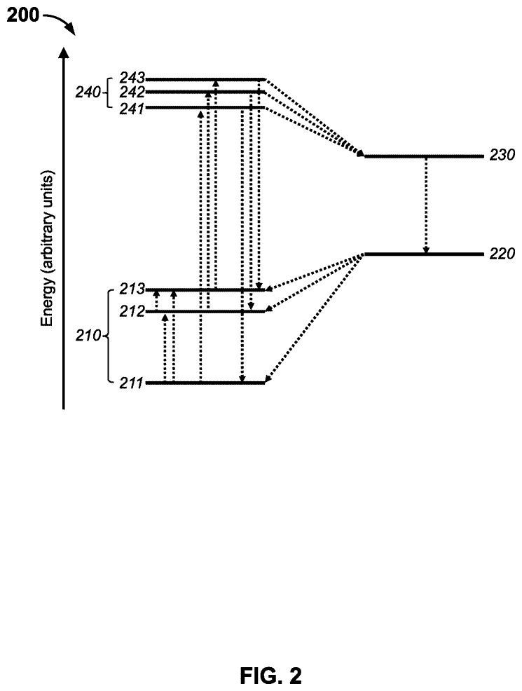

In the example shown, the system 100 comprises a plurality of dopant molecules 120. In some embodiments, the plurality of dopant molecules 120 are contained in the host material 110. In some embodiments, each dopant molecule 120 comprises a qubit for use in performing the non-classical computation. The quantum states of the qubits are described in further detail in FIG. 2.

In some embodiments, each dopant molecule 120 comprises an organic molecule. In some embodiments, each dopant molecule 120 comprises a GST molecule; that is, in some embodiments, each dopant molecule 120 is associated with a GST electronic manifold, as described herein with respect to FIG. 2.

In some embodiments, at least one dopant molecule 120 comprises a carbene molecule. In some embodiments, at least one dopant molecule 120 comprises a nitrene molecule. In some embodiments, at least one dopant molecule 120 comprises a biradical molecule. In some embodiments, at least one dopant molecule 120 comprises a diradical molecule. In some embodiments, at least one dopant molecule 120 comprises a diaryl diazomethane compound, di(naphthalen-2-yl) carbene, or di(phenyl) carbene. In some embodiments, at least one dopant molecule 120 comprises any partially or fully isotopically labeled derivative of any of the foregoing.

In some embodiments, at least one dopant molecule 120 is at least partially deuterated. That is, in some embodiments, at least one dopant molecule 120 contains one or more deuterium atoms where hydrogen atoms would otherwise be expected. In some embodiments, at least one dopant molecule 120 contains at least about 1, 2, 3, 4, 5, 6, 7, 8, 9, 10, 11, 12, 13, 14, 15, 16, 17, 18, 19, 20, or more deuterium atoms, at most about 20, 19, 18, 17, 16, 15, 14, 13, 12, 11, 10, 9, 8, 7, 6, 5, 4, 3, 2, or one deuterium atoms, or a number of deuterium atoms that is within a range defined by any two of the preceding values. In some embodiments, at least one dopant molecule 120 is fully deuterated. That is, in some embodiments, at least one dopant molecule 120 contains deuterium atoms at every site where hydrogen atoms would otherwise be expected. In some embodiments, at least one dopant molecule 120 is at least partially labeled with carbon-13. That is, in some embodiments, at least one dopant molecule 120 contains one or more carbon-13 atoms where carbon-12 atoms would otherwise be expected. In some embodiments, at least one dopant molecule 120 contains at least about 1, 2, 3, 4, 5, 6, 7, 8, 9, 10, 11, 12, 13, 14, 15, 16, 17, 18, 19, 20, or more carbon-13 atoms, at most about 20, 19, 18, 17, 16, 15, 14, 13, 12, 11, 10, 9, 8, 7, 6, 5, 4, 3, 2, or one carbon-13 atoms, or a number of carbon-13 atoms that is within a range defined by any two of the preceding values.

In some embodiments, at least one dopant molecule 120 is coupled to at least one other dopant molecule 120 by a coupling interaction 130. In some embodiments, the at least one dopant molecule 120 is coupled to at least about 1, 2, 3, 4, 5, 6, 7, 8, or more other dopant molecules 120, at most about 8, 7, 6, 5, 4, 3, 2, or 1 other dopant molecules 120, or a number of dopant molecules that is within a range defined by any two of the preceding values, by the coupling interaction 130. For instance, in some embodiments, the at least one dopant molecule 120 is coupled to between about 1 and about 2, between about 1 and about 3, between about 1 and about 4, between about 1 and about 5, between about 1 and about 6, between about 1 and about 7, between about 1 and about 8, between about 2 and about 3, between about 2 and about 4, between about 2 and about 5, between about 2 and about 6, between about 2 and about 7, between about 2 and about 8, between about 3 and about 4, between about 3 and about 5, between about 3 and about 6, between about 3 and about 7, between about 3 and about 8, between about 4 and about 5, between about 4 and about 6, between about 4 and about 7, between about 4 and about 8, between about 5 and about 6, between about 5 and about 7, between about 5 and about 8, between about 6 and about 7, between about 6 and about 8, or between about 7 and about 8 other dopant molecules 120.

In some embodiments, each dopant molecule is coupled to at least one other dopant molecule by the coupling interaction 130. In some embodiments, each dopant molecule 120 is coupled to at least about 1, 2, 3, 4, 5, 6, 7, 8, or more other dopant molecules 120, at most about 8, 7, 6, 5, 4, 3, 2, or 1 other dopant molecules 120, or a number of dopant molecules that is within a range defined by any two of the preceding values, by the coupling interaction 130. For instance, in some embodiments, the each dopant molecule 120 is coupled to between about 1 and about 2, between about 1 and about 3, between about 1 and about 4, between about 1 and about 5, between about 1 and about 6, between about 1 and about 7, between about 1 and about 8, between about 2 and about 3, between about 2 and about 4, between about 2 and about 5, between about 2 and about 6, between about 2 and about 7, between about 2 and about 8, between about 3 and about 4, between about 3 and about 5, between about 3 and about 6, between about 3 and about 7, between about 3 and about 8, between about 4 and about 5, between about 4 and about 6, between about 4 and about 7, between about 4 and about 8, between about 5 and about 6, between about 5 and about 7, between about 5 and about 8, between about 6 and about 7, between about 6 and about 8, or between about 7 and about 8 other dopant molecules 120. In some embodiments, the set of dopant molecules 120 to which each dopant molecule 120 is coupled is referred to as its “nearest neighbors.”

In some embodiments, the coupling interaction 130 comprises an electronic coupling interaction. In some embodiments, the coupling interaction 130 comprises an electronic dipolar coupling interaction. In some embodiments, the coupling interaction 130 comprises a magnetic coupling interaction. In some embodiments, the coupling interaction 130 has a coupling strength. In some embodiments, the coupling strength is at least about 100 Hertz (Hz), 200 Hz, 300 Hz, 400 Hz, 500 Hz, 600 Hz, 700 Hz, 800 Hz, 900 Hz, 1 kilohertz (kHz), 2 kHz, 3 kHz, 4 kHz, 5 kHz, 6 kHz, 7 kHz, 8 kHz, 9 kHz, 10 kHz, 20 kHz, 30 kHz, 40 kHz, 50 kHz, 60 kHz, 70 kHz, 80 kHz, 90 kHz, 100 kHz, 200 kHz, 300 kHz, 400 kHz, 500 kHz, 600 kHz, 700 kHz, 800 kHz, 900 kHz, 1 megahertz (MHz), 2 MHZ, 3 MHz, 4 MHZ, 5 MHZ, 6 MHZ, 7 MHz, 8 MHz, 9 MHz, 10 MHz, or more, at most about 10 MHz, 9 MHz, 8 MHz, 7 MHz, 6 MHz, 5 MHz, 4 MHZ, 3 MHz, 2 MHz, 1 MHz, 900 kHz, 800 kHz, 700 kHz, 600 kHz, 500 kHz, 400 kHz, 300 kHz, 200 kHz, 100 kHz, 90 kHz, 80 kHz, 70 kHz, 60 kHz, 50 kHz, 40 kHz, 30 kHz, 20 kHz, 10 kHz, 9 kHz, 8 kHz, 7 kHz, 6 kHz, 5 kHz, 4 kHz, 3 kHz, 2 kHz, 1 kHz, 900 Hz, 800 Hz, 700 Hz, 600 Hz, 500 Hz, 400 Hz, 300 Hz, 200 Hz, 100 Hz, or less, or within a range defined by any two of the preceding values. For instance, in some embodiments, the coupling strength is between about 100 Hz and about 1,000 kHz, about 100 Hz and about 100 kHz, about 100 Hz and about 10 kHz, about 100 Hz and about 1 kHz, about 1 kHz and about 1,000 kHz, about 1 kHz and about 100 kHz, about 1 kHz and about 10 kHz, about 10 kHz and about 1,000 kHz, about 10 kHz and about 100 kHz, or about 100 kHz and about 1,000 kHz. In some embodiments, the coupling interaction 130 between each pair of dopant molecules 120 is the same. In some embodiments, the coupling interaction 130 between each pair of dopant molecules 120 is different.

In some embodiments, the plurality of dopant molecules 120 are separated by an average distance 140. In some embodiments, the average distance 140 is at least about 0.3 nanometers (nm), 0.4 nm, 0.5 nm, 0.6 nm, 0.7 nm, 0.8 nm, 0.9 nm, 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, or more, at most about 20 nm, 19 nm, 18 nm, 17 nm, 16 nm, 15 nm, 14 nm, 13 nm, 12 nm, 11 nm, 10 nm, 9 nm, 8 nm, 7 nm, 6 nm, 5 nm, 4 nm, 3 nm, 2 nm, 1 nm, 0.9 nm, 0.8 nm, 0.7 nm, 0.6 nm, 0.5 nm, 0.4 nm, 0.3 nm, or less, or within a range defined by any two of the preceding values. For instance, in some embodiments, the average distance 140 is between about 0.3 nm and about 1 nm, about 0.3 nm and about 10 nm, or about 1 nm and about 10 nm.

In some embodiments, the plurality of dopant molecules 120 are contained in the host material 110 at a concentration of at least about 1×10⁶ dopant molecules per cubic micrometer (μm⁻³), 2×10⁶ μm⁻³, 3×10⁶ μm⁻³, 4×10⁶ μm⁻³, 5×10⁶ μm⁻³, 6×10⁶ μm⁻³, 7×10⁶ μm⁻³, 8×10⁶ μm⁻³, 9×10⁶ μm⁻³, 1×10⁷ μm⁻³, 2×10⁷ μm⁻³, 3×10⁷ μm⁻³, 4×10⁷ μm⁻³, 5×10⁷ μm⁻³, 6×10⁷ μm⁻³, 7×10⁷ μm⁻³, 8×10⁷ μm⁻³, 9×10⁷ μm⁻³, 1×10⁸ μm⁻³, 2×10⁸ μm⁻³, 3×10⁸ μm⁻³, 4×10⁸ μm⁻³, 5×10⁸ μm 3, 6×10⁸ μm⁻³, 7×10⁸ μm 3, 8×10⁸ μm⁻³, 9×10⁸ μm⁻³, 1×10⁹ μm 3, 2×10⁹ μm⁻³, 3×10⁹ μm⁻³, 4×10⁹ μm⁻³, 5×10⁹ μm⁻³, 6×10⁹ μm⁻³, 7×10⁹ μm⁻³, 8×10⁹ μm 3, 9×10⁹ μm⁻³, 1×10¹⁰ μm⁻³, 2×10¹⁰ μm⁻³, 3×10¹⁰ μm⁻³, 4×10¹⁰ μm⁻³, 5×10¹⁰ μm⁻³, 6×10¹⁰ μm⁻³, 7×10¹⁰ μm⁻³, 8×10¹⁰ μm⁻³, 9×10¹⁰ μm⁻³, 1×10¹¹ μm⁻³, 2×10¹¹ μm⁻³,3×10¹¹ μm⁻³, 4×10¹¹ μm⁻³, 5×10¹¹ μm⁻³, 6×10¹¹ μm⁻³, 7×10¹¹ μm⁻³, 8×10¹¹ μm⁻³, 9×10¹¹ μm⁻³, 1×10¹² μm⁻³, or more, at most about 1×10¹² μm⁻³, 9×10¹¹ μm⁻³, 8×10¹¹ μm⁻³, 7×10¹¹ μm⁻³, 6×10¹¹ μm⁻³, 5×10¹¹ μm⁻³, 4×10¹¹ μm⁻³, 3×10¹¹ μm⁻³, 2×10¹¹ μm⁻³, 1×10¹¹ μm⁻³, 9×10¹⁰ μm⁻³, 8×10¹⁰ μm⁻³, 7×10¹⁰ μm⁻³, 6×10¹⁰ μm⁻³, 5×10¹⁰ μm⁻³, 4×10¹⁰ μm⁻³, 3×10¹⁰ μm⁻³, 2×10¹⁰ μm⁻³, 1×10¹⁰ μm⁻³, 9×10⁹ μm⁻³, 8×10⁹ μm 3, 7×10⁹ μm 3, 6×10⁹ μm⁻³, 5×10⁹ μm⁻³, 4×10⁹ μm⁻³, 3×10⁹ μm⁻³, 2×10⁹ μm⁻³, 1×10⁹ μm⁻³, 9×10⁸ μm⁻³, 8×10⁸ μm⁻³, 7×10⁸ μm⁻³, 6×10⁸ μm⁻³, 5×10⁸ μm⁻³, 4×10⁸ μm 3, 3×10⁸ μm⁻³, 2×10⁸ μm⁻³, 1×10⁸ μm⁻³, 9×10⁷ μm⁻³, 8×10⁷ μm⁻³, 7×10⁷ μm⁻³, 6×10⁷ μm⁻³, 5×10⁷ μm⁻³, 4×10⁷ μm⁻³, 3×10⁷ μm⁻³, 2×10⁷ μm⁻³, 1×10⁷ μm⁻³, 9×10⁶ μm⁻³, 8×10⁶ μm⁻³, 7×10⁶ μm⁻³, 6×10⁶ μm⁻³, 5×10⁶ μm⁻³, 4×10⁶ μm⁻³, 3×10⁶ μm⁻³, 2×10⁶ μm⁻³, 1×10⁶ μm⁻³, or less, or a concentration that is within a range defined by any two of the preceding values.

Although depicted as comprising 9 dopant molecules 120 in FIG. 1A, the system 100 may comprise any number of dopant molecules 120. For instance, the system 100 may comprise at least about 1, 2, 3, 4, 5, 6, 7, 8, 9, 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, 20,000, 30,000, 40,000, 50,000, 60,000, 70,000, 80,000, 90,000, 100,000, 200,000, 300,000, 400,000, 500,000, 600,000, 7000,000, 800,000, 900,000, 1,000,000, or more dopant molecules 120, at most about 1,000,000, 900,000, 800,000, 700,000, 600,000, 500,000, 400,000, 300,000, 200,000, 100,000, 90,000, 80,000, 70,000, 60,000, 50,000, 40,000, 30,000, 20,000, 10,000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, 9, 8, 7, 6, 5, 4, 3, 2, or 1 dopant molecules 120, or a number of dopant molecules 120 that is within a range defined by any two of the preceding values.

Although FIG. 1A depicts the dopant molecules 120 arranged in an array, this depiction is not intended to be limiting. In some embodiments, each of the dopant molecules 120 can have any number of nearest neighbors described herein. In some embodiments, different dopant molecules 120 can have a different number of nearest neighbors. For example, one dopant molecule 120 can have 8 nearest neighbors and another dopant molecule 120 can have 2 nearest neighbors. In some embodiments, the dopant molecules 120 are arranged in a regular, irregular, or disordered array. In some embodiments, the spatial arrangements of nearest neighbors around each of the dopant molecules 120 differs. In some embodiments, separations between each nearest neighbor and each of the dopant molecules 120 differs.

In some embodiments, the dopant molecules 120 are generated by cleaving (e.g., by photolyzing) at least one precursor to at least one of the dopant molecules 120. In some embodiments, the at least one precursor comprises at least one cleavable moiety. In some embodiments, the at least one cleavable moiety comprises at least one photocleavable moiety. In some embodiments, the at least one photocleavable moiety comprises at least one diazo moiety. In some embodiments, the precursor comprises a derivative of a carbene molecule. In some embodiments, the precursor comprises a diazo derivative of a carbene molecule or any partially or fully isotopically labeled derivative thereof.

In some embodiments, the precursor comprises a diazo derivative of a diarylcarbene. In some embodiments, the precursor comprises (diazomethylene)dinaphthalene, (diazomethylene)dibenzene, or any partially or fully isotopically labeled derivative thereof.

In some embodiments, the at least one photocleavable moiety comprises at least one azido moiety, at least one isocyanato moiety, or at least one iminoiodinane moiety. In some embodiments, the precursor comprises an azido derivative of a nitrene molecule, an isocyanato derivative of a nitrene molecule, or an iminoiodinane derivative of a nitrene molecule, or any partially or fully isotopically labeled derivative thereof.

In some embodiments, the precursor comprises 4-azidobenzoic acid or any partially or fully isotopically labeled derivative thereof.

In some embodiments, the precursor is at least partially deuterated. That is, in some embodiments, the precursor contains one or more deuterium atoms where hydrogen atoms would otherwise be expected. In some embodiments, the precursor contains at least about 1, 2, 3, 4, 5, 6, 7, 8, 9, 10, 11, 12, 13, 14, 15, 16, 17, 18, 19, 20, or more deuterium atoms, at most about 20, 19, 18, 17, 16, 15, 14, 13, 12, 11, 10, 9, 8, 7, 6, 5, 4, 3, 2, or one deuterium atoms, or a number of deuterium atoms that is within a range defined by any two of the preceding values. In some embodiments, the precursor is fully deuterated. That is, in some embodiments, the precursor contains deuterium atoms at every site where hydrogen atoms would otherwise be expected. In some embodiments, the precursor is at least partially labeled with carbon-13. That is, in some embodiments, the precursor contains one or more carbon-13 atoms where carbon-13 atoms would otherwise be expected. In some embodiments, the precursor contains at least about 1, 2, 3, 4, 5, 6, 7, 8, 9, 10, 11, 12, 13, 14, 15, 16, 17, 18, 19, 20, or more carbon-13 atoms, at most about 20, 19, 18, 17, 16, 15, 14, 13, 12, 11, 10, 9, 8, 7, 6, 5, 4, 3, 2, or one carbon-13 atoms, or a number of carbon-13 atoms that is within a range defined by any two of the preceding values.

In some embodiments, the at least one photocleavable moiety is susceptible to cleavage from the at least one precursor when exposed to cleavage (e.g., photolysis) light. In some embodiments, the cleavage light has a central wavelength of at least about 200 nanometers (nm), 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 410 nm, 420 nm, 430 nm, 440 nm, 450 nm, 460 nm, 470 nm, 480 nm, 490 nm, 500 nm, or more. In some embodiments, the cleavage light has a central wavelength of at most about 500 nm, 490 nm, 480 nm, 470 nm, 460 nm, 450 nm, 440 nm, 430 nm, 420 nm, 410 nm, 400 nm, 390 nm, 380 nm, 370 nm, 360 nm, 350 nm, 340 nm, 330 nm, 320 nm, 310 nm, 300 nm, 290 nm, 280 nm, 270 nm, 260 nm, 250 nm, 240 nm, 230 nm, 220 nm, 210 nm, 200 nm, or less. In some embodiments, the cleavage light has a central wavelength that is within a range defined by any two of the preceding values, such as between about 300 nm and about 500 nm, about 300 nm and about 400 nm, or about 350 nm and about 400 nm.

Thus, in some embodiments, the system 100 comprises at least one cleaved molecule 150. In the example shown, the system 100 comprises a plurality of cleaved molecules 150. In some embodiments, the at least one cleaved molecule 150 comprises at least one nitrogen molecule, at least one carbon monoxide molecule, or at least one aryl iodide molecule. In some embodiments, the at least one cleaved molecule 150 acts to increase a stability of the at least one dopant molecule 120. For instance, in some embodiments, the at least one cleaved molecule 150 increases the stability of the at least one dopant molecule 120 by being kinetically trapped in close vicinity to the otherwise reactive dopant molecule 120. In some embodiments, the at least one cleaved molecule 150 increases the stability of the at least one dopant molecule 120 by reducing chemical interactions between the at least one dopant molecule 120 and the host material 110.

FIG. 1B shows a side view of the system 100, in accordance with various embodiments. In the example shown, the system 100 comprises the at least one host material 110 and the plurality of dopant molecules 120.

In the example shown, the host material 110 comprises a thickness 160. In some embodiments, the host material 110 comprises a thin film. That is, in some embodiments, the thickness 160 is at least about 0.3 nm, 0.4 nm, 0.5 nm, 0.6 nm, 0.7 nm, 0.8 nm, 0.9 nm, 1 nm, 2 nm, 3 nm, 4 nm, 5 nm, 6 nm, 7 nm, 8 nm, 9 nm, 10 nm, 20 nm, 30 nm, 40 nm, 50 nm, 60 nm, 70 nm, 80 nm, 90 nm, 100 nm, 200 nm, 300 nm, 400 nm, 500 nm, 600 nm, 700 nm, 800 nm, 900 nm, 1,000 nm, or more, at most about 1,000 nm, 900 nm, 800 nm, 700 nm, 600 nm, 500 nm, 400 nm, 300 nm, 200 nm, 100 nm, 90 nm, 80 nm, 70 nm, 60 nm, 50 nm, 40 nm, 30 nm, 20 nm, 10 nm, 9 nm, 8 nm, 7 nm, 6 nm, 5 nm, 4 nm, 3 nm, 2 nm, 1 nm, 0.9 nm, 0.8 nm, 0.7 nm, 0.6 nm, 0.5 nm, 0.4 nm, 0.3 nm, or less, or within a range defined by any two of the preceding values. For instance, in some embodiments, the thickness 160 is between about 0.3 nm and about 1 nm, about 0.3 nm and about 10 nm, about 0.3 nm and about 100 nm, about 0.3 nm and about 1,000 nm, about 1 nm and about 10 nm, about 1 nm and about 10 nm, about 1 nm and about 100 nm, about 1 nm and about 1,000 nm, about 10 nm and about 100 nm, about 10 nm and about 1,000 nm, or about 100 nm and about 1,000 nm. In some embodiments, the use of a thin film host material 110 allows the formation of a pseudo-two-dimensional (pseudo-2D) layer of dopant molecules 120, as described herein.

In some embodiments, the thin film is formed atop a substrate (not shown in FIG. 1B). In some embodiments, the substrate comprises the host material 110. In some embodiments, the substrate comprises a microfabrication processing material such as silicon, glass, or sapphire. In some embodiments, the thin film is formed using one or more microfabrication techniques such as wet cleaning, Piranha cleaning, RCA cleaning, surface passivation, spin coating, dip coating, chemical vapor deposition (CVD), atmospheric pressure CVD, low-pressure CVD, ultrahigh vacuum CVD, aerosol assisted CVD, direct liquid injection CVD, hot wall CVD, cold wall CVD, microwave plasma-assisted CVD, plasma-enhanced CVD (PECVD), remote PECVD, low-energy PECVD, atomic-layer CVD, combustion CVD, rapid thermal CVD, photo-initiated CVD, laser CVD, vapor phase epitaxy, physical vapor deposition, sputter deposition, evaporative deposition, pulsed laser deposition, pulsed electron deposition, atomic layer deposition, molecular beam epitaxy, etching, wet etching, dry etching, reactive-ion etching (RIE), deep RIE, atomic layer etching, or self-assembly (to form a self-assembled monolayer).

In some embodiments, the host material 110 has a thickness 160 of at least about 1 nm, 2 nm, 3 nm, 4 nm, 5 nm, 6 nm, 7 nm, 8 nm, 9 nm, 10 nm, 20 nm, 30 nm, 40 nm, 50 nm, 60 nm, 70 nm, 80 nm, 90 nm, 100 nm, 200 nm, 300 nm, 400 nm, 500 nm, 600 nm, 700 nm, 800 nm, 900 nm, 1 micrometer (μm), 2 μm, 3 μm, 4 μm, 5 μm, 6 μm, 7 μm, 8 μm, 9 μm, 10 μm, 20 μm, 30 μm, 40 μm, 50 μm, 60 μm, 70 μm, 80 μm, 90 μm, 100 μm, 200 μm, 300 μm, 400 μm, 500 μm, 600 μm, 700 μm, 800 μm, 900 μm, 1 millimeter (mm), 2 mm, 3 mm, 4 mm, 5 mm, 6 mm, 7 mm, 8 mm, 9 mm, 10 mm, or more, at most about 10 mm, 9 mm, 8 mm, 7 mm, 6 mm, 5 mm, 4 mm, 3 mm, 2 mm, 1 mm, 900 μm, 800 μm, 700 μm, 600 μm, 500 μm, 400 μm, 300 μm, 200 μm, 100 μm, 90 μm, 80 μm, 70 μm, 60 μm, 50 μm, 40 μm, 30 μm, 20 μm, 10 μm, 9 μm, 8 μm, 7 μm, 6 μm, 5 μm, 4 μm, 3 μm, 2 μm, 1 μm, 900 nm, 800 nm, 700 nm, 600 nm, 500 nm, 400 nm, 300 nm, 200 nm, 100 nm, 90 nm, 80 nm, 70 nm, 60 nm, 50 nm, 40 nm, 30 nm, 20 nm, 10 nm, 9 nm, 8 nm, 7 nm, 6 nm, 5 nm, 4 nm, 3 nm, 2 nm, 1 nm, or less, or within a range defined by any two of the preceding values. In some embodiments, the host material 110 is not formed on a substrate.

In the example shown, the plurality of dopant molecules 120 are arranged in a pseudo-2D layer. In some embodiments, the pseudo-2D layer comprises a thin slice of space to which the plurality of dopant molecules 120 are confined. In some embodiments, vectors can be drawn between pairs of dopant molecules 120 in the pseudo-2D layer. In some embodiments, the vectors make angles with a plane defined by the host material 110. In some embodiments, the angles are at least about 0 degrees, 1 degree, 2 degrees, 3 degrees, 4 degrees, 5 degrees, 6 degrees, 7 degrees, 8 degrees, 9 degrees, 10 degrees, 15 degrees, 20 degrees, 25 degrees, 30 degrees, 35 degrees, 40 degrees, 45 degrees, 50 degrees, 55 degrees, 60 degrees, 65 degrees, 70 degrees, 75 degrees, 80 degrees, 85 degrees, or 90 degrees, at most about 90 degrees, 85 degrees, 80 degrees, 75 degrees, 70 degrees, 65 degrees, 60 degrees, 55 degrees, 50 degrees, 45 degrees, 40 degrees, 35 degrees, 30 degrees, 25 degrees, 20 degrees, 15 degrees, 10 degrees, 9 degrees, 8 degrees, 7 degrees, 6 degrees, 5 degrees, 4 degrees, 3 degrees, 2 degrees, 1 degrees, or 0 degrees, or within a range defined by any two of the preceding values. In some embodiments, the pseudo-2D layer comprises a self-assembled monolayer (SAM). In some embodiments, arranging the plurality of dopant molecules 120 in the pseudo-2D layer reduces the extent to which each of the plurality of dopant molecules 120 must interact with the nearest neighbors located substantially above or below them, simplifying the quantum dynamics of the plurality of dopant molecules 120.

While FIG. 1B depicts a pseudo-2D layer comprising a thin slice of space to which the plurality of dopant molecules 120 are confined, the disclosed embodiments are not so limited. In some embodiments, the plurality of dopant molecules 120 can be disposed within a thicker layer. In such a thicker layer, each of the plurality of dopant molecules 120 may interact with the nearest neighbors located substantially above or below them.

### Electronic Triplet States for Use as Qubit Basis States

FIG. 2 shows an example of an electronic energy level diagram 200 for a GST molecule. In some embodiments, the GST molecule is used as a qubit (e.g., a qubit as described herein with respect to FIGS. 1A and 1B). In the example shown, the GST molecule is associated with a GST electronic manifold 210, a first singlet electronic state 220, a second singlet electronic state 230, and an excited state triplet (EST) electronic manifold 240. In some embodiments, the GST electronic manifold 210 comprises a first triplet state 211, a second triplet state 212, and a third triplet state 213. In some embodiments, the first triplet state 211, second triplet state 212, and third triplet state 213 represent the lowest-energy electronic states of the GST molecule. In some embodiments, the first triplet state 211 is denoted by |T₁ [symbol] , the second triplet state 212 is denoted by |T₂ [symbol] , and the third triplet state 213 is denoted by |T₃ [symbol] . In some embodiments, the EST electronic manifold 240 comprises a first triplet state 241, a second triplet state 242, and a third triplet state 243. In some embodiments, the first singlet electronic state 220, second singlet electronic state 230, and EST electronic manifold 240 each represent higher-energy electronic states than the GST molecule. As depicted in FIG. 2, in some embodiments, the second singlet electronic state 230 is lower in energy than the EST electronic manifold 240. However, in other embodiments, the second singlet electronic state 230 is higher in energy than the EST electronic manifold 240.

In some embodiments, at thermal equilibrium, the GST electronic state 210 is highly populated (i.e., the electronic wavefunction of the GST molecule is heavily biased to the GST electronic state 210, with relatively equal contributions to the first triplet state 211, second triplet state 212, and third triplet state 213), while the first singlet electronic state 220, second electronic singlet state 230, first triplet state 241, second triplet state 242, and third triplet state 243 are not highly populated.

In some embodiments, the GST molecule is configured to absorb electromagnetic energy to drive the population from the first triplet state 211, second triplet state 212, or third triplet state 213 to the first singlet electronic state 220, second singlet electronic state 230, first triplet state 241, second triplet state 242, or third triplet state 243. In some embodiments, the GST molecule is configured to relax via radiative decay back to the first triplet state 211, second triplet state 212, or third triplet state 213; or to the first singlet electronic state 220 or second singlet electronic state 230 via inter-system crossing (ISC). In some embodiments, continuous absorption of the electromagnetic energy selectively drives population into any combination of the first triplet state 211, second triplet state 212, and third triplet state 213, thereby creating a non-equilibrium electronic state distribution. In this manner, any combination of the first triplet state 211, second triplet state 212, and third triplet state 213 may be “hyperpolarized,” as described herein.

In some embodiments, linear combinations of the first triplet state, |T₁ [symbol] second triplet state |T₂ [symbol] , and third triplet state |T₃ [symbol] may be utilized as qubit basis states for the non-classical computation. Thus, the qubit may comprise a first qubit basis state that is a first linear combination (e.g., with respect to a laboratory frame of reference, a rotating frame of reference, or another suitable time-independent or time-dependent frame of reference) of the first triplet state |T₁ [symbol] , second triplet state |T₂ [symbol] , and third triplet state |T₃ [symbol] (e.g., first qubit basis state |0 [symbol] =α₁|T₁ [symbol] +α₂|T₂ [symbol] +α₃|T₃ [symbol] ) and a second qubit basis state that is a second linear combination of first triplet state |T₁ [symbol] , second triplet state |T₂ [symbol] , and third triplet state |T₃ [symbol] (e.g., second qubit basis state |1 [symbol] =β₁|T₁ [symbol] +β₂|T₂ [symbol] +β₃|T₃ [symbol] ). In general, α₁, α₂, α₃, β₁, β₂, and β₃ may each be any complex number, subject to the normalization conditions |α₁|²+|α₂|²+|α₃|²=1 and |β₁|²+|β₂|²+|β₃|²=1. Moreover, α₁, α₂, α₃, β₁, β₂, and β₃ should generally be chosen to make the first qubit basis state and the second qubit basis state different (e.g., orthogonal) from one another.

In some embodiments, a lifetime (e.g., a coherence lifetime or a relaxation lifetime) of the first qubit basis state or the second qubit basis state is at least about 100 microseconds (μs), 200 μs, 300 μs, 400 μs, 500 μs, 600 μs, 700 μs, 800 μs, 900 μs, 1 millisecond (ms), 2 ms, 3 ms, 4 ms, 5 ms, 6 ms, 7 ms, 8 ms, 9 ms, 10 ms, 15 ms, 20 ms, 25 ms, 30 ms, 35 ms, 40 ms, 45 ms, 50 ms, 55 ms, 60 ms, 65 ms, 70 ms, 75 ms, 80 ms, 85 ms, 90 ms, 95 ms, 100 ms, 125 ms, 150 ms, 175 ms, 200 ms, 225 ms, 250 ms, 275 ms, 300 ms, 325 ms, 350 ms, 375 ms, 400 ms, 425 ms, 450 ms, 475 ms, 500 ms, 525 ms, 550 ms, 575 ms, 600 ms, 625 ms, 650 ms, 675 ms, 700 ms, 725 ms, 800 ms, 825 ms, 850 ms, 875 ms, 900 ms, 925 ms, 950 ms, 975 ms, 1 second(s), 2 s, 3 s, 4 s, 5 s, 6 s, 7 s, 8 s, 9 s, 10 s, 20 s, 30 s, 40 s, 50 s, 1 minute (min), 2 min, 3 min, 4 min, 5 min, 6 min, 7 min, 8 min, 9 min, 10 min, 20 min, 30 min, 40 min, 50 min, 1 hour (h), 2 h, 3 h, 4 h, 5 h, 6 h, 7 h, 8 h, 9 h, 10 h, or more, at most about 10 h, 9 h, 8 h, 7 h, 6 h, 5 h, 4 h, 3 h, 2 h, 1 h, 50 min, 40 min, 30 min, 20 min, 10 min, 9 min, 8 min, 7 min, 6 min, 5 min, 4 min, 3 min, 2 min, 1 min, 50 s, 40 s, 30 s, 20 s, 10 s, 9 s, 8 s, 7 s, 6 s, 5 s, 4 s, 3 s, 2 s, 1 s, 975 ms, 950 ms, 925 ms, 900 ms, 875 ms, 850 ms, 825 ms, 800 ms, 775 ms, 750 ms, 725 ms, 700 ms, 675 ms, 650 ms, 625 ms, 600 ms, 575 ms, 550 ms, 525 ms, 500 ms, 475 ms, 450 ms, 425 ms, 400 ms, 375 ms, 350 ms, 325 ms, 300 ms, 275 ms, 250 ms, 225 ms, 200 ms, 175 ms, 150 ms, 125 ms, 100 ms, 95 ms, 90 ms, 85 ms, 80 ms, 75 ms, 70 ms, 65 ms, 60 ms, 55 ms, 50 ms, 45 ms, 40 ms, 35 ms, 30 ms, 25 ms, 20 ms, 15 ms, 10 ms, 9 ms, 8 ms, 7 ms, 6 ms, 5 ms, 4 ms, 3 ms, 2 ms, 1 ms, 900 μs, 800 μs, 700 μs, 600 μs, 500 μs, 400 μs, 300 μs, 200 μs, 100 μs, or less, or a lifetime that is within a range defined by any two of the preceding values.

In some embodiments, the lifetime is defined as the half-life for the electronic state of the qubit to return from a hyperpolarized electronic state distribution to a thermal equilibrium electronic state distribution. In some embodiments, the lifetime is measured at an intended operating temperature of the qubit, such as a temperature of at least about 1 K, 2 K, 3 K, 4 K, 5 K, 6 K, 7 K, 8 K, 9 K, 10 K, 15 K, 20 K, 25 K, 30 K, 35 K, 40 K, 45 K, 50 K, or more, at most about 50 K, 45 K, 40 K, 35 K, 30 K, 25 K, 20 K, 15 K, 10 K, 9 K, 8 K, 7 K, 6 K, 5 K, 4 K, 3 K, 2 K, 1 K, or less, or a temperature that is between any two of the preceding values (such as between about 4 K and about 20 K). In some embodiments, the coupling strength described herein with respect to FIGS. 1A and 1B (e.g., the coupling interaction 130 depicted in FIGS. 1A and 1B) is greater than a multiple of an inverse of the lifetime. In some embodiments, the multiple is at least about 1, 2, 3, 4, 5, 6, 7, 8, 9, 10, or more, at most about 10, 9, 8, 7, 6, 5, 4, 3, 2, 1, or less, or within a range defined by any two of the preceding values.

### Optical Hyperpolarization and Initialization of Qubit States

In some embodiments, hyperpolarization allows the non-classical computation to be performed with a high signal-to-noise ratio (SNR). In some embodiments, hyperpolarization allows the qubit to be initialized in the first qubit basis state or the second qubit basis state (or any linear combination thereof) to thereby initialize the non-classical computation. In some embodiments, hyperpolarization permits coherent manipulation of the quantum state of the qubit to perform the non-classical computation.

In some embodiments, hyperpolarization allows one or a plurality of the qubits to be placed into a particular quantum state (e.g., the first qubit basis state, the second qubit basis state, or any linear combination thereof). In some embodiments, the qubits are initialized following such hyperpolarization.

In the context of a GST molecule, in some embodiments, hyperpolarization describes a condition in which an absolute value of a difference between a population of electronic states being in one state (e.g., the first singlet electronic state of a GST molecule) and a population of electronic states being in another state (e.g., any combination of the first triplet state |T₁ [symbol] , second triplet state |T₂ [symbol] , and third triplet state |T₃ [symbol] of a GST molecule) exceeds the absolute value of the corresponding difference at thermal equilibrium.

In some embodiments, a population difference between two electronic states is the difference between the population of the two electronic states divided by the total population of the two electronic states. A population difference may be expressed as a fractional population difference or a percentage population difference. In some embodiments, the population difference (expressed as a percentage) is at least about 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 95%, or more, at most about 95%, 90%, 85%, 80%, 75%, 70%, 65%, 60%, 55%, 50%, 45%, 40%, 35%, 30%, 25%, 20%, 15%, 10%, 9%, 8%, 7%, 6%, 5%, 4%, 3%, 2%, 1%, or less, or within a range defined by any two of the preceding values.

As described herein, in some embodiments, the qubit is configured to absorb electromagnetic energy to drive population into any combination of the first triplet state |T₁ [symbol] , second triplet state |T₂ [symbol] , and third triplet state |T₃ [symbol] , thereby creating hyperpolarization. In some embodiments, the electromagnetic energy has a central wavelength that is selected to drive the population to any combination of the first triplet state |T₁ [symbol] , second triplet state |T₂ [symbol] , and third triplet state |T₃ [symbol] . In some embodiments, the central wavelength is within an infrared (IR), visible, or ultraviolet (UV) portion of the electromagnetic spectrum. In some embodiments, the central wavelength is at least about 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 685 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more, at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, 390 nm, 380 nm, 370 nm, 360 nm, 350 nm, 340 nm, 330 nm, 320 nm, 310 nm, 300 nm, 290 nm, 280 nm, 270 nm, 260 nm, 250 nm, 240 nm, 230 nm, 220 nm, 210 nm, 200 nm, or less, or within a range defined by any two of the preceding values.

### Optical Initialization of Individual Qubits

Returning to the discussion of FIGS. 1A and 1B, in some embodiments, different dopant molecules 120 experience different physico-chemical environments due to their differing positions or orientations in the host material 110. In some embodiments, the different physico-chemical environments cause the different dopant molecules 120 to have slightly different electronic energy level structures. For instance, returning to the discussion of FIG. 2, the energy differences between any two of the first triplet state 211, second triplet state 212, third triplet state 213, first singlet electronic state 220, second singlet state 230, first triplet state 241, second triplet state 242, and third triplet state 243 may be dependent upon the physico-chemical environment of the associated dopant molecule, shifting the wavelength or frequency of the electromagnetic energy required to drive transitions between those two states.

Returning to the discussion of FIGS. 1A and 1B, in some embodiments, the different electronic energy level structures of the dopant molecules 120 may allow individual addressing of each dopant molecule 120. For instance, each dopant molecule 120 may be individually optically addressed if a bandwidth of the optical energy used to initialize each dopant molecule is sufficiently narrow (e.g., the bandwidth is small compared with a difference between the wavelength required to initialize a given dopant molecule 120 and the wavelength required to initialize other dopant molecules 120).

For instance, a first dopant molecule 120 and a second dopant molecule 120 may have different electronic energy level structures. Thus, in some embodiments, the first dopant molecule 120 may be configured to absorb first electromagnetic energy having a first central wavelength and the second dopant molecule 120 may be configured to absorb second electromagnetic energy having a second central wavelength. In some embodiments, the first or second central wavelength comprises any central wavelength described herein. In some embodiments, the first and second central wavelengths are different from one another.

In some embodiments, the first central wavelength is associated with a first range of wavelengths having a first bandwidth. In some embodiments, the first bandwidth is measured as a first full width at half maximum (FWHM). In some embodiments, the second central wavelength is associated with a second range of wavelengths having a second bandwidth. In some embodiments, the second bandwidth is measured as a second FWHM bandwidth. In some embodiments, the first bandwidth or the second bandwidth is at least about 1 MHZ, 2 MHz, 3 MHz, 4 MHZ, 5 MHZ, 6 MHz, 7 MHz, 8 MHz, 9 MHZ, 10 MHz, 15 MHZ, 20 MHz, 25 MHZ, 30 MHz, 35 MHz, 40 MHz, 45 MHz, 50 MHz, 55 MHz, 60 MHz, 65 MHz, 70 MHz, 75 MHZ, 80 MHz, 85 MHz, 90 MHz, 95 MHz, 100 MHz, or more, at most about 100 MHz, 95 MHz, 90 MHz, 85 MHZ, 80 MHz, 75 MHz, 70 MHZ, 65 MHz, 60 MHz, 55 MHz, 50 MHz, 45 MHz, 40 MHz, 35 MHZ, 30 MHZ, 25 MHZ, 20 MHz, 15 MHz, 10 MHZ, 9 MHZ, 8 MHz, 7 MHz, 6 MHZ, 5 MHz, 4 MHZ, 3 MHZ, 2 MHZ, 1 MHz, or less, or within a range defined by any two of the preceding values.

In some embodiments, the first range of wavelengths and the second range of wavelengths are different. In some embodiments, the first range of wavelengths and the second range of wavelengths do not overlap (e.g., within the first FWHM and the second FWHM). In some embodiments, the first FWHM and the second FWHM are similar to or wider than the bandwidth of an optical source directed to the first dopant molecule 120 and the second dopant molecule 120. In some embodiments, the non-overlapping nature of the first and second ranges of wavelength permits the first dopant molecule 120 to absorb optical energy while the second dopant molecule 120 does not absorb the optical energy. In some embodiments, the non-overlapping nature of the first and second ranges of wavelengths permits the second dopant molecule 120 to absorb optical energy while the first dopant molecule 120 does not absorb the optical energy. This procedure may be referred to as “individual optical initialization” of the first and second dopant molecules 120. In some embodiments, individual optical initialization of the first and second dopant molecules 120 causes the first and second dopant molecules 120 to emit different amounts of the optical energy. In some embodiments, measuring the optical energy collapses the quantum state of the at least one dopant molecule into an electronic energy eigenstate of the at least one dopant molecule, thereby initializing the dopant molecule into a desired initial quantum state.

Although discussed in terms of two dopant molecules 120, the principles of individual optical initialization described herein may be extended to any number of dopant molecules 120. For instance, individual optical initialization may be applied to at least about 2, 3, 4, 5, 6, 7, 8, 9, 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, or more dopant molecules 120, at most about 10,000, 9,000, 6,000, 5,000, 4,000, 3,000, 2,000, 1,000, 900, 800, 700, 600, 500, 400, 300, 200, 100, 90, 80, 70, 60, 50, 40, 30, 20, 10, 9, 8, 7, 6, 5, 4, 3, or 2 dopant molecules 120, or a number of dopant molecules 120 that is within a range defined by any two of the preceding values.

Such individual optical initialization may be particularly useful for qubits based on the dopant molecules 120. As described herein, such dopant molecules 120 may be separated from one another by distances that are relatively small compared with typical optical beam waists. For instance, in some embodiments, the dopant molecules 120 are separated from one another by distances of less than 10 nm (or any other separation distance described herein) in order to ensure suitable coupling between nearest neighbor dopant molecules 120. In some embodiments, a typical optical beam waist may be approximately 500 nm, such that optical energy will strike approximately 5,000 qubits. Thus, individual optical initialization may allow manipulation of individual qubits even when optical energy is directed to hundreds or thousands of qubits.

In some embodiments, individual optical initialization of qubits may allow individual initialization of qubits in the first qubit basis state or the second qubit basis state (or any linear combination thereof) to thereby initialize the non-classical computation.

### RF or MW Manipulation of Individual Qubits

In some embodiments, the first and second qubit states described herein are separated by energy differences that are in the RF or MW portion of the electromagnetic spectrum. Thus, in some embodiments, manipulation of the quantum states of each qubit may be performed using RF or MW energy. Moreover, in some embodiments, the different physico-chemical environments of the different dopant molecules 120 gives rise to wavelength or frequency shifts that are not large enough to allow individual optical initialization of each qubit. In such embodiments, a plurality of qubits may first be simultaneously optically initialized using, for instance, a broadband optical source, as described herein. In some embodiments, the quantum state of each qubit is then individually manipulated using RF or MW energy.

In some embodiments, the first dopant molecule 120 may be configured to absorb first electromagnetic energy having a first central frequency and the second dopant molecule 120 may be configured to absorb second electromagnetic energy having a second central frequency. In some embodiments, the first or second central frequency is at least about 1 MHZ, 2 MHZ, 3 MHz, 4 MHz, 5 MHz, 6 MHZ, 7 MHz, 8 MHZ, 9 MHZ, 10 MHZ, 20 MHz, 30 MHz, 40 MHZ, 50 MHz, 60 MHz, 70 MHz, 80 MHz, 90 MHz, 100 MHz, 200 MHz, 300 MHz, 400 MHz, 500 MHz, 600 MHz, 700 MHz, 800 MHZ, 900 MHz, 1 gigahertz (GHz), 2 GHZ, 3 GHZ, 4 GHZ, 5 GHz, 6 GHZ, 7 GHZ, 8 GHZ, 9 GHZ, 10 GHz, 20 GHz, 30 GHz, 40 GHz, 50 GHz, 60 GHz, 70 GHz, 80 GHz, 90 GHz, 100 GHz, or more, at most about 100 GHz, 90 GHz, 80 GHz, 70 GHZ, 60 GHz, 50 GHz, 40 GHz, 30 GHz, 20 GHz, 10 GHz, 9 GHZ, 8 GHZ, 7 GHz, 6 GHZ, 5 GHZ, 4 GHz, 3 GHZ, 2 GHZ, 1 GHZ, 900 MHz, 800 MHZ, 700 MHZ, 600 MHz, 500 MHz, 400 MHZ, 300 MHz, 200 MHz, 100 MHz, 90 MHz, 80 MHz, 70 MHz, 60 MHz, 50 MHz, 40 MHz, 30 MHz, 20 MHz, 10 MHz, 9 MHZ, 8 MHZ, 7 MHz, 6 MHZ, 5 MHz, 4 MHZ, 3 MHz, 2 MHz, 1 MHz, or less, or within a range defined by any two of the preceding values. In some embodiments, the first or second central frequency is in an RF or MW portion of the electromagnetic spectrum.

In some embodiments, the first and second central frequencies are different from one another. In some embodiments, the first central frequency is associated with a first range of frequencies having a first bandwidth. In some embodiments, the first bandwidth is measured as a first FWHM bandwidth. In some embodiments, the second central frequency is associated with a second range of frequencies having a second bandwidth. In some embodiments, the second bandwidth is measured as a second FWHM bandwidth. In some embodiments, the first or second bandwidth is dependent on a power of RF or MW energy supplied to the first or second dopant molecule 120. In some embodiments, the first or second bandwidth comprises a natural bandwidth of the first or second dopant molecule 120. For instance, in some embodiments, the first or second bandwidth is at least about 100 Hz, 200 Hz, 300 Hz, 400 Hz, 500 Hz, 600 Hz, 700 Hz, 800 Hz, 900 Hz, 1 kHz, 2 kHz, 3 kHz, 4 kHz, 5 kHz, 6 kHz, 7 kHz, 8 kHz, 9 kHz, 10 kHz, 20 kHz, 30 kHz, 40 kHz, 50 kHz, 60 kHz, 70 kHz, 80 kHz, 90 kHz, 100 kHz, 200 kHz, 300 kHz, 400 kHz, 500 kHz, 600 kHz, 700 kHz, 800 kHz, 900 kHz, 1 MHz, 2 MHz, 3 MHZ, 4 MHZ, 5 MHZ, 6 MHZ, 7 MHz, 8 MHZ, 9 MHz, 10 MHz, 20 MHz, 30 MHZ, 40 MHz, 50 MHz, 60 MHz, 70 MHz, 80 MHz, 90 MHz, 100 MHz, or more, at most about 100 MHz, 90 MHz, 80 MHz, 70 MHz, 60 MHz, 50 MHz, 40 MHZ, 30 MHz, 20 MHz, 10 MHz, 9 MHz, 8 MHz, 7 MHz, 6 MHZ, 5 MHz, 4 MHZ, 3 MHZ, 2 MHZ, 1 MHZ, 900 kHz, 800 kHz, 700 kHz, 600 kHz, 500 kHz, 400 kHz, 300 kHz, 200 kHz, 100 kHz, 90 kHz, 80 kHz, 70 kHz, 60 kHz, 50 kHz, 40 kHz, 30 kHz, 20 kHz, 10 kHz, 9 kHz, 8 kHz, 7 kHz, 6 kHz, 5 kHz, 4 kHz, 3 kHz, 2 kHz, 1 kHz, 900 Hz, 800 Hz, 700 Hz, 600 Hz, 500 Hz, 400 Hz, 300 Hz, 200 Hz, 100 Hz, or less, or within a range defined by any two of the preceding values.

In some embodiments, the first range of frequencies and the second range of frequencies are different. In some embodiments, the first range of frequencies and the second range of frequencies do not overlap (e.g., within the first FWHM and the second FWHM). In some embodiments, the first FWHM and the second FWHM are similar to or narrower than the bandwidth of RF or MW energy directed to the first dopant molecule 120 and the second dopant molecule 120. In some embodiments, the non-overlapping nature of the first and second ranges of frequencies permits the first dopant molecule 120 to absorb RF or MW energy while the second dopant molecule 120 does not absorb the RF or MW energy. In some embodiments, the non-overlapping nature of the first and second ranges of frequencies permits the second dopant molecule 120 to absorb RF or MW energy while the first dopant molecule 120 does not absorb the RF or MW energy. This procedure may be referred to as “individual RF or MW manipulation” of the first and second dopant molecules 120.

Although discussed in terms of two dopant molecules 120, the principles of individual RF or MW manipulation described herein may be extended to any number of dopant molecules 120. For instance, individual RF or MW manipulation may be applied to at least about 2, 3, 4, 5, 6, 7, 8, 9, 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, or more dopant molecules 120, at most about 10,000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, 9, 8, 7, 6, 5, 4, 3, or 2 dopant molecules 120, or a number of dopant molecules 120 that is within a range defined by any two of the preceding values.

Such individual RF or MW manipulation may be particularly useful for qubits based on the dopant molecules 120. As described herein, such dopant molecules 120 may be separated from one another by distances that are relatively small compared with typical optical beam waists. For instance, in some embodiments, the dopant molecules 120 are separated from one another by distances of less than 10 nm (or any other separation distance described herein) in order to ensure suitable coupling between nearest neighbor dopant molecules 120. In some embodiments, a typical optical beam waist may strike hundreds or thousands of qubits, as described herein.

Thus, individual RF or MW manipulation may allow individual coherent manipulation of the quantum states of each qubit following (individual or simultaneous) optical initialization of the qubits. In some embodiments, the coherent manipulation comprises implementation of at least one non-classical operation. In some embodiments, the non-classical operation comprises any non-classical operation described herein.

### Storage of Non-Classical Information in Nuclear SpinDegrees of Freedom

In some embodiments, non-classical information (such as that obtained during or after implementation of any of the non-classical operations described herein) may be transferred from the electronic state of the at least one dopant molecule 120 to a nuclear spin state of the at least one dopant molecule 120 or at least one nearby molecule contained within the host material 110 (referred to as a “nearby host molecule”). In some embodiments, the information may be transferred by implementing a swap gate between the electronic state of the at least one dopant molecule 120 and the nuclear spin state. In some embodiments, the swap gate may be implemented by applying RF or MW energy to the at least one dopant molecule 120 and the nuclear spin state, as described herein.

In some embodiments, transferring the non-classical information to the nuclear spin state provides an increase in readout fidelity, initialization fidelity, or lifetime, thereby improving the overall fidelity of the non-classical computation.

### Optical Readout of Individual Qubits

In some embodiments, the different electronic energy level structures of the dopant molecules 120 may allow individual optical readout of the quantum state of each dopant molecule 120 following the non-classical operation. For instance, the quantum state of each dopant molecule 120 may be individually optically read out based on the wavelength of light emitted by the dopant molecule 120, which may vary based on the physico-chemical environment of each dopant molecule 120.

In some embodiments, each dopant molecule 120 is configured to absorb and emit light. In some embodiments, an optical property of the light emitted by each dopant molecule 120 is correlated with the quantum state of the associated dopant molecule 120. For instance, in some embodiments, a dopant molecule 120 in the first qubit state absorbs and emits light having a first property, while a dopant molecule 120 in the second qubit state absorbs and emits light having a second property. In some embodiments, a dopant molecule in a linear superposition between the first qubit state and the second qubit state absorbs and emits light having a linear superposition of the first property and the second property. In some embodiments, the first property is different from the second property. Thus, in some embodiments, measuring the light emitted by the dopant molecule 120 allows determination of the quantum state of the dopant molecule 120 at the time of the measurement. In some embodiments, the first or second property comprises an intensity of the light emitted by the dopant molecule 120. In some embodiments, the first or second property comprises a polarization state of the light emitted by the dopant molecule 120. In some embodiments, the first or second property comprises a wavelength of the light emitted by the dopant molecule 120. In some embodiments, the first or second property comprises a frequency of the light emitted by the dopant molecule 120.

### Systems for Initializing, Manipulating, and Reading Out Dopant Molecule Qubit States

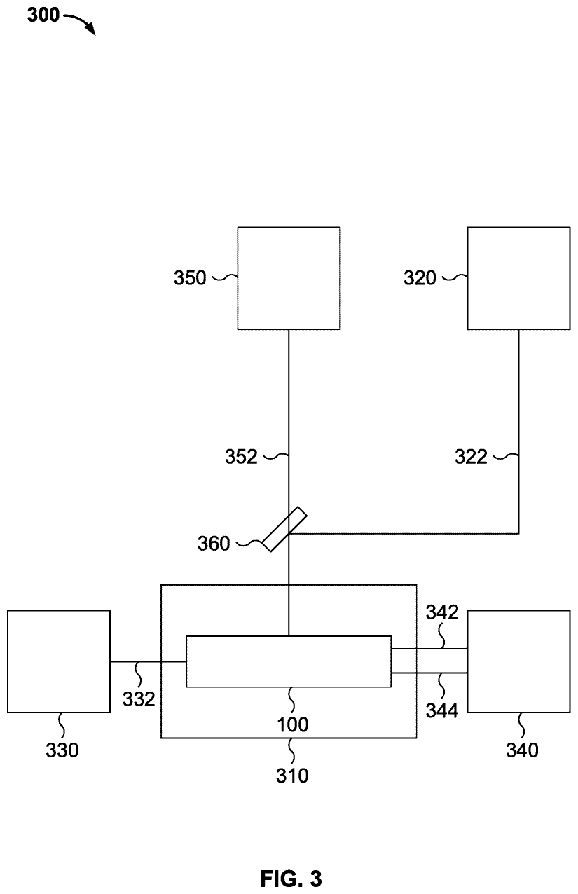

FIG. 3 shows a system 300 for performing a non-classical computation using the system 100 of FIG. 1A or 1B, in accordance with various embodiments. In the example shown, the system 300 comprises at least one cryogenic unit 310. In some embodiments, the cryogenic unit 310 is configured to contain the system 100 described herein with respect to FIGS. 1A and 1B. In some embodiments, the cryogenic unit 310 contains the system 100. In some embodiments, the cryogenic unit 310 does not contain the system 100. In some embodiments, the cryogenic unit 310 is configured to cool the system 100 to an operating temperature, such as a temperature of at least about 1 K, 2 K, 3 K, 4 K, 5 K, 6 K, 7 K, 8 K, 9 K, 10 K, 15 K, 20 K, 25 K, 30 K, 35 K, 40 K, 45 K, 50 K, or more, at most about 50 K, 45 K, 40 K, 35 K, 30 K, 25 K, 20 K, 15 K, 10 K, 9 K, 8 K, 7 K, 6 K, 5 K, 4 K, 3 K, 2 K, 1 K, or less, or a temperature that is between any two of the preceding values (such as between about 4 K and about 20 K). In some embodiments, the cryogenic unit 310 comprises at least one helium cryocooler. In some embodiments, the cryogenic unit 310 comprises at least one closed-cycle helium cryocooler. In some embodiments, the cryogenic unit 310 comprises at least one window (not shown in FIG. 3) configured to permit electromagnetic energy (such as optical energy) to pass therethrough. In some embodiments, the cryogenic unit 310 comprises at least one electrical feedthrough (not shown in FIG. 3) configured to permit electromagnetic energy (such as RF or MW energy) to pass therethrough.

In the example shown, the system 300 comprises at least one initialization unit 320. In some embodiments, the initialization unit 320 is configured to direct third electromagnetic energy 322 to at least one dopant molecule (not shown in FIG. 3) of the system 100. In some embodiments, the third electromagnetic energy 322 is configured to initialize a quantum state of the at least one dopant molecule into any linear combination of the first qubit state and the second qubit state, as described herein with respect to FIGS. 1A, 1B, and 2. In some embodiments, the third electromagnetic energy 322 comprises at least one IR, visible, or UV wavelength described herein. For instance, in some embodiments, the third electromagnetic energy 322 comprises at least one wavelength between about 200 nm and about 1,000 nm. In some embodiments, the initialization unit 320 is configured to initialize the quantum state of the at least one dopant molecule in any manner described herein with respect to FIGS. 1A, 1B, or 2. In some embodiments, the initialization unit 320 comprises a confocal optical system, a confocal microscope, or a widefield microscope. In some embodiments, the initialization unit 320 is configured to measure electromagnetic energy (not shown in FIG. 3) emitted by the at least one dopant molecule in response to the third electromagnetic energy 322. In some embodiments, the measured electromagnetic energy is indicative of whether the quantum state of the at least one dopant molecule was properly initialized. In some embodiments, measuring the emitted electromagnetic energy collapses the quantum state of the at least one dopant molecule into an electronic energy eigenstate of the at least one dopant molecule, thereby initializing the dopant molecule into a desired initial quantum state. In some embodiments, the initialization unit 320 is configured to re-apply the third electromagnetic energy 322 in response to the measured electromagnetic energy. For instance, in some embodiments, the initialization unit 320 is configured to re-apply the third electromagnetic energy 322 to the at least one dopant molecule if the measured electromagnetic energy indicates that the at least one dopant molecule was not properly initialized.

In the example shown, the system 300 comprises a single initialization unit 320. However, in some embodiments, the system 300 comprises a plurality of initialization units 320. In some embodiments, the system 300 comprises at least 1, 2, 3, 4, 5, 6, 7, 8, 9, 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, 20,000, 30,000, 40,000, 50,000, 60,000, 70,000, 80,000, 90,000, 100,000, or more initialization units 320, at most about 100,000, 90,000, 80,000, 70,000, 60,000, 50,000, 40,000, 30,000, 20,000, 10,000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, 9, 8, 7, 6, 5, 4, 3, 2, or 1 initialization units 320, or a number of initialization units 320 that is within a range defined by any two of the preceding values. In some embodiments, each initialization unit 320 is configured to initialize a quantum state of at least about 1, 2, 3, 4, 5, 6, 7, 8, 9, 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, or more qubits, at most about 10,000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, 9, 8, 7, 6, 5, 4, 3, 2, or 1 qubits, or a number of qubits that is within a range defined by any two of the preceding values.

In the example shown, the system 300 comprises at least one non-classical operation unit 330. In some embodiments, the non-classical operation unit 330 is configured to apply fourth electromagnetic energy 332 to at least one dopant molecule of the system 100. In some embodiments, the fourth electromagnetic energy 332 is configured to perform at least one non-classical operation on the at least one dopant molecule, as described herein with respect to FIGS. 1A, 1B, and 2. In some embodiments, the fourth electromagnetic energy 332 comprises at least one RF or MW frequency described herein. For instance, in some embodiments, the fourth electromagnetic energy 332 comprises at least one frequency between about 1 MHz and about 100 GHz. In some embodiments, the non-classical operation unit is configured to perform any non-classical operation described in any manner described herein with respect to FIGS. 1A, 1B, and 2. In some embodiments, the non-classical operation unit 330 comprises at least one RF cavity, MW cavity, RF stripline, MW stripline, RF antenna, MW antenna, microscopic RF antenna, microscope MW antenna, nanoscopic RF antenna, or nanoscopic MW antenna.

In the example shown, the system 300 comprises a single non-classical operation unit 330. However, in some embodiments, the system 300 comprises a plurality of non-classical operation units 330. In some embodiments, the system 300 comprises at least 1, 2, 3, 4, 5, 6, 7, 8, 9, 10, 20, 30, 40, 50, 60, 70, 80, 90, 100, 200, 300, 400, 500, 600, 700, 800, 900, 1,000, or more non-classical operation units 330, at most about 1,000, 900, 800, 700, 600, 500, 400, 300, 200, 100, 90, 80, 70, 60, 50, 40, 30, 20, 10, 9, 8, 7, 6, 5, 4, 3, 2, or 1 non-classical operation units 330, or a number of non-classical operation units 330 that is within a range defined by any two of the preceding values. In some embodiments, each non-classical operation unit 330 is configured to perform a non-classical operation on at least about 1, 2, 3, 4, 5, 6, 7, 8, 9, 10, 20, 30, 40, 50, 60, 70, 80, 90, 100, 200, 300, 400, 500, 600, 700, 800, 900, 1,000, or more qubits, at most about 1,000, 900, 800, 700, 600, 500, 400, 300, 200, 100, 90, 80, 70, 60, 50, 40, 30, 20, 10, 9, 8, 7, 6, 5, 4, 3, 2, or 1 qubits, or a number of qubits that is within a range defined by any two of the preceding values.

In the example shown, the system 300 comprises at least one storage unit 340. In some embodiments, the at least one storage unit 340 is configured to apply fifth electromagnetic energy 342 and sixth electromagnetic energy 344 to the at least one dopant molecule. In some embodiments, the fifth electromagnetic energy 342 and sixth electromagnetic energy 344 are jointly configured to transfer information from the electronic state of the at least one dopant molecule to a nuclear spin state of the at least one dopant molecule, as described herein with respect to FIGS. 1A, 1B, and 2. In some embodiments, the fifth electromagnetic energy 342 and sixth electromagnetic energy 344 are configured to jointly apply a swap gate to the at least one dopant molecule, as described herein with respect to FIGS. 1A, 1B, and 2. In some embodiments, the fifth electromagnetic energy 342 comprises at least one RF or MW frequency described herein. For instance, in some embodiments, the fifth electromagnetic energy 342 comprises at least one frequency between about 1 kHz and about 100 MHz. In some embodiments, the sixth electromagnetic energy 344 comprises at least one RF or MW frequency described herein. For instance, in some embodiments, the sixth electromagnetic energy 344 comprises at least one frequency between about 1 MHz and about 100 GHz. In some embodiments, the storage unit 340 comprises at least one RF cavity, MW cavity, RF stripline, MW stripline, RF antenna, MW antenna, microscopic RF antenna, microscope MW antenna, nanoscopic RF antenna, or nanoscopic MW antenna.

In the example shown, the system 300 comprises a single storage unit 340. However, in some embodiments, the system 300 comprises a plurality of storage units 340. In some embodiments, the system 300 comprises at least 1, 2, 3, 4, 5, 6, 7, 8, 9, 10, 20, 30, 40, 50, 60, 70, 80, 90, 100, 200, 300, 400, 500, 600, 700, 800, 900, 1,000, or more storage units 340, at most about 1,000, 900, 800, 700, 600, 500, 400, 300, 200, 100, 90, 80, 70, 60, 50, 40, 30, 20, 10, 9, 8, 7, 6, 5, 4, 3, 2, or 1 storage units 340, or a number of storage units 340 that is within a range defined by any two of the preceding values. In some embodiments, each storage unit 340 is configured to transfer information from the electronic state to the nuclear spin state of at least about 1, 2, 3, 4, 5, 6, 7, 8, 9, 10, 20, 30, 40, 50, 60, 70, 80, 90, 100, 200, 300, 400, 500, 600, 700, 800, 900, 1,000, or more qubits, at most about 1,000, 900, 800, 700, 600, 500, 400, 300, 200, 100, 90, 80, 70, 60, 50, 40, 30, 20, 10, 9, 8, 7, 6, 5, 4, 3, 2, or 1 qubits, or a number of qubits that is within a range defined by any two of the preceding values.

In some embodiments, the system 300 does not comprise a storage unit 340.

In the example shown, the system 300 comprises at least one detection unit 350. In some embodiments, the detection unit 350 is configured to detect the electronic state of the at least one dopant molecule, as described herein with respect to FIGS. 1A, 1B, and 2. In some embodiments, the detection unit 350 is configured to detect the nuclear spin state of the at least one dopant molecule, as described herein with respect to FIGS. 1A, 1B, and 2. In some embodiments, the detection unit 350 is configured to direct seventh electromagnetic energy 352 to the at least one dopant molecule to thereby obtain a result of the at least one non-classical operation, as described herein with respect to FIGS. 1A, 1B, and 2. In some embodiments, the seventh electromagnetic energy 352 comprises at least one IR, visible, or UV wavelength described herein. For instance, in some embodiments, the seventh electromagnetic energy 352 comprises at least one wavelength between about 200 nm and about 1,000 nm. In some embodiments, the detection unit 350 comprises at least one optical detector configured to detect light emitted by the at least one dopant molecule in response to the seventh electromagnetic energy 352. In some embodiments, the detection unit 350 comprises a confocal optical system, confocal microscope, widefield microscope, spectrometer, optical spectrometer, fluorescence spectrometer, UV-visible spectrometer, polarimeter, or polarization camera.

In the example shown, the system 300 comprises a single detection unit 350. However, in some embodiments, the system 300 comprises a plurality of detection units 350. In some embodiments, the system 300 comprises at least 1, 2, 3, 4, 5, 6, 7, 8, 9, 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, 20,000, 30,000, 40,000, 50,000, 60,000, 70,000, 80,000, 90,000, 100,000, or more detection units 350, at most about 100,000, 90,000, 80,000, 70,000, 60,000, 50,000, 40,000, 30,000, 20,000, 10,000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, 9, 8, 7, 6, 5, 4, 3, 2, or 1 detection units 350, or a number of detection units 350 that is within a range defined by any two of the preceding values. In some embodiments, each detection unit 350 is configured to detect an electronic state or a nuclear spin state of at least about 1, 2, 3, 4, 5, 6, 7, 8, 9, 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, or more qubits, at most about 10,000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, 9, 8, 7, 6, 5, 4, 3, 2, or 1 qubits, or a number of qubits that is within a range defined by any two of the preceding values.

In some embodiments, the system 300 comprises at least one polarizing beamsplitter 360. In some embodiments, the polarizing beamsplitter 360 is configured to direct the third electromagnetic energy 322 from the initialization unit 320 to the system 100. In some embodiments, the polarizing beamsplitter 360 is configured to direct the seventh electromagnetic energy 352 from the detection unit 350 to the system 100 and to direct the light emitted by the at least one dopant molecule in response to the seventh electromagnetic energy 352 from the system 100 to the detection unit 350.

In some embodiments, the system 300 comprises one or more magnetic field sources (not shown in FIG. 3). In some embodiments, the magnetic field sources are configured to generate one or more magnetic fields or magnetic field gradients in a vicinity of the system 100. In some embodiments, the magnetic field sources each comprise a permanent magnet, an electromagnet, or a superconducting magnet. In some embodiments, the magnetic field sources comprise one or more solenoids, Helmholtz coils, anti-Helmholtz coils, saddle coils, Halbach arrays, or the like. In some embodiments, one or more of the magnetic field sources are contained in the cryogenic unit 310. In some embodiments, one or more of the magnetic field sources is configured to generate an average magnetic field strength (over the system 100) of at least about 1 microtesla (μ), 2μ, 3μ, 4μ, 5μ, 6μ, 7μ, 8μ, 9μ, 10μ, 20 μT, 30 μT, 40 μT, 50 μT, 60 μT, 70 μT, 80 μT, 90 μT, 100 μT, 200 μT, 300 μT, 400 μT, 500 μT, 600 μT, 700 μT, 800 μT, 900 μT, 1 millitesla (mT), 2 mT, 3 mT, 4 mT, 5 mT, 6 mT, 7 mT, 8 mT, 9 mT, 10 mT, 20 mT, 30 mT, 40 mT, 50 mT, 60 mT, 70 mT, 80 mT, 90 mT, 100 mT, 200 mT, 300 mT, 400 mT, 500 mT, 600 mT, 700 mT, 800 mT, 900 mT, 1 Tesla (T), or more, at most about 1 T, 900 mT, 800 mT, 700 mT, 600 mT, 500 mT, 400 mT, 300 mT, 200 mT, 100 mT, 90 mT, 80 mT, 70 mT, 60 mT, 50 mT, 40 mT, 30 mT, 20 mT, 10 mT, 9 mT, 8 mT, 7 mT, 6 mT, 5 mT, 4 mT, 3 mT, 2 mT, 1 mT, 900 μT, 800 μT, 700 μT, 600 μT, 500 μT, 400 μT, 300 μT, 200 μT, 100 μT, 90 μT, 80 μT, 70 μT, 60 μT, 50 μT, 40 μT, 30 μT, 20 μT, 10 μT, 9 μT, 8μ, 7μ, 6μ, 5μ, 4μ, 3μ, 2μ, 1μ, or less, or an average magnetic field strength that is within a range defined by any two of the preceding values. In some embodiments, one or more of the magnetic field sources is configured to an average magnetic field gradient (over the system 100) of at least about 1 microtesla per meter (μTm⁻¹), 2 μTm⁻¹, 3 μTm⁻¹, 4 μTm⁻¹, 5 μTm⁻¹, 6 μTm⁻¹, 7 μTm⁻¹, 8 μTm⁻¹, 9 μTm⁻¹, 10 μTm⁻¹, 20 μTm⁻¹, 30 μTm⁻¹, 40 μTm⁻¹, 50 μTm⁻¹, 60 ρTm⁻¹, 70 μTm⁻¹, 80 ρTm⁻¹, 90 μTm⁻¹, 100 μTm⁻¹, 200 μTm⁻¹, 300 μTm⁻¹, 400 μTm⁻¹, 500 μTm⁻¹, 600 μTm⁻¹, 700 μTm⁻¹, 800 μTm⁻¹, 900 μTm⁻¹, 1 microtesla per meter (mTm⁻¹), 2 mTm⁻¹, 3 mTm⁻¹, 4 mTm⁻¹, 5 mTm⁻¹, 6 mTm⁻¹, 7 mTm⁻¹, 8 mTm⁻¹, 9 mTm⁻¹, 10 mTm⁻¹, 20 mTm⁻¹, 30 mTm⁻¹, 40 mTm⁻¹, 50 mTm⁻¹, 60 mTm⁻¹, 70 mTm⁻¹, 80 mTm⁻¹, 90 mTm⁻¹, 100 mTm⁻¹, 200 mTm⁻¹, 300 mTm⁻¹, 400 mTm⁻¹, 500 mTm⁻¹, 600 mTm⁻¹, 700 mTm⁻¹, 800 mTm⁻¹, 900 mTm⁻¹, 1,000 mTm⁻¹, or more, at most about 1,000 mTm⁻¹, 900 mTm⁻¹, 800 mTm⁻¹, 700 mTm⁻¹, 600 mTm⁻¹, 500 mTm⁻¹, 400 mTm⁻¹, 300 mTm⁻¹, 200 mTm⁻¹, 100 mTm⁻¹, 90 mTm⁻¹, 80 mTm⁻¹, 70 mTm⁻¹, 60 mTm⁻¹, 50 mTm⁻¹, 40 mTm⁻¹, 30 mTm⁻¹, 20 mTm⁻¹, 10 mTm⁻¹, 9 mTm⁻¹, 8 mTm⁻¹, 7 mTm⁻¹, 6 mTm⁻¹, 5 mTm⁻¹, 4 mTm⁻¹, 3 mTm⁻¹, 2 mTm⁻¹, 1 mTm⁻¹, 900 μTm⁻¹, 800 μTm⁻¹, 700 ρTm⁻¹, 600 μTm⁻¹, 500 μTm⁻¹, 400 μTm⁻¹, 300 μTm⁻¹, 200 μTm⁻¹, 100 μTm⁻¹, 90 μTm⁻¹, 80 μTm⁻¹, 70 μTm⁻¹, 60 μTm⁻¹, 50 μTm⁻¹, 40 μTm⁻¹, 30 μTm⁻¹, 20 μTm⁻¹, 10 μTm⁻¹, 9 μTm⁻¹, 8 μTm⁻¹, 7 μTm⁻¹, 6 μTm⁻¹, 5 μTm⁻¹, 4 μTm⁻¹, 3 μTm⁻¹, 2 μTm⁻¹, 1 μTm⁻¹, or less, or an average magnetic field gradient that is within a range defined by any two of the preceding values.

### Methods for Performing Non-Classical Computations

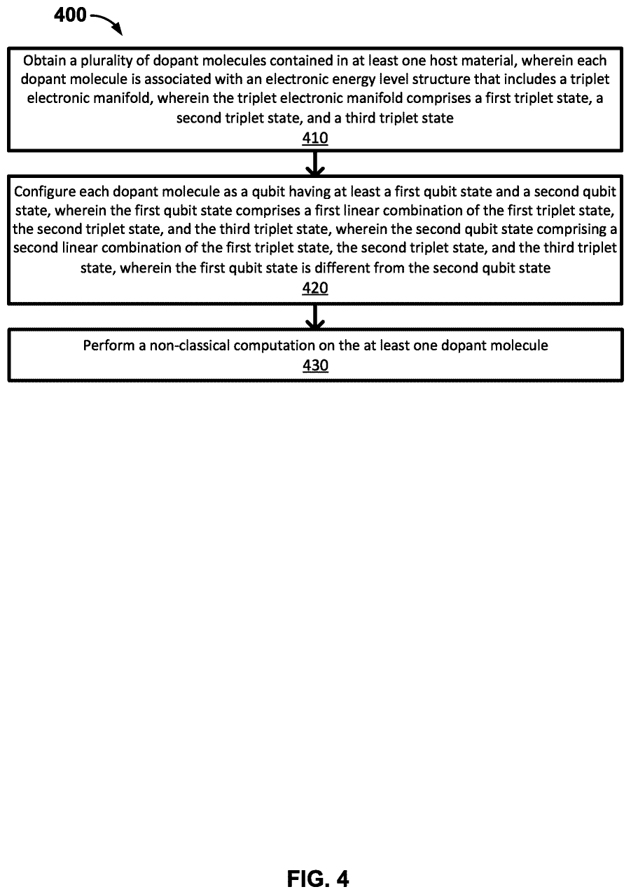

FIG. 4 shows a flowchart depicting a method 400 for performing a non-classical computation, in accordance with various embodiments. In some embodiments, the method 400 is performed using the system 100 of FIG. 1A or 1B or the system 300 of FIG. 3. At 410, a plurality of dopant molecules contained in at least one host material are obtained. In some embodiments, the plurality of dopant molecules comprise any dopant molecules described herein with respect to FIGS. 1A, 1B, 2, or 3. In some embodiments, the host material comprises any host material described herein with respect to FIGS. 1A, 1B, 2, or 3. In some embodiments, each dopant molecule is associated with an electronic energy level structure that includes a triplet electronic manifold, as described herein with respect to FIG. 2. In some embodiments, the triplet electronic manifold comprises a first triplet state, a second triplet state, and a third triplet state, as described herein with respect to FIG. 2.

At 420, each dopant molecule is configured as a qubit having at least a first qubit state and a second qubit state, as described herein with respect to FIGS. 1A, 1B, 2, or 3. In some embodiments, the first qubit state comprises a first linear combination of the first triplet state, the second triplet state, and the third triplet state, as described herein. In some embodiments, the second qubit state comprising a second linear combination of the first triplet state, the second triplet state, and the third triplet state, wherein the first qubit state is different from the second qubit state, as described herein. In some embodiments, the first qubit state or the second qubit state has any lifetime described herein with respect to FIGS. 1A, 1B, 2, or 3 at any temperature described herein with respect to FIGS. 1A, 1B, 2, or 3. In some embodiments, at least one dopant molecule is coupled to at least one other dopant molecule by an electronic or magnetic dipolar coupling interaction having any dipolar or magnetic coupling strength described herein with respect to FIGS. 1A, 1B, 2, or 3.

At 430, a non-classical computation is performed on the at least one dopant molecule. In some embodiments, performing the non-classical computation comprises directing third electromagnetic energy to at least one dopant molecule to thereby initialize a quantum state of the at least one dopant molecule into the first qubit state or the second qubit state, applying fourth electromagnetic energy to at least one dopant molecule to thereby perform at least one non-classical operation on the at least one dopant molecule, and detecting the electronic state of the at least one dopant molecule or the nuclear spin state of the at least one dopant molecule to thereby obtain a result of the at least one non-classical operation, as described herein with respect to FIGS. 1A, 1B, 2, or 3. In some embodiments, the third electromagnetic energy comprises any third electromagnetic energy described herein. In some embodiments, the fourth electromagnetic energy comprises any fourth electromagnetic energy described herein. In some embodiments, the at least one non-classical operation comprises any non-classical operation described herein.

In some embodiments, the performing the non-classical computation further comprises, prior to detecting the nuclear spin state of the at least one dopant molecule, applying fifth electromagnetic energy and sixth electromagnetic energy to the at least one dopant molecule, as described herein with respect to FIGS. 1A, 1B, 2, or 3. In some embodiments, the fifth electromagnetic energy and sixth electromagnetic energy are jointly configured to transfer information from the electronic state to a nuclear spin state of the at least one dopant molecule, as described herein with respect to FIGS. 1A, 1B, 2, or 3. In some embodiments, the fifth electromagnetic energy comprises any fifth electromagnetic energy described herein. In some embodiments, the sixth electromagnetic energy comprises any sixth electromagnetic energy described herein.

In some embodiments, detecting the electronic state of the at least one dopant molecule or the nuclear spin state of the at least one dopant molecule comprises applying seventh electromagnetic energy to the at least one dopant molecule to thereby obtain the result of the at least one non-classical operation, as described herein with respect to FIGS. 1A, 1B, 2, or 3. In some embodiments, the seventh electromagnetic energy comprises any seventh electromagnetic energy described herein. In some embodiments, detecting the electronic state of the at least one dopant molecule or the nuclear spin state of the at least one dopant molecule further comprises detecting light emitted by the at least one dopant molecule in response to the seventh electromagnetic energy, as described herein with respect to FIGS. 1A, 1B, 2, or 3.

### Methods for Generating, Producing, or Constructing Non-Classical Computers

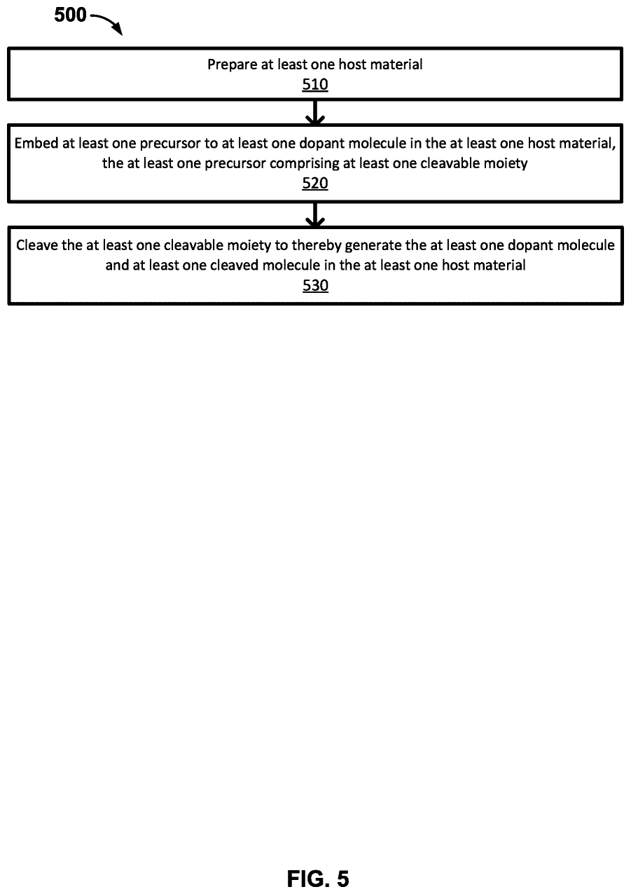

FIG. 5 shows a flowchart depicting a method 500 for generating, producing, or constructing a non-classical computer, in accordance with various embodiments. In some embodiments, the method 500 is used to generate the system 100 of FIG. 1A or 1B or the system 300 of FIG. 3. At 510, at least one host material is prepared or obtained. In some embodiments, the at least one host material comprises any host material comprises any host material described herein with respect to FIGS. 1A, 1B, 2, or 3.

At 520, at least one precursor to at least one dopant molecule is embedded in the at least one host material. For instance, in some embodiments, the at least one precursor is embedded in the at least one host material by solution based growth of dilute molecular crystals. In some embodiments, the at least one dopant molecule comprises any dopant molecule described herein with respect to FIGS. 1A, 1B, 2, or 3. In some embodiments, the at least one precursor comprises at least one cleavable moiety. In some embodiments, the at least one cleavable moiety comprises any cleavable moiety described herein with respect to FIG. 1A.

In some embodiments, the at least one dopant molecule is associated with an electronic energy level structure that includes a triplet electronic manifold, as described herein with respect to FIG. 2. In some embodiments, the triplet electronic manifold comprises a first triplet state, a second triplet state, and a third triplet state, as described herein with respect to FIG. 2.

At 530, the at least one cleavable moiety is cleaved, as described herein with respect to FIG. 1A. In some embodiments, cleaving the at least one cleavable moiety generates the at least one dopant molecule and at least one cleaved molecule in the at least one host material, as described herein with respect to FIG. 1A. In some embodiments, the at least one cleaved molecule comprises any cleaved molecule described herein with respect to FIG. 1A. In some embodiments, the at least one cleavable moiety is cleaved by exposing the at least one precursor to light, as described herein with respect to FIG. 1A. In some embodiments, the light comprises any light described herein with respect to FIG. 1A.

### RECITATION OF EMBODIMENTS

Non-limiting embodiments of the foregoing disclosed herein include:

Embodiment 1. A method for generating a non-classical computer, comprising:
preparing at least one host material;
embedding at least one precursor to at least one dopant molecule in the at least one host material, the at least one precursor comprising at least one cleavable moiety;
cleaving the at least one cleavable moiety to thereby generate the at least one dopant molecule and at least one cleaved molecule in the at least one host material, wherein:
   the at least one dopant molecule comprises a qubit having at least a first qubit state and a second qubit state;
   the at least one dopant molecule is associated with an electronic energy level structure that includes a triplet electronic manifold;
   the triplet electronic manifold comprises a first triplet state, a second triplet state, and a third triplet state;
   the first qubit state comprises a first linear combination of the first triplet state, the second triplet state, and the third triplet state;
   the second qubit state comprises a second linear combination of the first triplet state, the second triplet state, and the third triplet state; and
   the first qubit state is different from the second qubit state.

Embodiment 2. The method of Embodiment 1, wherein the at least one cleavable moiety comprises at least one photocleavable moiety.

Embodiment 3. The method of Embodiment 1, wherein the at least one photocleavable moiety comprises at least one diazo, azido, isocyanato, or iminoiodinane moiety.

Embodiment 4. The method of Embodiment 3, wherein the at least one cleaved molecule comprises at least one dinitrogen molecule, carbon monoxide molecule, or aryl iodide molecule.

Embodiment 5. The method of any one of Embodiments 1-4, wherein cleaving the at least one cleavable moiety comprises exposing the at least one precursor to light.

Embodiment 6. The method of Embodiment 5, wherein the light has a central wavelength between about 200 nanometers (nm) and about 500 nm.

Embodiment 7. The method of any one of Embodiments 1-6, wherein the at least one dopant molecule comprises a plurality of dopant molecules.

Embodiment 8. The method of any one of Embodiments 1-7, wherein the host material comprises at least one organic molecule.

Embodiment 9. The method of any one of Embodiments 1-8, wherein the host material comprises a crystalline host material, a single crystalline host material, a polycrystalline host material, a liquid crystalline host material, a powder host material, an amorphous host material, or a frozen solution host material.

Embodiment 10. The method of any one of Embodiments 1-9, wherein the host material comprises a C4-C20 linear or branched alkane; an aromatic hydrocarbon; a polyaromatic hydrocarbon optionally substituted with a methylene, nitrile, carbonyl, carboxylate, alkyl, deuterated alkyl, aryl, deuterated aryl, heteroaryl, deuterated heteroaryl, borane, imine, amine, nitro, phosphine, thioether, ether, fluoro, chloro, bromo, iodo, or thiocarbonyl group; a diarylketone; naphthalene; anthracene; pare-terphenyl; benzoic acid; fluorene; biphenyl; benzene; n-hexane; biphenylene; ortho-terphenylene; meta-terphenylene; para-terphenylene; phenanthrene; di(naphthalen-2-yl) methanone; di(phenyl) methanone; or any partially or fully isotopically labeled derivative thereof.

Embodiment 11. The method of any one of Embodiments 1-10, wherein the host material comprises a thin film having a thickness of at most 100 nanometers (nm).

Embodiment 12. The method of any one of Embodiments 1-11, wherein the at least one dopant molecule comprises an organic molecule.

Embodiment 13. The method of any one of Embodiments 1-12, wherein the at least one precursor comprises a derivative of a carbene molecule; a derivative of a nitrene molecule; a diazo derivative of a carbene molecule; an azido derivative of a nitrene molecule; an isocyanato derivative of a nitrene molecule; an imidoiodinane derivative of a nitrene; (diazomethylene)dinaphthalene; (diazomethylene)dibenzene; 4-azidobenzoic acid; or any partially or fully isotopically labeled derivative thereof.

Embodiment 14. The method of any one of Embodiments 1-13, wherein the at least one dopant molecule comprises a carbene molecule; a nitrene molecule; a di(napthalen-2-yl) carbene molecule; a di(phenyl) carbene molecule; or any partially or fully isotopically labeled derivative thereof.

Embodiment 15. The method of any one of Embodiments 1-14, wherein the plurality of dopant molecules are arranged in a pseudo-two-dimensional (pseudo-2D) layer.

Embodiment 16. The method of Embodiment 15, wherein the pseudo-2D layer comprises a self-assembled monolayer (SAM).

Embodiment 17. The method of any one of Embodiments 1-16, wherein an average distance between dopant molecules is at most 20 nm.

Embodiment 18. The method of any one of Embodiments 1-17, wherein the at least one dopant molecule is contained in the at least one host material at a concentration of at least 10⁶ dopant molecules per cubic micrometer (μm³).

Embodiment 19. The method of any one of Embodiments 1-18, wherein:
the at least one dopant molecule comprises a plurality of dopant molecules;
a first dopant molecule of the plurality of dopant molecules is configured to absorb first electromagnetic energy having a first central wavelength or a first central frequency;
a second dopant molecule of the plurality of dopant molecules is configured to absorb second electromagnetic energy having a second central wavelength or a second central frequency; and
the first central wavelength or the first central frequency is different from the second central wavelength or the second central frequencies.

Embodiment 20. The method of Embodiment 19, wherein:
the first central wavelength or the first central frequency is associated with a first range of wavelengths or a first range of frequencies having a first full width at half maximum (FWHM) bandwidth;
the second central wavelength or the second central frequency is associated with a second range of wavelengths or a second range of frequencies having a second FWHM bandwidth; and
the first range of wavelengths or the first range of frequencies within the first FWHM bandwidth and the second range of wavelengths or the second range of frequencies within the second FWHM bandwidth do not overlap.

Embodiment 21. The method of Embodiment 20, wherein the first FWHM bandwidth or the second FWHM bandwidth is at most 100 megahertz (MHz).

Embodiment 22. The method of any one of Embodiments 19-21, wherein the first central wavelength or the second central wavelength is between 200 nm and 1,000 nm.

Embodiment 23. The method of Embodiment 21, wherein the first FWHM bandwidth or the second FWHM bandwidth is at most 100 gigahertz (GHz).

Embodiment 24. The method of Embodiment 23, wherein the first central frequency or the second central frequency is between 1 MHz and 100 GHz.

Embodiment 25. The method of any one of Embodiments 1-24, wherein the triplet electronic manifold comprises a ground state triplet (GST) electronic manifold.

Embodiment 26. A system for performing a non-classical computation, comprising:
at least one host material;
at least one dopant molecule contained in the at least one host material; and
at least one cleaved molecule contained in the at least one host material, wherein:
   the at least one dopant molecule comprises a qubit having at least a first qubit state and a second qubit state;
   the at least one dopant molecule is associated with an electronic energy level structure that includes a triplet electronic manifold;
   the triplet electronic manifold comprises a first triplet state, a second triplet state, and a third triplet state;
   the first qubit state comprises a first linear combination of the first triplet state, the second triplet state, and the third triplet state;
   the second qubit state comprises a second linear combination of the first triplet state, the second triplet state, and the third triplet state; and
   the first qubit state is different from the second qubit state.

Embodiment 27. The system of Embodiment 26, wherein the at least one dopant molecule and the at least one cleaved molecule are generated by cleaving at least one precursor to the at least one dopant molecule, the at least one precursor comprising at least one cleavable moiety.

Embodiment 28. The system of Embodiment 27, wherein the at least one cleavable moiety comprises at least one photocleavable moiety.

Embodiment 29. The system of Embodiment 28, wherein the at least one photocleavable moiety comprises at least one diazo moiety, azido moiety, isocyanato moiety, or iminoiodinane moiety.

Embodiment 30. The system of Embodiment 29, wherein the cleaved molecule comprises at least one dinitrogen molecule, carbon monoxide molecule, or aryl iodide molecule.

Embodiment 31. The system of any one of Embodiments 27-30, wherein cleaving the at least one precursor comprises exposing the at least one precursor to light.

Embodiment 32. The system of Embodiment 31, wherein the light has a central wavelength between about 200 nanometers (nm) and about 500 nm.

Embodiment 33. The system of any one of Embodiments 26-32, wherein the at least one dopant molecule comprises a plurality of dopant molecules.

Embodiment 34. The system of any one of Embodiments 26-33, wherein the host material comprises at least one organic molecule.

Embodiment 35. The system of any one of Embodiments 26-34, wherein the host material comprises a crystalline host material, a single crystalline host material, a polycrystalline host material, a liquid crystalline host material, a powder host material, an amorphous host material, or a frozen solution host material.

Embodiment 36. The system of any one of Embodiments 26-35, wherein the host material comprises a C4-C20 linear or branched alkane; an aromatic hydrocarbon; a polyaromatic hydrocarbon optionally substituted with a methylene, nitrile, carbonyl, carboxylate, alkyl, deuterated alkyl, aryl, deuterated aryl, heteroaryl, deuterated heteroaryl, borane, imine, amine, nitro, phosphine, thioether, ether, fluoro, chloro, bromo, iodo, or thiocarbonyl group; a diarylketone; naphthalene; anthracene; para-terphenyl; benzoic acid; fluorene; biphenyl; benzene; n-hexane; biphenylene; ortho-terphenylene; meta-terphenylene; para-terphenylene; phenanthrene; di(naphthalen-2-yl) methanone; di(phenyl) methanone; or any partially or fully isotopically labeled derivative thereof.

Embodiment 37. The system of any one of Embodiments 26-36, wherein the host material comprises a thin film having a thickness of at most 100 nanometers (nm).

Embodiment 38. The system of any one of Embodiments 26-37, wherein the at least one dopant molecule comprises an organic molecule.

Embodiment 39. The system of any one of Embodiments 26-38, wherein the at least one precursor comprises a derivative of a carbene molecule; a derivative of a nitrene molecule; a diazo derivative of a carbene molecule; an azido derivative of a nitrene molecule; an isocyanato derivative of a nitrene molecule; an imidoiodinane derivative of a nitrene molecule; (diazomethylene)dinaphthalene; (diazomethylene)dibenzene; 4-azidobenzoic acid; or any partially or fully isotopically labeled derivative thereof.

Embodiment 40. The system of any one of Embodiments 26-39, wherein the at least one dopant molecule comprises a carbene molecule; a nitrene molecule; a di(napthalen-2-yl) carbene molecule; a di(phenyl) carbene molecule; or any partially or fully isotopically labeled derivative thereof.

Embodiment 41. The system of any one of Embodiments 26-40, wherein the plurality of dopant molecules are arranged in a pseudo-two-dimensional (pseudo-2D) layer.

Embodiment 42. The system of Embodiment 41, wherein the pseudo-2D layer comprises a self-assembled monolayer (SAM).

Embodiment 43. The system of any one of Embodiments 26-42, wherein an average distance between dopant molecules is at most 20 nm.

Embodiment 44. The system of any one of Embodiments 26-43, wherein the at least one dopant molecule is contained in the at least one host material at a concentration of at least 10⁶ dopant molecules per cubic micrometer (μm³).

Embodiment 45. The system of any one of Embodiments 26-44, wherein:
the at least one dopant molecule comprises a plurality of dopant molecules;
a first dopant molecule of the plurality of dopant molecules is configured to absorb first electromagnetic energy having a first central wavelength or a first central frequency;
a second dopant molecule of the plurality of dopant molecules is configured to absorb second electromagnetic energy having a second central wavelength or a second central frequency; and
the first central wavelength or the first central frequency is different from the second central wavelength or the second central frequencies.

Embodiment 46. The system of Embodiment 45, wherein:
the first central wavelength or the first central frequency is associated with a first range of wavelengths or a first range of frequencies having a first full width at half maximum (FWHM) bandwidth;
the second central wavelength or the second central frequency is associated with a second range of wavelengths or a second range of frequencies having a second FWHM bandwidth; and
the first range of wavelengths or the first range of frequencies within the first FWHM bandwidth and the second range of wavelengths or the second range of frequencies within the second FWHM bandwidth do not overlap.

Embodiment 47. The system of Embodiment 46, wherein the first FWHM bandwidth or the second FWHM bandwidth is at most 100 megahertz (MHz).

Embodiment 48. The system of any one of Embodiments 45-47, wherein the first central wavelength or the second central wavelength is between 200 nm and 1,000 nm.

Embodiment 49. The system of Embodiment 48, wherein the first FWHM bandwidth or the second FWHM bandwidth is at most 100 gigahertz (GHz).

Embodiment 50. The system of Embodiment 49, wherein the first central frequency or the second central frequency is between 1 MHz and 100 GHz.

Embodiment 51. The system of any one of Embodiments 26-50, wherein the triplet electronic manifold comprises a ground state triplet (GST) electronic manifold.

Embodiment 52. The system of any one of Embodiments 26-51, further comprising at least one initialization unit configured to direct third electromagnetic energy to the at least one dopant molecule to thereby initialize a quantum state of the at least one dopant molecule into the first qubit state or the second qubit state.

Embodiment 53. The system of Embodiment 52, wherein the third electromagnetic energy comprises at least one wavelength between 200 nm and 1,000 nm.

Embodiment 54. The system of any one of Embodiments 26-53, further comprising at least one non-classical operation unit configured to apply fourth electromagnetic energy to the at least one dopant molecule to thereby perform at least one non-classical operation on the at least one dopant molecule.

Embodiment 55. The system of Embodiment 54, wherein the at least one non-classical operation comprises at least one quantum operation, at least one quantum computing operation, at least one quantum gate operation, at least one quantum simulation operation, or at least one quantum annealing operation.

Embodiment 56. The system of Embodiment 54 or 55, wherein the fourth electromagnetic energy comprises at least one frequency between 1 MHz and 100 GHz.

Embodiment 57. The system of any one of Embodiments 54-56, wherein, subsequent to performing the at least one non-classical operation, a result of the at least one non-classical operation is correlated with an electronic state of the at least one dopant molecule.

Embodiment 58. The system of Embodiment 57, further comprising at least one storage unit configured to apply fifth electromagnetic energy and sixth electromagnetic energy to the at least one dopant molecule, wherein the fifth electromagnetic energy and sixth electromagnetic energy are jointly configured to transfer information from the electronic state to a nuclear spin state of the at least one dopant molecule.

Embodiment 59. The system of Embodiment 58, wherein the fifth electromagnetic energy and the sixth electromagnetic energy are configured to jointly apply a swap gate to the at least one dopant molecule to thereby transfer the information from the electronic state to the nuclear spin state of the at least one dopant molecule.

Embodiment 60. The system of Embodiment 58 or 59, wherein the fifth electromagnetic energy comprises at least one frequency between 1 kHz and 100 MHz and wherein the sixth electromagnetic energy comprises at least one frequency between 1 MHz and 100 GHz.

Embodiment 61. The system of any one of Embodiments 26-60, further comprising at least one detection unit configured to detect the electronic state of the at least one dopant molecule or the nuclear spin state of the at least one dopant molecule to thereby obtain a result of the at least one non-classical operation.

Embodiment 62. The system of Embodiment 61, wherein the at least one detection unit is configured to apply seventh electromagnetic energy to the at least one dopant molecule to thereby obtain the result of the at least one non-classical operation.

Embodiment 63. The system of Embodiment 61 or 62, wherein the at least one detection unit comprises at least one optical detector configured to detect light emitted by the at least one dopant molecule in response to the seventh electromagnetic energy.

Embodiment 64. The system of Embodiment 63, wherein the light emitted by the at least one dopant molecule has a first optical property associated with the first qubit state and a second optical property associated with the second qubit state, and wherein the first optical property is different from the second optical property.

Embodiment 65. The system of Embodiment 64, wherein the first optical property or the second optical property comprises an intensity, polarization, wavelength, or frequency of the light.

Embodiment 66. The system of any one of Embodiments 26-65, further comprising a cryogenic unit configured to contain the at least one host material and to cool the at least one host material to a temperature of at most 20 K.

Embodiment 67. The system of Embodiment 66, wherein the cryogenic unit comprises a helium cryocooler or a closed-cycle helium cryocooler.

### EXAMPLES

### Example 1: General Synthesis and Characterization Procedures

Unless otherwise noted, commercially available materials were used without purification. Moisture- and oxygen-sensitive reactions were carried out in flame-dried glassware and under an inert atmosphere of purified argon using a syringe/septa technique. Thin-layer chromatography (TLC) was performed on aluminium plates coated with 0.20 mm thickness of Silica Gel 60 F254. Developing plates were visualized using ultraviolet (UV) light at wavelength of 254 and 365 nm. NMR spectra were recorded on a Bruker Avance Neo 400 MHz or a Bruker Avance Neo 600 MHz spectrometer operating at 400.13 MHz for ¹H and 100.61 MHz for ¹³C or 600.15 MHz for ¹H and 150.94 MHz for ¹³C, respectively. NMR chemical shifts (d) are reported in parts-per-million (ppm). For the ¹H and ¹³C spectra, the solvent signal served for internal calibration (¹H NMR: δ(CHCl₃)=7.26; ¹³C NMR: (CDCl₃)=77.16]. ¹³C NMR spectra were recorded in the proton-decoupled mode. Coupling constants (J) are given in Hz and the apparent resonance multiplicity is reported as s (singlet), d (doublet), t (triplet), q (quartet), quint (quintet) or m (multiplet). Flash chromatography was carried out with a Biotage® Selekt Flash Purification System using a Biotage® Sfär HC Duo column as the solid phase. Electron paramagnetic resonance (EPR) spectra were recorded on an X-band EPR spectrometer (Bruker ELEXSYS E580) with the software xEPR for data acquisition. Measurements were performed using a dielectric ring resonance (Bruker model 4118X-MD5, typical microwave frequency about 9.7 GHZ) which was mounted in a helium-flow cryostat (Oxford CF935) with optical access. When operated in continuous-wave (cw) mode, a typical quality factor of about 10,000 was achieved and typical modulation amplitude and frequencies were 1 gauss (G) and 100 kHz, respectively. In pulsed model, a Bruker SpinJet arbitrary waveform generator with a 1 kW traveling-wave tube (TWT) amplifier (Applied Systems Engineering model 117) was used. Prior the measurements, samples were inserted into EPR tubers (Wilmad Quartz CFQ) having an outer diameter (OD) of 4 millimeters (mm) and aligned on a homemade Teflon sample stage. The sample could be rotated with a one-axis goniometer stage (Bruker E218G1).

### Example 2: Generic Synthetic Route for the Formation of Carbene Dopant Molecules

The general synthetic route for formation of carbene dopant molecules in organic host materials is shown below.

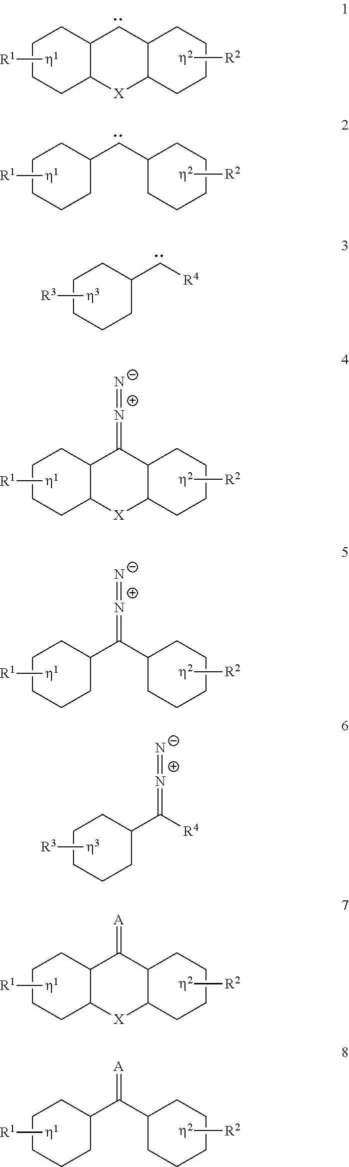

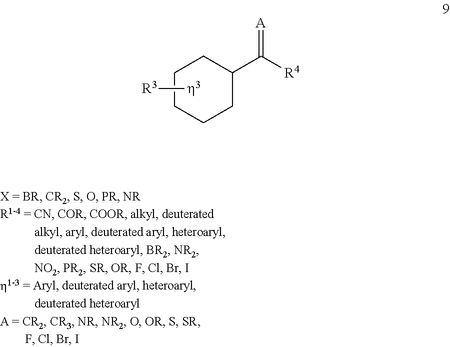

The carbenes are designed to possess a triplet ground state in which the two unpaired electrons are confined to close-by molecular orbitals. As such, electron coupling is maximized and the zero-field splitting parameters D and E of the electronic spin are large. Moreover, spin lattice relaxation times benefit from the weak spin orbit couplings typically present in purely organic materials. The carbenes may be included in a cyclic structure (1) and comprise two (2) or one (3) aryl or heteroaryl group π¹⁻³ that can be substituted by one or more nitrile groups, carbonyl groups, carboxylic acid groups, ester groups, alkyl groups, aryl groups, heteroaryl groups, amine groups, nitro groups, phosphine groups, alcohol groups, ether groups, thioether groups, or halogen groups. Such groups may be selected (e.g., using computational molecular modeling, high-throughput synthesis and screening, or the like) to fine tune the electronic properties such as the ZFS, zero-phonon lines, spectral stability, and/or thermodynamic/kinetic stability.

Since the carbenes are typically not stable enough to prepare dilute molecular crystals directly, a stable carbene precursor is instead embedded into the molecular matrix (compounds 4-6) and later activated (i.e., converted from carbene precursor form to activated carbene form). Carbene precursors typically comprise a diaryl diazo group (R₂C═N—═N), which can be photoactivated with light (λ=200 to 500 nm) to generate a molecule of dinitrogen N₂ and a molecule of carbene. An example of such activation is shown below.

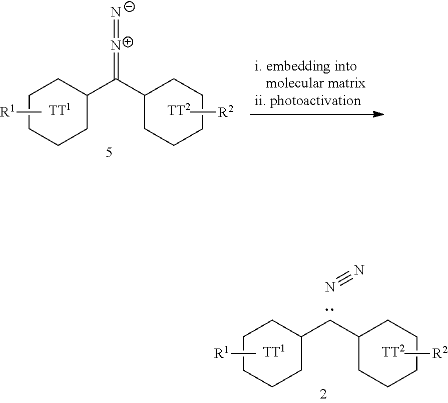

The host materials in which the carbenes are embedded (compounds 6-9) are typically designed such that they structurally resemble the carbene precursors 1-3, respectively, and enable the formation of dilute molecular crystals by substitutional replacement of host material (i.e., matrix) molecules by the carbene precursors. This isostructural relationship allows the preparation of high-quality dilute molecular crystals by reducing the amount of strain imparted by the dopant molecules (i.e., the carbenes). Both the carbene and the host material can be partially or fully deuterated to reduce the magnetic noise in the dilute molecular crystals and thus enhance the spin-spin coherence time T₂. Using bottom-up synthetic chemistry, the molecules can also be selectively labeled with ¹³C (e.g., at the carbene carbon), adding a nuclear spin manifold that may be used for quantum state preparation. Close packing of the molecules in the supramolecular arrangement helps to stabilize the carbene by trapping the inert N₂ molecule in close proximity to the reactive carbene center and thereby shielding it from any nearby reaction partners.

### Example 3: Synthesis of the Compounds Required to Embed di(napthalen-2-yl) carbene in di(naphthalen-2-yl) methanone

The synthetic route for formation of di(napthalen-2-yl) carbene dopant molecules in a di(napthalen-2-yl) methanone host material is shown below.

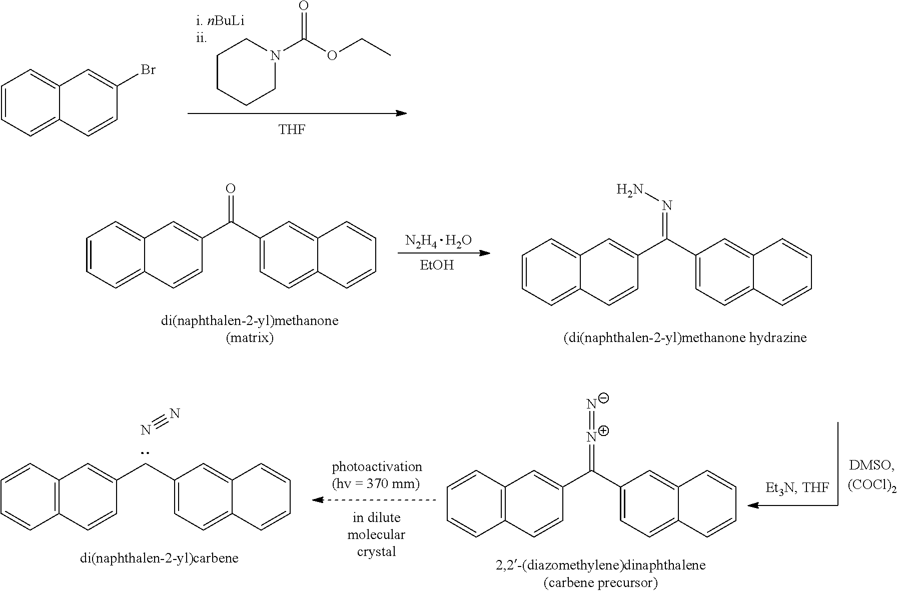

a) formation of di(naphthalen-2-yl) methanone

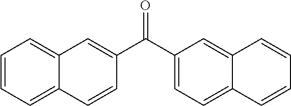 [SMILES: O=C(c1ccc2ccccc2c1)c1ccc2ccccc2c1]

Di(naphthalen-2-yl) methanone was prepared by modifying the procedure described in B. Kozankiewicz, M. Aloshyna, A. D. Gudmundsdottir, M. S. Platz, M. Orrit, P. Tamarat, J. Phys. Chem. A 1999, 103, 3155. A solution of 2-bromonaphthalene (25.0 grams, g, 0.12 moles, mol) in diethyl ether (anhydrous, 400 milliliters, mL, 0.3 molar, M) was cooled to −78 degrees Celsius (° C.) and n-butyllithium (2.5 M in hexanes, 48.3 mL, 1.00 equiv.) was added via dropping funnel within 10 minutes (min). The solution was stirred for 1 hour (h) at −78° C. To the resulting yellowish dispersion, a solution of N-carboethoxypiperidine (9.49 g, 0.12 mol, 1.00 equiv.) in diethyl ether (anhydrous, 50 mL) was added at −78° C. within 5 min after the addition was complete the cooling bath was removed. The reaction mixture was allowed to warm to room temperature (RT) within 1 h. The reaction was quenched by addition of 10% aqueous HCl (150 mL). The organic phase was separated, and the aqueous phase extracted with diethyl ether (2×100 mL). The combined organic phases were washed with water (200 mL) and brine (100 mL), and then dried over MgSO₄. To the ethereal solution methanol (80 mL) was added and most of the diethyl ether was removed under reduced pressure to give a white precipitate. Nearly quantitative precipitation occurred upon storage at 7° C. for 3 h. The precipitate was filtered off, washed with cold methanol (2×50 mL) and dried under vacuum to give the product as a white solid (15.5 g, 91%). The following physical, chemical, and spectroscopic parameters were obtained. Rf (SiO₂, CH₂Cl₂)=0.81. Melting point (Mp). 168.1-170.3° C.; ¹H NMR (400 MHZ, CDCl₃): δ 8.34 (d, J=1.3 Hz, 2H), 8.06-7.97 (m, 4H), 7.97-7.90 (m, 4H), 7.64 (ddd, J=8.3, 6.9, 1.3 Hz, 2H), 7.57 (ddd, J=8.3, 6.9, 1.3 Hz, 2H) ppm; ¹³C NMR (101 MHz, CDCl₃): δ 196.6, 135.4, 135.3, 132.4, 131.9, 129.5, 128.5, 128.4, 128.0, 126.9, 126.0 ppm. IR (ATR): v̅ 3051 (w), 1650 (m), 1618 (m), 1355 (m), 1272 (m), 954 (m), 918 (m), 871 (m), 830 (m), 776 (m) 748 (s) cm⁻¹.

b) formation of (di(naphthalen-2-yl)meth-ylene) hydrazine

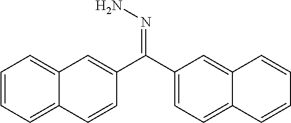 [SMILES: NN=C(c1ccc2ccccc2c1)c1ccc2ccccc2c1]

(Di(naphthalen-2-yl)methylene) hydrazine was prepared by modifying the procedure described in E. Schmitt, G. Landelle, J.-P. Vors, N. Lui, S. Pazenok, F. R. Leroux, Eur. J. Org. Chem. 2015, 2015, 6052. A mixture of di(naphthalen-2-yl) methanone (4.9 g, 17.3 mmol), hydrazine hydrate (1.18 mL, 24.3 mmol, 1.40 equiv.) and EtOH (anhydrous, 6.00 mL, 4.0 M) was heated to 160° C. for 16 h in a high pressure vessel that was sealed with a polytetrafluoroethylene (PTFE)-lined screw cap. The mixture was left to cool to RT for over 1 h and stored at 7° C. for another 2 h. The colorless needles formed were recrystallized from anhydrous EtOH, filtered, and dried in vacuo, to yield the product (4.77 g, 93%). The following physical, chemical, and spectroscopic parameters were obtained. Rf (SiO₂, CH₂Cl₂/)=0.14; Mp. 151.2-152.7° C.; ¹H NMR (400 MHZ, CDCl₃): δ 8.11-8.03 (m, 2H), 8.00-7.87 (m, 3H), 7.86-7.79 (m, 2H), 7.68-7.53 (m, 4H), 7.48-7.35 (m, 3H), 5.58 (s, 2H) ppm; ¹³C NMR (101 MHz, CDCl₃): δ 149.2, 136.2, 133.7, 133.5, 133.4, 133.3, 130.5, 129.6, 128.6, 128.5, 128.4, 128.1, 128.0, 127.7, 127.1, 126.8, 126.4, 126.3, 126.2, 123.8 ppm; IR (ATR): \dot{v} 3325 (m), 3189 (w), 3044 (w), 1622 (w), 1580 (m), 1499 (m), 1323 (w), 1270 (w), 1188 (w), 1151 (w), 1113 (w), 1074 (w), 927 (m), 867 (m) 744 (s) cm⁻¹.

c) formation of 2,2′-(diazomethylene)dinaphthalene

2,2′-(diazomethylene)dinaphthalene was prepared by modifying the procedure described in M. I. Javed and M. Brewer, Org. Synth. 2008, 85, 189. Handling and isolation of the product was done under exclusion of daylight. To a solution of dimethylsulfoxide (0.19 mL, 0.21 g, 2.73 mmol, 1.10 equiv.) and tetrahydrofuran (anhydrous, 22 mL, 0.13 M) was added oxalyl chloride (0.22 mL, 0.33 g, 2.61 mmol, 1.05 equiv.) in tetrahydrofuran (4 mL) at −55° C. over 5 min. The solution was maintained between −55° C. and −50° C. for 30 min while stirring and then cooled to −78° C. A mixture of (di(naphthalen-2-yl)methylene) hydrazine (0.74 g, 2.48 mmol, 1.00 equiv.) and triethylamine (0.72 mL, 0.53 g, 5.22 mmol, 2.10 equiv.) in tetrahydrofuran (10 mL) was added to the reaction solution over 5 min to provide a deep-red solution containing a copious white precipitate. The reaction mixture was maintained at −78° C. for 30 min, and then filtered while cold through a medium porosity sintered-glass funnel into round-bottom flask and the solid was rinsed with tetrahydrofuran (2×50 mL). The filtrate was concentrated at RT by rotary evaporation. The red residue was redissolved in n-hexane (200 mL) and rapidly filtered through a plug of activated basic alumina supported in a medium porosity sintered glass funnel and the solids were rinsed with n-hexane (˜100 mL) until the filtrate was colorless. The filtrate was concentrated at RT by rotary evaporation (to ca. 50 mL) and stored at 7° C. overnight. The formed precipitate was filtered off and dried under vacuum to give the product as purple crystalline solid (0.63 g, 87%). The following physical, chemical, and spectroscopic parameters were obtained. R/(Al₂O₃ basic, hexane)=0.52; Mp. 137.3-138.0° C.; ¹H NMR (400 MHZ, CDCl₃): δ 7.89 (d, J=8.6 Hz, 1H), 7.84 (dd, J=7.6, 1.8 Hz, 1H), 7.80 (d, J=2.0 Hz, 1H), 7.76 (dd, J=7.6, 1.7 Hz, 1H), 7.54-7.42 (m, 3H) ppm; ¹³C NMR (101 MHZ, CDCl₃): d 134.1, 131.9, 129.1, 127.9, 127.5, 127.1, 126.8, 125.8, 123.8, 123.5, 77.5, 77.2, 76.8, 63.5 ppm; IR (ATR): v̅ 3053 (w), 2011 (s), 1622 (m), 1590 (m), 1500 (m), 1465 (m) 1385 (m), 1366 (m), 1226 (m), 852 (s), 806 (s), 742 (s) cm⁻¹.

d) Formation of dilute molecular crystals of 2,2′-(diazomethylene)dinaphthalene in di(napthalen-2-yl) methanone

Di(naphthalen-2-yl) methanone (0.85 grams) was dissolved in hot ethyl acetate (HPLC grade, 100 mL, 0.030 M) and the solution was allowed to cool to RT. In the dark, to this solution, 2,2′-(diazomethylene)dinaphthalene (0.91 milligrams, 1025 ppm) was added. Aliquots (5 milliliters, mL) of this resulting parent solution were added into 10 mL vials using a syringe equipped with a 0.45 μm pore size syringe filter and the vials were placed in a screw top jar filled with ethanol (HPLC grade). Dilute molecular crystals (parallelepiped ca. 5×4×4 mm) formed within storage in the dark at RT for 7 days. The crystals were isolated in the dark, washed with ethanol (HPLC grade) and dried in vacuum. The dilute molecular crystals could be stored in the freezer (T=−22° C.) in the dark for several months without detectable degradation.

To generate the di(napthalen-2-yl) carbene dopant molecules in the di(naphthalen-2-yl) methanone host material, the dilute molecular crystals of 2,2′-(diazomethylene)dinaphthalene in di(napthalen-2-yl) methanone need only be exposed to light of the correct wavelength, as described herein.

### Example 4: Synthesis of the Compounds Required to Embed di(phenyl) carbene in di(phenyl) methanone

The synthetic route for formation of di(phenyl) carbene dopant molecules in a di(phenyl) methanone host material is shown below.

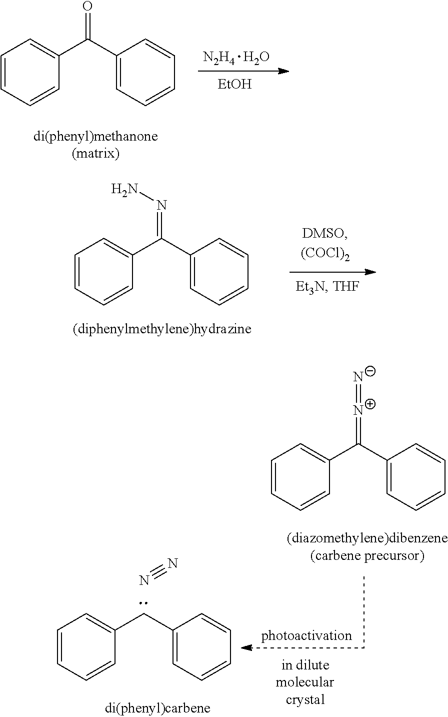

a) formation of (diphenylmethylene) hydrazine

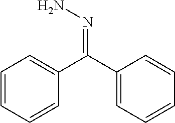 [SMILES: NN=C(c1ccccc1)c1ccccc1]

(Diphenylmethylene) hydrazine was prepared according to the procedure described in E. Schmitt, G. Landelle, J.-P. Vors, N. Lui, S. Pazenok, F. R. Leroux, Eur. J. Org. Chem. 2015, 2015, 6052.

### b) Formation of (Diazomethylene)Dibenzene

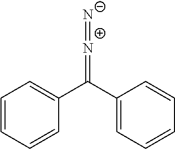 [SMILES: [N-]=[N+]=C(c1ccccc1)c1ccccc1]

(Diazomethylene)dibenzene was prepared according to the procedure described in M. I. Javed and M. Brewer, Org. Synth. 2008, 85, 189.

c) Formation of dilute molecular crystals of (diazomethylene)dibenzene in di(phenyl) methanone

Di(phenyl) methanone (0.30 grams, purified by sublimation) was dissolved in hot n-hexane (HPLC grade, 4.1 milliliter, 0.40 M) and the solution was allowed to cool to RT. In the dark, to this solution (diazomethylene)dibenzene (0.08 mg, 247 ppm) was added. Aliquots (1.0 milliliters, mL) of this resulting parent solution were added into 3.0 mL vials, which were sealed via a punctuated screw cap. Dilute molecular crystals (ca. 6×4×3 mm) formed upon storage in the dark at RT for 6 days. The crystals were isolated in the dark, washed with cold n-hexane (HPLC grade) and dried in vacuum. The dilute molecular crystals could be stored in the freezer (T=−22° C.) in the dark for several months without detectable degradation.

To generate the di(phenyl) carbene dopant molecules in the di(phenyl) methanone host material, the dilute molecular crystals of (diazomethylene)dibenzene in di(phenyl) methanone need only be exposed to light of the correct wavelength, as described herein.

### Example 5: Synthesis of the Compounds Required to Embed di(naphthalen-2-yl) carbene-dis in di(naphthalen-2-yl) methanone-d₁₄

The synthetic route for formation of di(naphthalen-2-yl) carbene-d₁₄ dopant molecules in a di(napthalen-2-yl) methanone-d₁₄ host material is shown below.

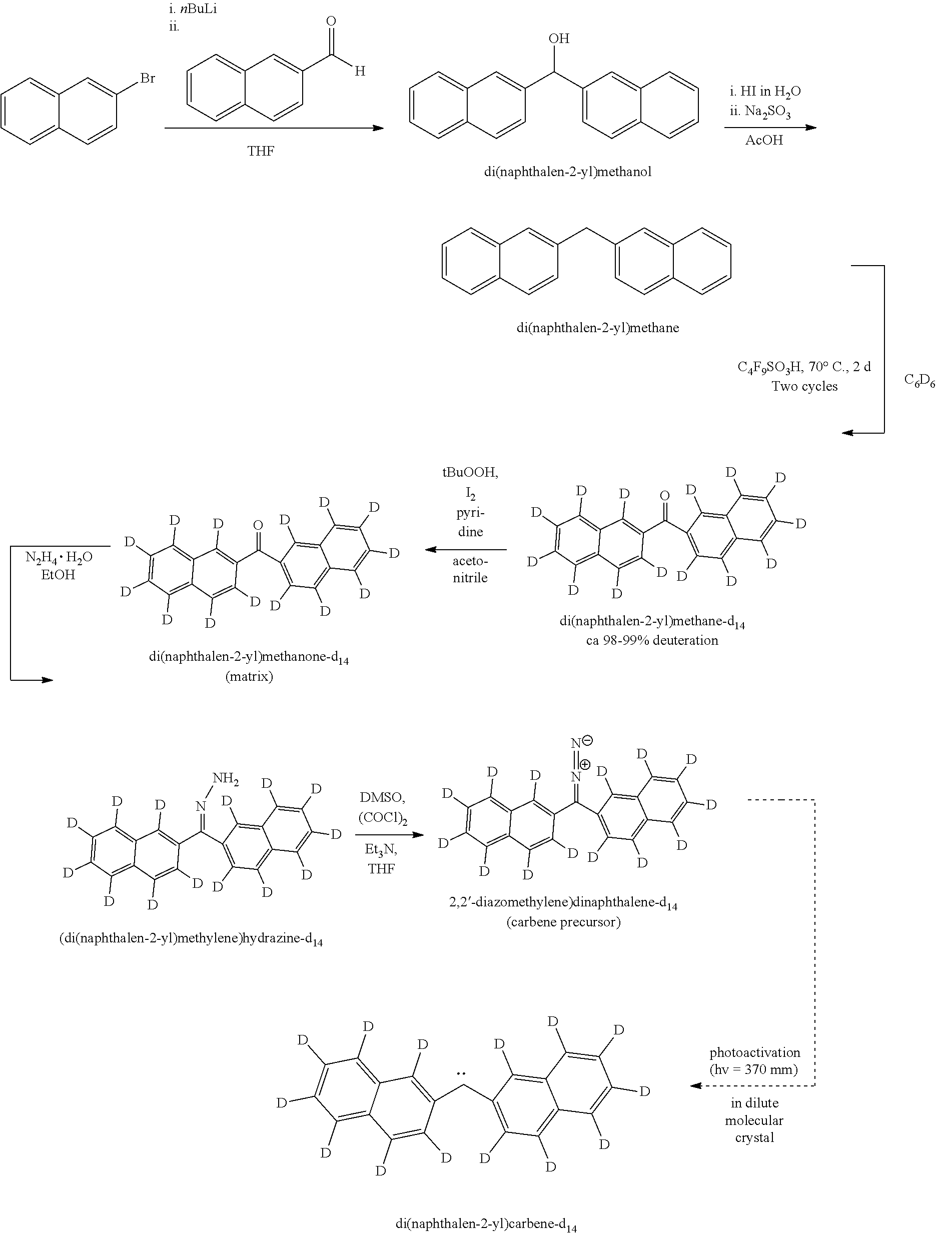

a) formation of di(naphthalen-2-yl) methane

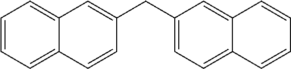 [SMILES: c1ccc2cc(Cc3ccc4ccccc4c3)ccc2c1]

Di(naphthalen-2-yl) methane was prepared by modifying the procedure described in T. K. Wood, W. E. Piers, B. A. Keay, M. Parvez, Chem. Eur. J. 2010, 16, 12199. To a solution of di(naphthalen-2-yl) methanol (3.80 g, 13.4 mmol) in AcOH (89.0 mL, 0.15 M) at RT was added HI (7.31 mL, 55% in H₂O, 53.5 mmol, 4.00 equiv.) and the reaction mixture was heated to reflux (130° C.) for 2 h. The reaction mixture was allowed to cool to RT and an aqueous saturated solution of Na₂SO₃ (80 mL) was slowly added under vigorous stirring until no further color change from dark to yellow was observed. The mixture was diluted with H₂O (80 mL) and extracted with Et₂O (3×100 mL). The combined organic phases were cooled to 0° C. and an aqueous solution of NaOH (50%, 105 mL) was slowly added until a pH of at least 12 was reached. The aqueous phase was extracted with Et₂O (50 mL), the combined organic phases were washed with brine (80 mL), dried over Na₂SO₄, and the solvent was removed in vacuo. The residue was recrystallized from hot n-hexane/toluene 5:1 (100 mL) to give white crystals (0.99 g, 87%). The following physical, chemical, and spectroscopic parameters were obtained. R$ (SiO₂, 30% CH₂Cl₂/hexane)=0.68; Mp. 91.7-93.9° C.; ¹H NMR (400 MHZ, CDCl₃): δ 7.85-7.73 (m, 3H), 7.68 (d, J=1.7 Hz, 1H), 7.45 (tt, J=6.9, 5.1 Hz, 2H), 7.36 (dd, J=8.4, 1.8 Hz, 1H), 4.32 (s, 1H) ppm; ¹³C NMR (101 MHZ, CDCl₃): δ 138.6, 133.8, 132.3, 128.3, 127.9, 127.8, 127.7, 127.4, 126.2, 125.5, 42.4 ppm; IR (ATR): v̅ 3080 (w), 3051 (w), 2815 (w) 1625 (w), 1596 (m), 1499 (m), 1409 (w), 1361 (m), 1270 (w), 954 (m), 806 (s), 757 (s), 730 (s) cm⁻¹.

b) formation of di(naphthalen-2-yl) methane-d₁₄

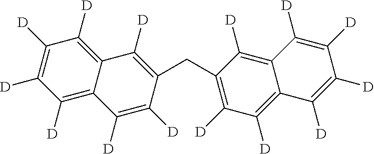 [SMILES: [2H]c1c([2H])c([2H])c2c([2H])c(Cc3c([2H])c([2H])c4c([2H])c([2H])c([2H])c([2H])c4c3[2H])c([2H])c([2H])c2c1[2H]]

Di(naphthalen-2-yl) methane-d₁₄ was prepared by modifying the procedure described in X. Liang, S. Duttwyler, Asian J. Org. Chem. 2017, 6, 1063. A flame dried 100 mL glass vial was charged with non-deuterated di(naphthalen-2-yl) methane (2.5 g, 9.32 mmol), C6D₆ (99.5% D, 37.3 mL, 0.25 M), and perfluorobutanesulfonic acid (0.15 mL, 0.93 mmol, 10 mol %). The mixture was cooled to 0° C. and sparged with argon for 5 min. The vial was sealed with a PTFE-lined screw cap and the reaction mixture was stirred at 70° C. for 2 days. The reaction was allowed to cool to RT and quenched with D₂O (4 mL). Saturated aqueous NaHCO₃ solution (50 mL) was added, and the mixture was transferred to a separation funnel. The organic layer was separated, and the aqueous layer was extracted with Et₂O (3×5 mL). The combined organic layers were dried over Na₂SO₄, and the solvent was removed under reduced pressure. The as obtained crude product (2.38 g, 91%, 93-94% D determined by internal standard mesitylene) was resubjected to a second deuteration cycle using the same reaction conditions as described above. The crude product resulting from the second cycle was recrystallized from hot n-hexane (20 mL) to give the product as colorless crystals (2.15 g, 82%, 98.5% D determined by internal standard mesitylene). The following physical, chemical, and spectroscopic parameters were obtained. Rf (SiO₂, 10% CH₂Cl₂/hexane)=0.43; Mp. 92.4-93.7° C.; ¹H NMR (400 MHZ, CDCl₃): δ 7.87 (s, residual H), 7.84 (s, residual H), 7.83 (s, residual H), 7.75 (s, residual H), 7.51 (s, residual H), 7.49 (s, residual H), 7.42 (s, residual H) ppm; ¹³C UDEFT NMR (151 MHz, CDCl₃): δ 138.4 (s), 133.6 (s), 132.1 (s), 128.1 (s, residual C—H), 127.77 (t, J^{l}_{c-D}=24.3 Hz), 127.71 (s, residual C—H), 127.4 (t, J^{l}_{c-D}=24.1 Hz), 127.3 (t, J^{l}_{C-D}=24.3 Hz), 127.2 (t, J^{l}_{c-D}=25.2 Hz), 127.0 (t, J^{l}_{c-D}=23.9 Hz), 125.9 (s, residual C—H), 125.6 (t, J^{l}_{c-D}=24.0 Hz), 125.3 (s, residual C—H), 125.0 (t, J^{l}_{C-D}=24.3 Hz) ppm, 42.2 ppm (three residual C—H signals not observed due to overlap); IR (ATR): v̅ 2901 (w), 2271 (w), 1604 (w), 1555 (w), 1438 (m), 1410 (m), 1251 (m) 905, m), 837 (m), 738 (m), 702 (m), 651 (m), 584 (s) cm⁻¹

c) formation of di(naphthalen-2-yl) methanone-d₁₄

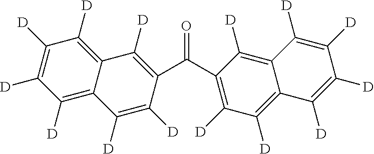 [SMILES: [2H]c1c([2H])c([2H])c2c([2H])c(C(=O)c3c([2H])c([2H])c4c([2H])c([2H])c([2H])c([2H])c4c3[2H])c([2H])c([2H])c2c1[2H]]

Di(naphthalen-2-yl) methanone-d₁₄ was prepared by modifying the procedure described in J. Zhang, Z. Wang, Y. Wang, C. Wan, X. Zheng, Z. Wang, Green Chem. 2009, 11, 1973. Di(naphthalen-2-yl) methane-d₁₄ (1.33 g, 4.73 mmol), iodine (60.0 mg, 0.24 mmol. 0.05 equiv.), pyridine (20.0 μL, 24.0 mmol, 0.05 equiv.), aqueous tert-butylhydroperoxide (70% in H₂O, 3.48 mL, 18.9 mmol, 4 equiv.), and acetonitrile (23.7 mL, 0.2 M) were sealed in a 15 mL high pressure tube and stirred at 80° C. for 16 h. After cooling to RT, water (20 mL) and the tan precipitate was filtered off and washed with water and small amounts of cold methanol. The crude product was purified by flash chromatography (Si₂O, 20%-80% CH₂Cl₂/cyclohexane) to obtain a colorless microcrystalline solid (1.15 g, 83%). The following physical, chemical, and spectroscopic parameters were obtained. Rf (SiO₂, CH₂Cl₂)=0.82; Mp. 167.3-167.5° C.; ¹H NMR (400 MHZ, CDCl₃): δ 8.34 (s, residual H), 8.01 (s, residual H), 8.00 (s, residual H), 7.95 (s, residual H), 7.94 (s, residual H), 7.64 (s, residual H), 7.58 (s, residual H) ppm; ¹³C UDEFT NMR (151 MHZ, CDCl₃): δ 196.9 (s), 135.3 (s), 135.1 (s), 132.3 (s), 131.9 (s, residual C—H), 131.6 (t, J^{l}_{C-D}=24.5 Hz), 129.4 (s, residual C—H), 129.1 (t, J^{l}_{c-D}=24.3 Hz), 128.22 (s, residual C—H), 128.16 (s, residual C—H), 128.0 (t, J^{l}_{c-D}=24.5 Hz), 127.9 (t, J^{l}_{c-D}=24.3 Hz), 127.5 (t, J^{l}_{c-D}=24.3 Hz), 126.7 (s, residual C—H), 126.5 (t, J^{l}_{c-D}=24.3 Hz), 125.9 (s, residual C—H), 125.6 (t, J^{l}_{C-D}=24.8 Hz) ppm; IR (ATR): D 2271 (w), 1648 (s), 1597 (m), 1541 (m), 1388 (m), 1213 (m), 1068 (m), 1009 (m), 919 (w), 779 (s), 733 (m), 705 (m), 684 (m), 650 (m), 637 (s), 605 (m), 573 (m) cm⁻¹.

d) formation of (di(naphthalen-2-yl)methylene) hydrazine-d₁₄

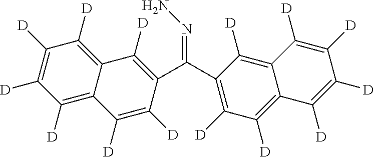 [SMILES: [2H]c1c([2H])c([2H])c2c([2H])c(C(=NN)c3c([2H])c([2H])c4c([2H])c([2H])c([2H])c([2H])c4c3[2H])c([2H])c([2H])c2c1[2H]]

(Di(naphthalen-2-yl)methylene) hydrazine-d₁₄ was prepared by modifying the procedure described in E. Schmitt, G. Landelle, J.-P. Vors, N. Lui, S. Pazenok, F. R. Leroux, Eur. J. Org. Chem. 2015, 2015, 6052. A mixture of di(naphthalen-2-yl) methanone-d₁₄ (0.30 g, 1.01 mmol), hydrazine hydrate (69.0 μL, 1.41 mmol, 1.40 equiv.), and EtOH (anhydrous, 0.94 mL, 1.5 M) was heated to 160° C. for 12 h in a high pressure vessel that was sealed with a PTFE-lined screw cap. The mixture was left to cool to RT over 1 h and stored at 7° C. for another 2 h. The colorless needles formed were filtered off and washed with cold EtOH to yield the product (0.21 g, 67%). The following physical, chemical, and spectroscopic parameters were obtained. Rf (SiO₂, CH₂Cl₂/hexane)=0.16; Mp. 151.2-151.5° C.; ¹H NMR (600 MHZ, CDCl₃): 0 8.09 (s, residual C—H), 8.09 (s, residual C—H, 0.011 H), 8.08 (s, residual C—H, 0.011 H), 8.00 (s, residual C—H, 0.011 H), 7.95 (s, residual C—H, 0.011 H), 7.93 (s, residual C—H, 0.012 H), 7.86 (s, residual C—H, 0.011 H), 7.85 (s, residual C—H, 0.011 H), 7.67 (s, residual C—H, 0.011 H), 7.64 (s, residual C—H, 0.011 H), 7.61 (s, residual C—H, 0.012 H), 7.59 (s, residual C—H, 0.011 H), 7.47 (s, residual C—H, 0.011 H), 7.46 (s, residual C—H, 0.012 H), 7.42 (s, residual C—H, 0.011 H), 5.60 (s, 2H) ppm. ¹³C UDEFT NMR (151 MHz, CDCl₃): δ 149.2 (s), 136.1 (s), 133.5 (s), 133.4 (s), 133.3 (s), 133.1 (s), 130.3 (s), 129.4 (s, residual C—H), 129.1 (t, J^{l}_{c-D}=24.5 Hz), 128.6-127.0 (m), 127.0-125.3 (m), 123.7 (s), 123.4 (t, J^{l}_{C-D}=24.0 Hz) ppm; IR (ATR): 3324 (m), 3185 (w), 2259 (w), 1621 (w), 1578 (m), 1438 (w), 1402 (w), 1375 (w), 1341 (w), 1306 (w), 1254 (m), 1145 (m), 1090 (m), 1062 (m), 991 (m), 931 (m), 868 (m), 846 (m), 832 (m), 809 (m), 799 (m), 777 (m), 758 (m), 732 (s), 704 (w), 665 (w), 647 (m), 583 (m) cm⁻¹.

e) formation of 2,2′-(diazomethylene)dinaphthalene-d₁₄

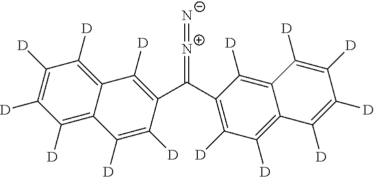 [SMILES: [2H]c1c([2H])c([2H])c2c([2H])c(C(=[N+]=[N-])c3c([2H])c([2H])c4c([2H])c([2H])c([2H])c([2H])c4c3[2H])c([2H])c([2H])c2c1[2H]]

2,2′-(diazomethylene)dinaphthalene-d₁₄ was prepared by modifying the procedure described in M. I. Javed and M. Brewer, Org. Synth. 2008, 85, 189. Handling and isolation of the product was done under exclusion of daylight. To a solution of dimethylsulfoxide (47.8 μL, 53.0 g, 0.67 mmol, 1.10 equiv.) and tetrahydrofuran (anhydrous, 2.5 mL, 0.26 M) was added oxalyl chloride (55.1 μL, 82.0 mg, 0.64 mmol, 1.05 equiv.) in tetrahydrofuran (2.5 mL) at −55° C. over 5 min. The solution was maintained between −55° C. and −50° C. for 30 min while stirring and then cooled to −78° C. A mixture of (di(naphthalen-2-yl)methylene) hydrazine-d₁₄ (190 mg, 0.61 mmol, 1.00 equiv.) and triethylamine (0.18 mL, 0.13 g, 1.29 mmol, 2.10 equiv.) in tetrahydrofuran (2 mL) was added to the reaction solution over 5 min to provide a deep-red solution containing a copious white precipitate. The reaction mixture was maintained at −78° C. for 30 min, and then filtered while cold through a medium porosity sintered-glass funnel into round-bottom flask and the solid was rinsed with tetrahydrofuran (2×3 mL). The filtrate was concentrated at room temperature by rotary evaporation. The red residue was redissolved in n-hexane (20 mL) and rapidly filtered through a plug of activated basic alumina supported in a medium porosity sintered glass funnel and the solids are rinsed with n-hexane (˜30 mL) until the filtrate was colorless. The filtrate was concentrated at room temperature by rotary evaporation (to ca. 20 mL) and stored at 7° C. overnight. The formed precipitate was filtered off and dried under vacuum to give the product as purple crystalline solid (53.0 mg, 28%). The following physical, chemical, and spectroscopic parameters were obtained. R/(Al₂O₃basic, hexane)=0.51; Mp. 134.0-134.2° C.; ¹H NMR (600 MHZ, CDCl₃): δ 7.90 (s, residual C—H), 7.84 (s, residual C—H), 7.81 (s, residual C—H) 7.77 (s, residual C—H) 7.49, (s, residual C—H), 7.47 (s, residual C—H), 7.46 (s, residual C—H) ppm; ¹³C UDEFT NMR (151 MHZ, CDCl₃): δ 133.9 (s), 131.7 (s), 128.9 (s), 128.6 (t, J^{l}_{C-D}=24.5 Hz), 127.7 (s), 127.4 (t, J^{l}_{c-D}=24.5 Hz) z, 126.98 (t, J^{l}_{C-D}=24.5 Hz), 126.95 (s), 126.6 (s), 126.3 (t, J^{l}_{C-D}=24.0 Hz), 125.3 (t, J^{l}_{c-D}=24.5 Hz), 123.4 (t, J^{l}_{c-D}=24.0 Hz), 123.1 (t, J^{l}_{C-D}=24.0 Hz) ppm; IR (ATR): v̅ 2267 (w), 2013 (s), 1600 (m), 1557 (m), 1442 (m), 1395 (m), 1323, (w), 1218 (m), 1029 (w), 872 (w), 853 (m), 831 (m), 727 (s), 644 (m), 616 (m), 602 (s), 579 (m) cm⁻¹.

f) Formation of dilute molecular crystals of 2,2′-(diazomethylene)dinaphthalene-d₁₄ in di(naphthalen-2-yl) methanone-d₁₄

Di(naphthalen-2-yl) methanone-d₁₄ (0.80 grams) was dissolved in hot ethyl acetate (HPLC grade, 90 mL, 0.030 M) and the solution was allowed to cool to RT. In the dark, to this solution, 2,2′-(diazomethylene)dinaphthalene-d₁₄ (4.5 milligrams, 5400 ppm) was added. Aliquots (5 milliliters, mL) of this resulting parent solution were added into 10 mL vials using a syringe equipped with a 0.45 μm pore size syringe filter and the vials were placed in a screw top jar filled with ethanol (HPLC grade). Dilute molecular crystals (parallelepiped ca. 3×3×4 mm) formed within storage in the dark at RT for 7 days. The crystals were isolated in the dark, washed with ethanol (HPLC grade) and dried in vacuum. The dilute molecular crystals could be stored in the freezer (T=−22° C.) in the dark for several months without detectable degradation.

To generate the di(napthalen-2-yl) carbene-d₁₄ dopant molecules in the di(naphthalen-2-yl) methanone-d₁₄ host material, the dilute molecular crystals of 2,2′-(diazomethylene)dinaphthalene-d₁₄ in di(napthalen-2-yl) methanone-d₁₄ need only be exposed to light of the correct wavelength, as described herein.

### Example 6: Synthesis of the Compounds Required to Embed di(phenyl) carbene-d₁₀ in di(phenyl) methanone-d₁₀

The synthetic route for formation of di(phenyl) carbene-d₁₀ dopant molecules in a di(phenyl) methanone-d₁₀ host material is shown below.

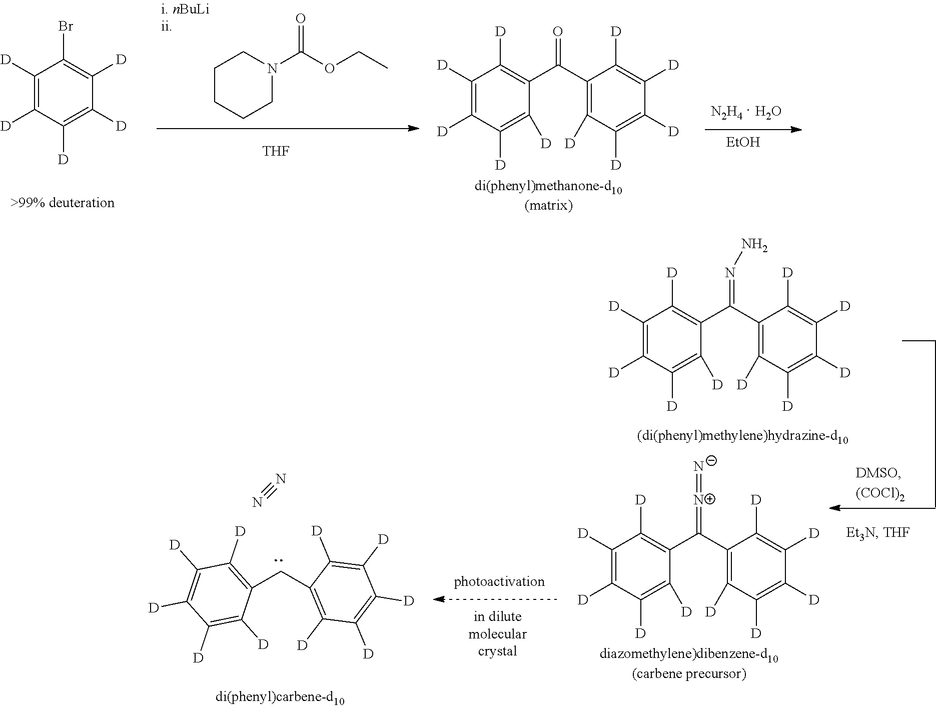

a) formation of di(phenyl) methanone-d₁₀

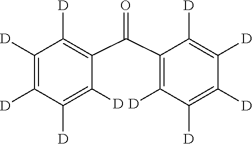 [SMILES: [2H]c1c([2H])c([2H])c(C(=O)c2c([2H])c([2H])c([2H])c([2H])c2[2H])c([2H])c1[2H]]

Di(phenyl) methanone-d₁₀ was prepared as follows. A solution of bromobenzene-d₅ (7.86 g, 48.5 mmol, 2.0 equiv., 99.5% D) in diethyl ether (anhydrous, 97 mL, 0.5 M) was cooled to 0° C. and n-butyllithium (2.5 M in hexanes, 20.3 mL, 2.1 equiv.) was added via dropping funnel within 5 min. The solution was stirred for 1 h at RT. To the resulting yellowish dispersion, a solution of N-carboethoxypiperidine (3.81 g, 24.3 mol, 1.00 equiv.) in diethyl ether (anhydrous, 20 mL) was added at 0° C. within 10 min. After the addition was complete the cooling bath was removed, and the reaction mixture was allowed to warm to RT within 30 min and stirred at RT for another 2 h. The reaction was quenched by addition of 10% aqueous HCl (150 mL). The organic phase was separated, and the aqueous phase extracted with diethyl ether (2×70 mL). The combined organic phases were washed with saturated sodium bicarbonate solution (50 mL), water (100 mL), and brine (80 mL), and then dried over MgSO₄. The solvent was removed under reduced pressure to give the crude product as an off-white solid. The product was obtained by twofold recrystallization from hot n-hexane (2×40 mL) as colorless crystals (3.36 g, 72%, 99.5% D determined by internal standard ¹H NMR with mesitylene). The following physical, chemical, and spectroscopic parameters were obtained. Rf (SiO₂, 40% CH₂Cl₂/hexane)=0.30; Mp. 49.8-50.3° C.; ¹H NMR (400 MHZ, CDCl₃): d 7.82 (s, residual H), 7.60 (s, residual H), 7.49 (s, residual H) ppm; ¹³C UDEFT NMR (151 MHz, CDCl₃): δ 196.8 (s), 137.6 (s), 132.2 (t, J^{l}_{c-D}=24.3 Hz), 129.8 (t, J^{l}_{c-D}=24.7 Hz), 127.9 (t, J^{l}_{C-D}=24.7 Hz) ppm; IR (ATR): ˜ 2291 (w), 2265 (w), 1646 (s), 1558 (m), 1385 (s), 1332 (m), 1216 (s), 954 (m), 912 (s), 821 (m), cm⁻¹

b) formation of (di(phenyl)methylene) hydrazine-d₁₀

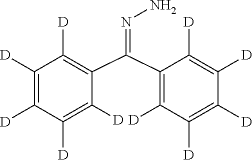 [SMILES: [2H]c1c([2H])c([2H])c(C(=NN)c2c([2H])c([2H])c([2H])c([2H])c2[2H])c([2H])c1[2H]]

(Di(phenyl)methylene) hydrazine-do was prepared by modifying the procedure described in E. Schmitt, G. Landelle, J.-P. Vors, N. Lui, S. Pazenok, F. R. Leroux, Eur. J. Org. Chem. 2015, 2015, 6052.

A mixture of di(phenyl) methanone-d₁₀ (0.50 g, 2.60 mmol), hydrazine hydrate (0.18 mL, 3.64 mmol, 1.40 equiv.), and EtOH (0.9 mL, 4.0 M) was heated to reflux for 12 h. The mixture was left to cool to RT over 1 h and stored at 7° C. for another 3 h. The colorless needles formed were recrystallized from EtOH (anhydrous, 1.0 mL), filtered, and dried in vacuo, to yield the product (0.43 g, 80%, 99.5% D determined by internal standard 1H NMR with mesitylene). The following physical, chemical, and spectroscopic parameters were obtained. Rf (SiO₂, CH₂Cl₂)=0.31; Mp. 98.5-100.4° C.; ¹H NMR (400 MHZ, CDCl₃): δ 7.53 (m, residual H), 7.47 (m, residual H), 7.29 (m, residual H) ppm; ¹³C UDEFT NMR (151 MHz, CDCl₃): δ 149.3 (s), 138.4 (s), 132.9 (s), 129.0 (t, J^{l}_{c-D}=24.4 Hz), 128.5 (t, J^{l}_{c-D}=24.4 Hz), 127.74 (t, J^{l}_{c-D}=24.4 Hz), 127,72 (t, J^{l}_{c-D}=24.4 Hz), 126.2 (t, J^{l}_{c-D}=24.4 Hz) ppm (one set of triplets overlapping at 129.0 ppm); IR (ATR): v̅ 3419 (m), 3266 (w), 2273 (w), 1609 (m), 1578 (m), 1554 (m), 1320 (m), 1290 (m), 1144 (m), 1059 (m), 1024 (w), 930 (m), 818 (m) cm⁻¹

c) formation of (diazomethylene)dibenzene-d₁₀

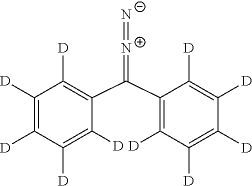 [SMILES: [2H]c1c([2H])c([2H])c(C(=[N+]=[N-])c2c([2H])c([2H])c([2H])c([2H])c2[2H])c([2H])c1[2H]]

(Diazomethylene)dibenzene-d₁₀ was prepared by modifying the procedure described in M. I. Javed and M. Brewer, Org. Synth. 2008, 85, 189. Handling and isolation of the product was done under exclusion of daylight. To a solution of dimethylsulfoxide (0.15 mL, 0.17 g, 2.13 mmol, 1.10 equiv.) and tetrahydrofuran (anhydrous, 17 mL, 0.13 M) was added oxalyl chloride (0.17 mL, 0.26 g, 2.04 mmol, 1.05 equiv.) in tetrahydrofuran (4 mL) at −55° C. over 5 min. The solution was maintained between −55° C. and −50° C. for 30 min while stirring and then cooled to −78° C. A mixture of di(phenyl)methylene) hydrazine-d₁₀ (0.40 g, 1.94 mmol, 1.00 equiv.) and triethylamine (0.56 mL, 0.41 g, 4.07 mmol, 2.10 equiv.) in tetrahydrofuran (10 mL) was added to the reaction solution over 5 min to provide a deep-red solution containing a copious white precipitate. The reaction mixture was maintained at −78° C. for 30 min, and then filtered while cold through a medium porosity sintered-glass funnel into round-bottom flask and the solid was rinsed with tetrahydrofuran (2×50 mL). The filtrate was concentrated at RT by rotary evaporation. The red residue was redissolved in n-pentane (20 mL) and rapidly filtered through a plug of activated basic alumina supported in a medium porosity sintered glass funnel and the solids were rinsed with n-pentane (˜50 mL) until the filtrate is colorless. The filtrate was concentrated at RT by rotary evaporation to provide 1,1′-(diazomethylene)dibenzene-d₁₀ (0.25 g, 63%) as an analytically pure violet liquid which solidified upon storage at 7° C. to a crystalline solid. The following physical, chemical, and spectroscopic parameters were obtained. Rf (Al₂O₃ basic, hexane)=0.93; Mp. 30.3-30.8° C.; UVvis (CH₂Cl₂): λₘₐₓ (, M⁻¹ cm⁻¹) 290 (20800) nm; ¹H NMR (400 MHZ, CDCl₃): 7.42 (s, residual H), 7.34 (s, residual H), 7.22 (m, residual H) ppm; ¹³C UDEFT NMR (151 MHZ, CDCl₃): δ 129.5 (s), 128.8 (t, J^{l}_{c-D}=24.5 Hz), 125.2 (t, J^{l}_{c-D}=24.6 Hz), 124.9 (t, J^{l}_{c-D}=24.2 Hz) ppm (one set of triplets overlapping at 129.0 ppm); IR (ATR): v̅ 2269 (w), 2028 (s), 1556 (m), 1404 (m), 1376 (m), 1238 (m), 1068 (w), 916 (w), 823 (m), 755 (m), cm⁻¹.

d) Formation of dilute molecular crystals of (diazomethylene)dibenzene-d₁₀ in di(phenyl) methanone-d₁₀

Di(phenyl) methanone-d₁₀ (0.30 grams, purified by sublimation) was dissolved in hot n-pentane (HPLC grade, 7.8 milliliter, 0.20 M) and the solution was allowed to cool to RT. In the dark, to this solution (diazomethylene)dibenzene-d₁₀ (0.08 mg, 247 ppm) was added. Aliquots (1.0 milliliters, mL) of this resulting parent solution were added into 3.0 mL vials and sealed with a punctuated screw cap. Dilute molecular crystals (ca. 3×5×4 mm) formed upon storage in the dark at 7° C. for 12 days. The crystals were isolated in the dark, washed with cold n-pentane (HPLC grade) and dried in vacuum. The dilute molecular crystals could be stored in the freezer (T=−22° C.) in the dark for several months without detectable degradation.

To generate the di(phenyl) carbene-d₁₀ dopant molecules in the di(phenyl) methanone-d₁₀ host material, the dilute molecular crystals of 1,1′-(diazomethylene)dinbenzene-d₁₀ in di(phenyl) methanone-d₁₀ need only be exposed to light of the correct wavelength, as described herein.

### Example 7: Synthesis of the Compounds Required to Embed di(naphthalen-2-yl) carbene-¹³c-d₁₄ in di(naphthalen-2-yl) methanone-¹³c-d₁₄

The synthetic route for formation of di(napthalen-2-yl) carbene-¹³C-d₁₄ dopant molecules in a di(naphthalene-2-yl) methanone-¹³C-d₁₄ host material is shown below.

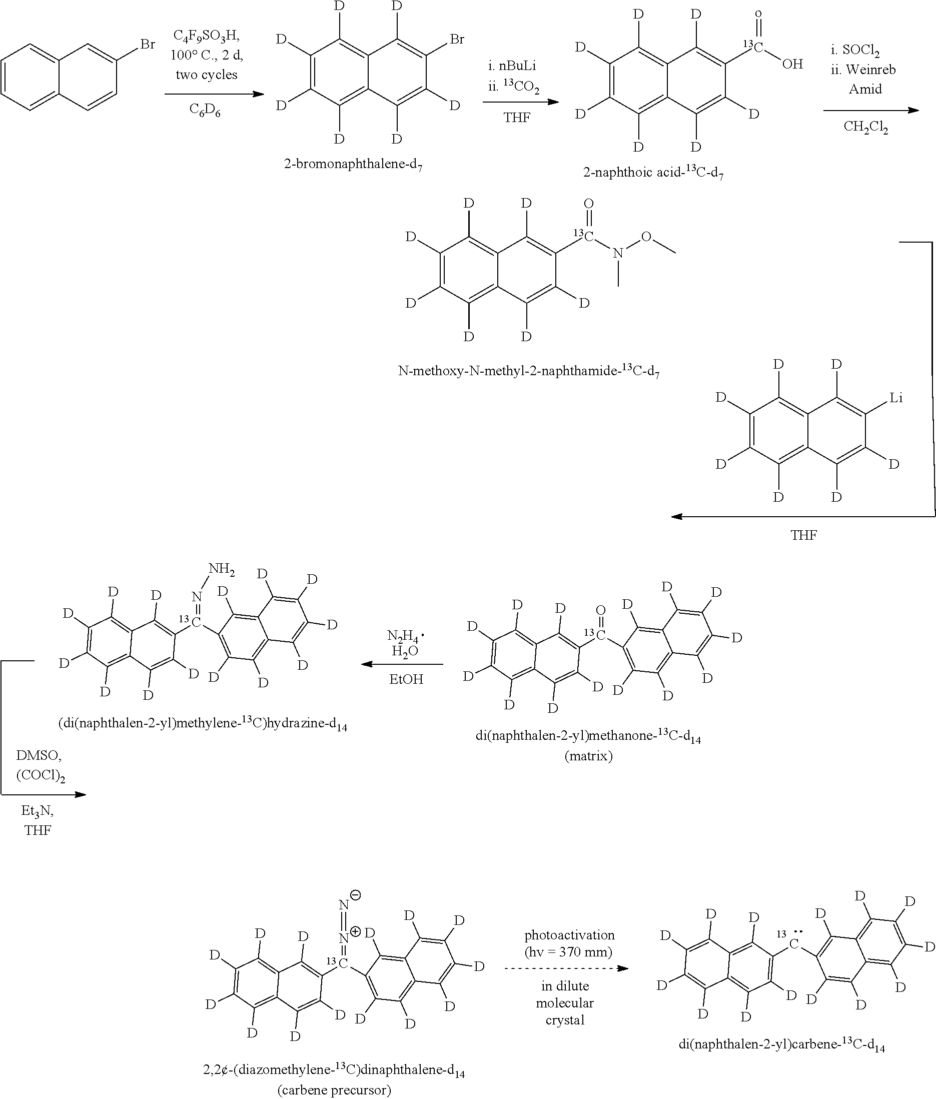

a) formation of 2-bromonaphthalene-d₇

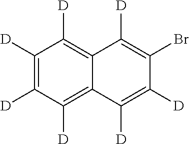 [SMILES: [2H]c1c([2H])c([2H])c2c([2H])c(Br)c([2H])c([2H])c2c1[2H]]

2-bromonaphthalene-d₇ was prepared by modifying the procedure described in X. Liang, S. Duttwyler, Asian J. Org. Chem. 2017, 6, 1063. A flame dried 350 mL high pressure reaction vessel was charged with 2-bromonaphthalene (5.0 g, 24.1 mmol), C₆D₆ (99.5% D, 80.5 mL, 0.3 M), and perfluorobutanesulfonic acid (0.40 mL, 2.41 mmol, 10 mol %) and a stir bar. The mixture was cooled to 0° C. and sparged with argon for 5 min. The vial was sealed with a PTFE-lined screw cap and the reaction mixture was stirred at 130° C. for 2 days. The reaction was allowed to cool to RT and quenched with D₂O (4 mL). Saturated aqueous NaHCO₃ solution (50 mL) was added, and the mixture was transferred to a separation funnel. The organic layer was separated, and the aqueous layer was extracted with Et₂O (3×30 mL). The combined organic layers were dried over Na₂SO₄, and the solvent was removed under reduced pressure. The as obtained crude product (4.85 g, 94% yield, 95.0% D determined by internal standard mesitylene) was resubjected to a second deuteration cycle using the same reaction conditions as described above. The crude product resulting from the second cycle was purified by sublimation (2.6×10⁻² mbar, 60° C.) to give a colorless microcrystalline solid (4.71 g, 91% yield, 98.8% D determined by internal standard mesitylene). The following physical, chemical, and spectroscopic parameters were obtained. Rf (SiO₂, hexane)=0.68; Mp. 56.9-57.0° C.; 1H NMR (400 MHZ, CDCl₃): δ 8.02 (s, residual H), 7.82 (s, residual H), 7.76 (s, residual H), 7.72 (s, residual H), 7.55 (s, residual H), 7.51 (s, residual H), 7.50 (s, residual H) ppm; ¹³C UDEFT NMR (151 MHz, CDCl₃): δ 134.5 (s), 131.9 (s), 130.0 (s, residual CH), 129.7 (t, J^{l}_{c-D}=24.8 Hz), 129.6 (s, residual CH), 129.28 (s, residual CH), 129.26 (t, J^{l}_{c-D}=24.5 Hz), 129.0 (t, J^{l}_{c-D}=25.5 Hz), 127.9 (s, residual CH), 127.5 (t, J^{l}_{C-D}=24.4 Hz), 127.0 (s, residual CH), 126.7 (t, J^{l}_{c-D}=24.3 Hz), 126.5 (t, J^{l}_{c-D}=24.2 Hz), 126.2 (s, residual CH), 125.9 (t, J^{l}_{c-D}=24.5 Hz), 119.7 (s) ppm. IR (ATR): ˜ 2272 (w), 1626 (m), 1553 (m), 1448 (m), 1380 (w), 1247 (m), 1098 (w), 1004 (s), 886 (s), 784 (s), 710 (s), 653 (m), 591 (s) cm⁻¹.

b) formation of 2-naphthoic acid-¹³c-d₇

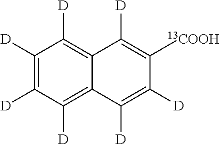

2-naphthoic acid-¹³C-d₇ was formed according to the following procedure. A solution of 2-lithium naphthalene-d₇ was prepared by slowly adding n-butyllithium (2.5 M in hexanes, 5.42 mL, 13.5 mmol, 1.00 equiv.) to a solution of 2-bromonaphthalene-d₇ (2.9 g, 13.5 mmol, 1.00 equiv.) in THF (54.1 mL, 0.25 M) at −78° C. The solution was stirred for 30 h at −78° C. Gaseous ¹³CO₂ (99.0% ¹³C, exc.) was slowly introduced via a gas inlet tube under Ar atmosphere at −78° C. until no blue color formation was observed any more. The solution was allowed to warm to RT for 2 h and subsequently quenched by addition of 1 M aqueous NaOH (20 mL) at RT. The aqueous layer was extracted with Et₂O (2×40 mL). To the aqueous layer was added 3 M HCl aqueous until pH<3, and the aqueous layer was extracted with Et₂O (2×40 mL). The combined organic phase was dried over Na₂SO₄ and concentrated. Trituration with hexane produced a white solid which was filtered off, washed with hexanes (30 mL), and dried under vacuum for 4 h to yield 2-naphthoic acid-¹³C-d₇ (1.90 g, 10.5 mmol, yield 78%). The following physical, chemical, and spectroscopic parameters were obtained. Rf (SiO₂, 10% MeOH/CH₂Cl₂)=0.75; Mp. 184.6-184.7° C.; ¹H NMR (600 MHz, DMSO-d₆): δ 13.05 (s, br, 1H), 8.61 (d, J_{C-H}=4.7 Hz, residual H), 8.12 (s, residual H), 8.01 (s, residual H), 8.00 (s, residual H), 7.98 (d, J_{C-H}=3.4 Hz, residual H), 7.65 (s, residual H), 7.60 (s, residual H) ppm; ¹³C UDEFT NMR (151 MHz, DMSO-d₆): δ 167.4, 134.7, 132.0 (d, J_{c-c}=4.9 Hz), 130.1 (t, J^{l}_{c-D}=24.7 Hz), 128.8 (t, J^{l}_{c-D}=24.5 Hz), 127.79 (t, J^{l}_{c-D}=23.8 Hz), 127.78 (d, J_{c-c}=71.3 Hz), 127.5 (s, residual CH), 127.1 (t, J^{l}_{c-D}=24.3 Hz), 126.5 (s, residual CH), 126.3 (t, J^{l}_{C-D}=24.0 Hz), 125.0 (s, residual CH), 124.7 (t, J^{l}_{C-D}=24.7 Hz) ppm; IR (ATR): ˜ 2893 (br), 2557 (w), 1642 (s), 1552 (m), 1415 (m), 1327 (m), 1262 (s), 1247 (m), 1122 (m), 932 (s), 867 (m), 840 (m), 741 (s), 690 (s) 650 (m), 576 (s), 533 (s) cm⁻¹.

c) Formation of N-methoxy-N-methyl-2-naphthamide-¹³C-d₇

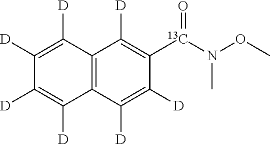 [SMILES: [2H]c1c([2H])c([2H])c2c([2H])c([13C](=O)N(C)OC)c([2H])c([2H])c2c1[2H]]

N-methoxy-N-methyl-2-naphthamide-¹³C-d₇ was formed according to the following procedure. 2-Naphthoic acid-¹³C-d₇ (1.85 g, 10.3 mmol, 1.00 equiv.) was dissolved in CH₂C₁₂ (anhydrous, 37.6 mL, 0.3 M) and one drop of DMF was added under Ar atmosphere. Then oxalyl chloride (0.97 mL, 1.10 equiv.) was added quickly and after 2 h of stirring, the solvent was evaporated under reduced pressure to yield the crude acyl chloride as an off-white solid. N,O-Dimethylhydroxylamine (1.16 g, 1.00 equiv.) was dissolved in CH₂Cl₂ (anhydrous, 37.6 mL, 0.3 M) under Ar atmosphere and cooled to 0° C. Triethylamine (3.31 mL, 2.0 equiv.) was added dropwise and stirred for 5 min at 0° C. The acyl chloride was redissolved CH₂Cl₂ (anhydrous, ca. 10.0 mL) and added dropwise to the amine solution. The solution was warmed to RT and stirred for 2 h. Then the reaction was quenched with HCl aq. (10 mL, 1.0 M) and transferred into a separatory funnel. The organic layer was separated and the aqueous phase extracted with CH₂Cl₂ (20 mL). The combined organic phases were washed with saturated aqueous NaHCO₃ (30 mL), water (20 mL), and brine (20 mL). After drying the organic phase over Na₂SO₄, all volatiles were removed under reduced pressure. The residue was purified by flash column chromatography (SiO₂, 20-50% ethyl acetate/hexanes) to give the product as a yellowish oil (2.01 g, 88%). The following physical, chemical, and spectroscopic parameters were obtained. R/(SiO₂, 50% EtOAc/hexane)=0.56; 1H NMR (600 MHZ, CDCl₃): δ 8.23 (d, J_{C-H}=4.4 Hz, residual H), 7.91 (s, residual H), 7.86 (s, residual H), 7.76 (d, J_{C-H}=3.3 Hz, residual H), 7.55 (s, residual H), 7.52 (s, residual H), 3.57 (s, 3H), 3.42 (d, J_{C-H}=2.1 Hz, 3H) ppm; ¹³C UDEFT NMR (151 MHz, CDCl₃): δ 170.1 (s), 134.2 (s, residual CH), 132.5 (d, J=4.6 Hz), 131.4 (d, J=67.5 Hz), 128.8 (s, residual CH), 128.5 (t, J^{l}_{c-D}=24.9 Hz), 127.8-126.7 (m, multiple CD and residual CH), 126.4 (s, residual CH), 126.1 (t, J^{l}_{c-D}=24.4 Hz), 125.1 (s, residual CH), 124.8 (t, J^{l}_{c-D}=25.1 Hz), 61.3 (s), 34.0 (s) ppm; IR (ATR): v̅ 2968 (w), 2993 (w), 2275 (w), 1593 (s), (w), 1410 (m), 1376 (m), 1352 (m), 1438 (m), 1182 (m), 1074 (m), 988 (m), 940 (m), 855 (m), 792 (m), 683 (m), 649 (m), 604 (m), 556 (m), 516 (m) cm⁻¹.

d) Formation of di(naphthalen-2-yl) methanone-¹³C-d₁₄

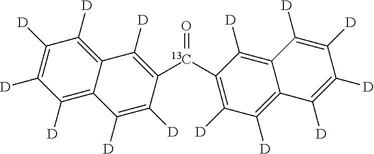 [SMILES: [2H]c1c([2H])c([2H])c2c([2H])c([13C](=O)c3c([2H])c([2H])c4c([2H])c([2H])c([2H])c([2H])c4c3[2H])c([2H])c([2H])c2c1[2H]]

Di(naphthalen-2-1) methanone-¹³C-d₁₄ was prepared according to the following procedure. A solution of 2-bromonaphthalene-d₇ (1.73 g, 8.08 mmol, 1.00 equiv.) in THF (anhydrous, 32.3 mL, 0.25 M) was cooled to −78° C. Then, n-butyllithium (2.5 M in hexanes, 3.56 mL, 1.10 equiv.) was added dropwise within 5 min so that the temperature did not exceed −70° C. and the solution was stirred for another 20 min at −78° C. The corresponding Weinreb amide N-methoxy-N-methyl-2-naphthamide-¹³C-d₇ (1.80 g, 8.08 mmol, 1.00 equiv,) was dissolved in THF (anhydrous, 10 mL) and added slowly to the lithiate solution. The mixture was stirred for 10 min at −78° C. before it was allowed to warm to RT within 2 h. The reaction was quenched by the addition of HCl aq. (10 mL, 1.0 M). The crude product was extracted with Et₂O (4×20 mL), and the combined organic layers were washed with saturated NaHCO₃ (30 mL), water (20 mL), and brine (20 mL). The solution was dried (MgSO₄), filtered, and the volatiles removed under reduced pressure. The crude product was dissolved in minimum amount of CH₂Cl₂ and triturated with methanol. The formed solid was filtered off and washed with methanol (30 mL) to obtain the product as a colorless microcrystalline solid (2.24 g, 93%). Analytically pure product was obtained by sublimation (165° C., 1.8·10⁻¹ mbar) as colorless crystals within 6 h. The following physical, chemical, and spectroscopic parameters were obtained. R/(SiO₂, CH₂Cl₂)=0.81; Mp. 167.6-167.9° C.; 1H NMR (400 MHZ, CDCl₃): δ 8.35 (d, J_{c-H}=4.4 Hz, residual H), 8.02 (d, J_{C-H}=3.2 Hz, residual H), 7.99 (s, residual H), 7.94 (d, J_{C-H}=7.4 Hz, residual H), 7.63 (s, residual H), 7.57 (s, residual H) ppm; ¹³C UDEFT NMR (151 MHz, CDCl₃): δ 135.3, 135.2 (d, J_{c-c}=55.2 Hz), 132.3 (d, J_{c-c}=4.4 Hz), 131.9 (s, residual C—H), 131.6 (t, J^{l}_{c-D}=24.3 Hz), 129.4 (s, residual C—H), 129.1 (t, J^{l}_{c-D}=24.4 Hz), 128.3 (d, J_{c-c}=3.9 Hz), 128.2 (t, J^{l}_{c-D}=24.4 Hz), 128.0 (td, J^{l}_{c-D}=24.4, J_{c-c}=3.1 Hz), 128.0 (t, J^{l}_{c-D}=24.2 Hz), 127.5 (t, J^{l}_{c-D}=24.4 Hz), 126.8 (s, residual C—H), 126.5 (t, J^{l}_{c-D}=24.5 Hz), 125.9 (s, residual C—H), 125.6 (t, J^{l}_{C-D}=24.6 Hz) ppm; IR (ATR): v̅ 2271 (w), 1619 (s), 1591 (s), 1540 (m), 1388 (m), 1315 (m), 1243 (w), 792 (s), 733 (m), 679 (m), 637 (m), 584 (s) cm⁻¹

e) Formation of (di(naphthalen-2-yl)methylene-¹³C) hydrazine-d₁₄

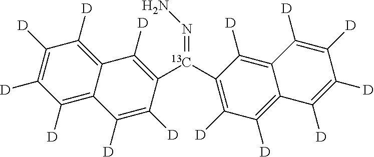 [SMILES: [2H]c1c([2H])c([2H])c2c([2H])c([13C](=NN)c3c([2H])c([2H])c4c([2H])c([2H])c([2H])c([2H])c4c3[2H])c([2H])c([2H])c2c1[2H]]

(Di(naphthalen-2-yl)methylene-¹³C) hydrazine-d₁₄ was prepared by modifying the procedure described in E. Schmitt, G. Landelle, J.-P. Vors, N. Lui, S. Pazenok, F. R. Leroux, Eur. J. Org. Chem. 2015, 2015, 6052. A mixture of di(naphthalen-2-yl) methanone-¹³C-d₁₄ (1.00 g, 3.36 mmol), hydrazine hydrate (0.23 mL, 4.71 mmol, 1.40 equiv.), and EtOH (anhydrous, 4.71 mL, 1.0 M) was heated to 160° C. for 12 h in a high pressure vessel that was sealed with a PTFE-lined screw cap. The mixture was left to cool to RT over 1 h and stored at 7° C. for another 2 h. The colorless needles formed were filtered off and washed with cold EtOH to yield the product (0.21 g, 67%). The following physical, chemical, and spectroscopic parameters were obtained. Rf (SiO₂, CH₂Cl₂/hexane)=0.15; Mp. 151.4-151.7° C.; ¹H NMR (600 MHZ, CDCl₃): 0 8.06 (s, residual H), 8.05 (d, J_{C-H}=3.2 Hz, residual H), 7.97 (s, residual H), 7.92 (s, residual H), 7.89 (d, J_{C-H}=3.8 Hz, residual H), 7.82 (s, residual H), 7.81 (s, residual H), 7.64 (s, residual H), 7.61 (s, residual H), 7.58 (s, residual H), 7.55 (d, J_{C-H}=5.3 Hz, residual H), 7.44 (d, J_{C-H}=2.9 Hz, residual H), 7.43 (s, residual H), 7.39 (s, residual H), 5.57 (d, J_{C-H}=6.9 Hz, 2H) ppm; ¹³C UDEFT NMR (151 MHz, CDCl₃): δ 149.3 (s), 136.1 (d, J_{c-c}=66.0 Hz), 133.6 (d, J_{c-c}=4.0 Hz), 133.4 (s), 133.3 (s), 133.2 (d, J_{c-c}=5.3 Hz), 130.3 (d, J_{c-c}=52.5 Hz), 129.5 (s, residual CH), 129.1 (t, J^{l}_{c-D}=24.4 Hz), 128.5-125.4 (m, multiple CD and residual CH signals), 123.7 (s, residual CH), 123.46 (t, J^{l}_{c-D}=24.7 Hz) ppm; IR (ATR): ˜ 3324 (m), 3182 (w), 2258 (w), 1620 (w), 1550 (m), 1438 (w), 1392 (w), 1335 (w), 1304 (w), 1252 (m), 1144 (m), 1088 (m), 1058 (m), 997 (m), 930 (m), 862 (m), 847 (m), 832 (m), 809 (m), 799 (m), 777 (m), 758 (m), 731 (s), 704 (w), 672 (w), 646 (m), 583 (m) cm⁻¹.

f) Formation of 2,2′-(diazomethylene-¹³C)dinaphthalene-d₁₄

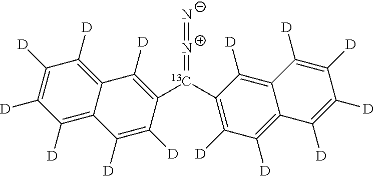 [SMILES: [2H]c1c([2H])c([2H])c2c([2H])c([13C](=[N+]=[N-])c3c([2H])c([2H])c4c([2H])c([2H])c([2H])c([2H])c4c3[2H])c([2H])c([2H])c2c1[2H]]

2,2′-(Diazomethylene-¹³C)dinaphthalene-d₁₄ was prepared by modifying the procedure described in M. I. Javed and M. Brewer, Org. Synth. 2008, 85, 189. Handling and isolation of the product was done under exclusion of daylight. To a solution of dimethylsulfoxide (0.10 mL, 0.11 g, 1.41 mmol, 1.10 equiv.) and tetrahydrofuran (anhydrous, 11.3 mL, 0.13 M) was added oxalyl chloride (0.12 mL, 0.17 g, 1.35 mmol, 1.05 equiv.) in tetrahydrofuran (5.0 mL) at −55° C. over 5 min. The solution was maintained between −55° C. and −50° C. for 30 min while stirring and then cooled to −78° C. A mixture of (di(naphthalen-2-yl)methylene-¹³C) hydrazine-d₁₄ (0.40 g, 1.28 mmol, 1.00 equiv.) and triethylamine (0.37 mL, 2.70 mmol, 2.10 equiv.) in tetrahydrofuran (3.0 mL) was added to the reaction solution over 5 min to provide a deep-red solution containing a copious white precipitate. The reaction mixture was maintained at −78° C. for 30 min, and then filtered while cold through a medium porosity sintered-glass funnel into round-bottom flask and the solid was rinsed with tetrahydrofuran (2×5 mL). The filtrate was concentrated at RT by rotary evaporation. The red residue was redissolved in n-hexane (20 mL) and rapidly filtered through a plug of activated basic alumina supported in a medium porosity sintered glass funnel and the solids were rinsed with n-hexane (˜50 mL) until the filtrate was colorless. The filtrate was concentrated at RT by rotary evaporation (to ca. 20 mL) and stored at 7° C. overnight. The formed precipitate was filtered off and dried under vacuum to give the product as purple crystalline solid (53.0 mg, 28%). The following physical, chemical, and spectroscopic parameters were obtained. Rf (Al₂O₃basic, hexane)=0.49; Mp. 134.3° C.; ¹H NMR (600 MHZ, C₆D₆): δ 7.66 (d, J_{C-H}=5.4 Hz, residual H), 7.60 (s, residual H), 7.58 (s, residual H), 7.46 (s, residual H), 7.28 (d, J_{C-H}=4.3 Hz, residual H) 7.23 (s, residual H), 7.22 (s, residual H) ppm; ¹³C UDEFT NMR (151 MHZ, C6D₆): δ 134.4 (d, J=5.2 Hz), 132.2 (s), 129.2 (d, J_{c-c}=4.8 Hz), 128.9 (t, J^{l}_{c-D}=24.2 Hz), 127.7 (t, J^{l}_{c-D}=24.2 Hz), 127.3 (t, J^{l}_{c-D}=24.4 Hz), 127.2 (d, J_{c-c}=68.1 Hz), 126.6, 126.3 (t, J^{l}_{C-D}=24.3 Hz), 125.6, 125.4 (t, J^{l}_{c-D}=24.5 Hz), 123.8, 123.6 (t, J^{l}_{c-D}=24.2 Hz), 123.5 (t, J^{l}_{c-D}=24.2 Hz), 63.5 (s) ppm; IR (ATR): ˜ 2267 (w), 2012 (s), 1600 (m), 1557 (m), 1439 (m), 1393 (m), 1322, (w), 1201 (m), 912 (w), 872 (w), 852 (m), 795 (m), 782 (m), 726 (s), 645 (m), 616 (m), 601 (s), 579 (m) cm⁻¹

g) Formation of dilute molecular crystals of (diazomethylene)dinaphthalene-¹³C-d₁₄ in di(naphthalen-2-yl) methanone-¹³C-d₁₄

Di(naphthalen-2-yl) methanone-¹³C-d₁₄ (0.80 grams) was dissolved in hot ethyl acetate (HPLC grade, 90 mL, 0.030 M) and the solution was allowed to cool to RT. In the dark, to this solution, 2,2′-(diazomethylene)dinaphthalene-¹³C-d₁₄ (4.5 milligrams, 5400 ppm) was added. Aliquots (5 milliliters, mL) of this resulting parent solution were added into 10 mL vials using a syringe equipped with a 0.45 μm pore size syringe filter and the vials were placed in a screw top jar filled with ethanol (HPLC grade). Dilute molecular crystals (parallelepiped ca. 3×3×4 mm) formed within storage in the dark at RT for 7 days. The crystals were isolated in the dark, washed with ethanol (HPLC grade) and dried in vacuum. The dilute molecular crystals could be stored in the freezer (T=−22° C.) in the dark for several months without detectable degradation.

To generate the di(napthalen-2-yl) carbene-¹³C-d₁₄ dopant molecules in the di(naphthalen-2-yl) methanone-¹³C-d₁₄ host material, the dilute molecular crystals of (diazomethylene)dinaphthalene¹³C-d₁₄ in di(napthalen-2-yl) methanone-¹³C-d₁₄ need only be exposed to light of the correct wavelength, as described herein.

### Example 8: X-Ray Crystal Structure of (diazomethylene)dinaphthalene embedded in di(naphthalen-2-yl) methanone

A dilute single crystal of 2,2′-(diazomethylene)dinaphthalene embedded in di(naphthalen-2-yl) methanone was grown by slow vapor diffusion of ethanol into a solution of a diluted solution of 2,2′-(diazomethylene)dinaphthalene (340 ppm) and di(naphthalen-2-y1) methanone (0.035 M)ethyl acetate at RT under exclusion of light within seven days. A suitable crystal was selected and mounted on a SuperNova, Dual, Cu using Cu-Kα radiation, λ=1.54178 Å, Atlas diffractometer. The crystal was kept at 150.00 (14) Kelvin during data collection. Using Olex2, the structure was solved with the XT structure solution program using Intrinsic Phasing and refined with the XL refinement package using least squares minimization. All non-H atoms were refined with anisotropic thermal parameters. H atoms in all structures were refined in calculated positions in a rigid group model. Table 1 shows the resulting crystal data. Due to the nature of the diffraction measurement only periodically assembled molecules (i.e., the host material) appear in the crystal structure, and the carbene precursor is not observed.

TABLE 1
Crystal data and structure refinement for a dilute
molecular crystal of 340 ppm 2,2′(diazomethylene)dinaphthalene
in di(naphthalen-2-yl)methanone

| | |
|---|---|
| Empirical formula | C₂₁H₁₄O |
| Formula weight | 282.32 |
| Temperature/K | 150.00(14) |
| Crystal system | Triclinic |
| Space group | P-1 |
| a/Å | 7.3689(4) |
| b/Å | 12.2023(6) |
| c/Å | 15.9898(11) |
| α/° | 100.979(5) |
| β/° | 96.779(5) |
| γ/° | 90.038(4) |
| Volume/Å³ | 1401.18(14) |
| Z | 4 |
| ρ_{calc}g/cm³ | 1.338 |
| μ/mm⁻¹ | 0.628 |
| F(000) | 592.0 |
| Crystal size/mm³ | 0.316 × 0.286 × 0.181 |
| Radiation | Cu Kα (λ = 1.54184) |
| 2Θ range for data | 7.382 to 145.982 |
| collection/° | |
| Index ranges | −8 ≤ h ≤ 9, −15 ≤ k ≤ 13, −19 ≤ l ≤ 19 |
| Reflections collected | 9762 |
| Independent reflections | 5418 [Rᵢₙₜ = 0.0245, R_{sigma} = 0.0306] |
| Data/restraints/parameters | 5418/0/398 |
| Goodness-of-fit (GooF) on | 1.057 |
| F^{2 (a)} | |
| Final R indexes | R₁ = 0.0542, wR₂ = 0.1768 |
| [I >= 2σ (I)] ^{(b)} | |
| Final R indexes [all data] | R₁ = 0.0852, wR₂ = 0.2075 |
| Largest diff. | 0.24/−0.17 |
| peak/hole/e Å⁻³ | |

^{(a)} GooF = [Σ[w(F²₀ − F²_{c})²/(n − p)]^{1/2} where n is the number of reflections and p is the total number of parameters refined.
^{(b)} R₁ = Σ∥F₀| − |F_{c}|/Σ|F₀|; wR₂ = [Σ[w(F²₀ − F²_{c})²]/Σ[w(F²₀)²]]^{1/2}

### Example 9: Generic Synthetic Route for the Formation of Nitrene Dopant Molecules

The general synthetic route for formation of nitrene dopant molecules in organic host materials is shown below.

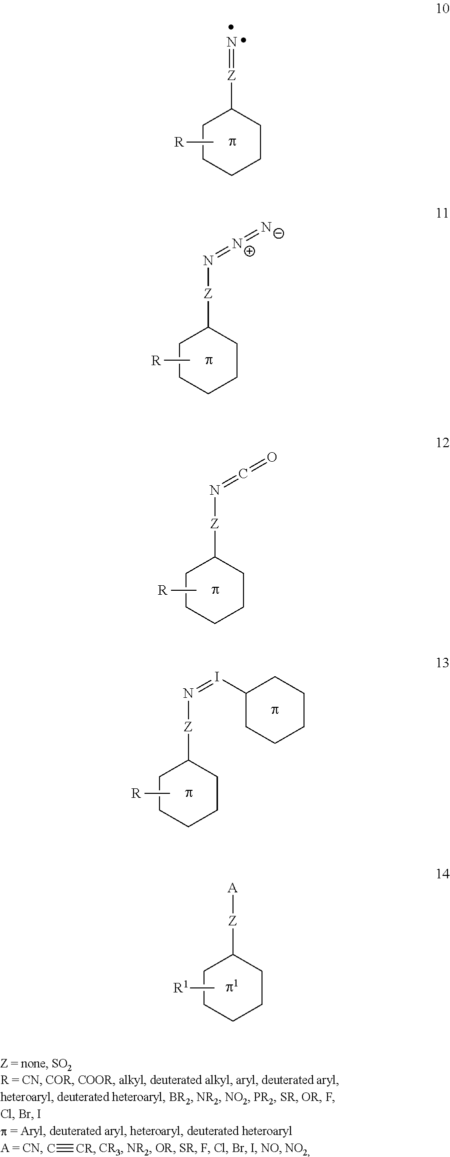

The nitrene materials are prepared following similar principles as those outlined for the preparation of carbenes above. That is, a photoactive nitrene precursor is embedded in an inert matrix (i.e., host material) by substitutional doping and the activated nitrene 10 is obtained after photolysis using an appropriate light source. The nitrene may be directly linked to an aryl group or via a sulfonyl group (—SO₂—) linker. Substituents at the nitrene aryl unit can be used to fine tune the thermodynamic/kinetic stability and the electronic properties. Here, again, one or more substituents R can be attached, such as one or more nitrile groups, carbonyl groups, carboxylic acid groups, ester groups, alkyl groups, aryl groups, heteroaryl groups, imine groups, amine groups, nitro groups, phosphine groups, alcohol groups, ether groups, thiol groups, thioether groups, or halogen groups. As in the case of carbenes, such groups may be selected (e.g., using computational molecular modeling, high-throughput synthesis and screening, or the like) to fine tune the electronic properties such as the ZFS, zero-phonon lines, spectral stability, and/or thermodynamic/kinetic stability.

The precursors to nitrenes (10) are aryl azides (—N₃, 11), aryl isocyanates (—NCO, 12), or iminoiodinanes (13). Each of these groups can be photolyzed with UV/vis light (2=200 to 500 nm) to obtain a nitrene and a molecule of dinitrogen N₂, carbon monoxide CO, or aryliodide, respectively.

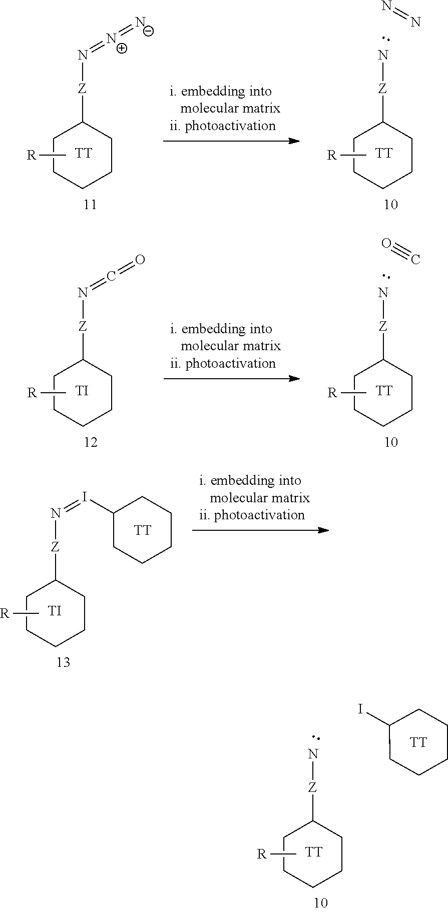

An exemplary route for embedding an aryl azide precursor (15) into a structurally related matrix (16) is shown below.

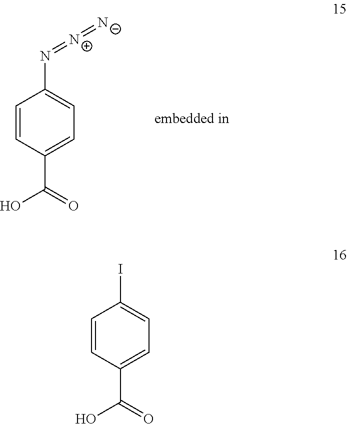 [SMILES: [N-]=[N+]=Nc1ccc(C(=O)O)cc1 ; O=C(O)c1ccc(I)cc1]

### Example 10: Formation of Dilute Molecular Crystals of 4-azidobenzoic acid in 4-iodobenzoic Acid

4-Iodobenzoic acid (1.00 grams) was dissolved in methanol (HPLC grade, 50 mL, 0.080 M) and the solution was allowed to cool to RT. In the dark, to this solution, 4-azidobenzoic acid (0.2 M in tert-butyl methyl ether, ≥95.0%, 130 μL, 6600 ppm) was added. Aliquots (8 milliliters, mL) of this resulting parent solution were added into 10 mL vials using a syringe equipped with a 0.20 μm pore size syringe filter and the vials were stored in the dark at room temperature for 4 days. Dilute molecular crystals (thin rectangular plates ca. 5× 10×0.01 mm) were isolated in the dark, washed with small amounts of cold methanol (HPLC grade) and dried in vacuum.

To generate the 4-nitrenebenzoic acid dopant molecules in the 4-iodobenzoic acid host material, the dilute molecular crystals of 4-azidobenzoic acid in 4-iodobenzoic acid need only be exposed to light of the correct wavelength, as described herein.

### Example 11: Optical Crystal Alignment for Characterization of Dopant Molecules in Host Materials

The chemical system created by embedding a dopant molecule (or a precursor thereto) in a host material may also be referred to herein as a “dilute molecular crystal.” The dilute molecular crystals exhibit intrinsic birefringence, i.e., are optically anisotropic. This property can be used to identify a set of axes of the material (i.e., the orthogonal axial system of the optical index ellipsoid axes n1, n2, and n3) for later alignment in experimental setups. A microscope in transmission mode with two crossed linear polarizers (denoted as polarizer and analyzer) can be used to identify such axes.

Here, an example is given of a typical configuration when the crystal is rotated in the field of view. Whenever the crossed polarizer axes are parallel with the vectors n1 and n2 (or more generally to their projections in the plane normal to the viewing direction), the crystal appears dark while in cases where the crystal is positioned at all other orientations some light will pass through the analyzer and the crystal displays variable degree of brightness. The maximum brightness for the birefringent material is observed when the polarizer and analyzer axes are at a 45° angle with respect to n1 and n2. This method can also be used to examine the crystal for microscopic imperfections, such as strain-induced extended effects (e.g., edge or screw dislocations).

### Example 12: Preparation, Photoactivation, and Annealing of Carbenes in Host Materials

After the crystal index ellipsoid has been determined macroscopically via the optical alignment method described above, a suitably sized crystal is prepared via micro-mechanic methods (e.g., doctor blade cleaving, diamond wire saw, etc.) from a raw crystal and, if needed, the surface is cleaved or polished with suitable organic solvents (e.g., hexane, pentane, ethanol, methanol). The prepared crystal is transferred to a suitable sample holder (e.g., electron paramagnetic resonance (EPR) tube, glass sample holder, etc.) and put into the device of interest (e.g., EPR, optical instrument) with an integrated cryostat. The specimen is cooled to temperatures at which the generated carbenes or nitrenes are stable (depends on the carbene or nitrene itself and the matrix). Using an integrated optical access such as an optical fiber or window the sample is irradiated with light (e.g., UV LED in a wavelength range between 300 and 400 nm) for a certain amount of time (depending on the light source output power, seconds to hours) in a macroscopic fashion to activate the complete sample. This process includes the conversion of the carbene or nitrene precursor molecules that have been embedded into a suitable matrix to their corresponding carbenes and one dinitrogen molecule (for nitrenes, carbon monoxide and aryl iodides are also possible). Alternatively, a focused laser beam which can be adjusted in lateral dimensions (x and y axis) can be used to activate regions of carbenes or nitrenes with dimensions >200 nm.

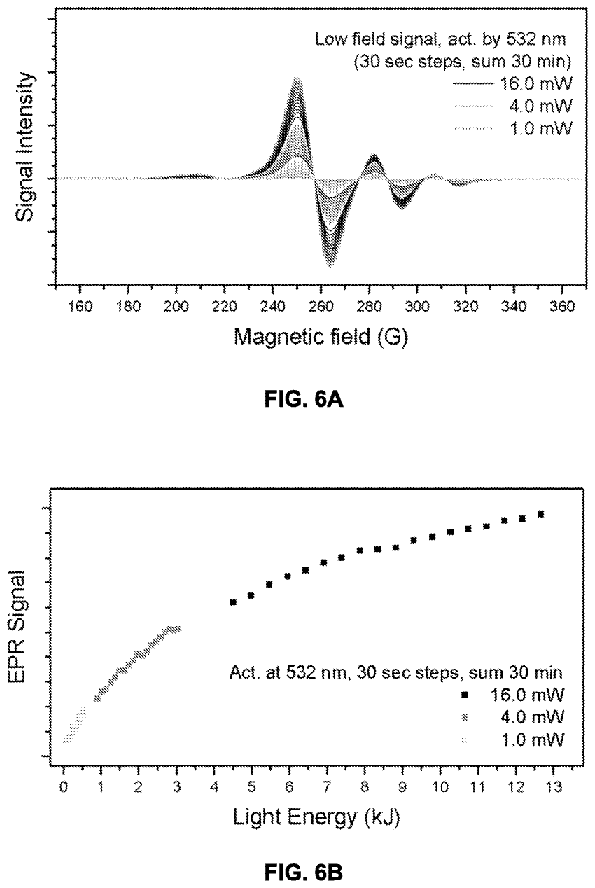

FIG. 6A shows exemplary continuous wave (cw) EPR signals associated with stepwise photoactivation of di(naphthalen-2-yl) carbene (500 ppm) in di(naphthalen-2-yl) methanone at a temperature of 25 K using a green laser (2=532 nm). The emergence of ground state triplet carbenes can be seen. FIG. 6B shows the double integral of the cw EPR signals from FIG. 6A as a function of the applied light energy and depicts the activation process for obtaining activated carbenes in a dilute molecular crystal. Such a plot can be used as a calibration curve for activating dopant molecules (e.g., carbene dopant molecules) in the dilute molecular crystals. By using such calibration curves (i.e., amount of carbenes activated per time of irradiation), a well-defined density of carbenes can be generated within a doped molecular crystal. Lithographic methods can be used to write patterns of qubits into the specimen (e.g., gradients, connected regions, lattices).

For very low temperatures (in some cases <140 K, for other samples below 260 K) carbenes and dinitrogen molecules are kinetically trapped within the matrix, such that the molecular geometries that are typical for carbenes cannot be adopted. An annealing procedure which includes warming the sample controllably to a specimen-dependent temperature (here 140 K, for other samples >50 K) over a sufficient amount of time (minutes to hours), triggers the reorientation of the activated carbenes and their direct molecular environment within dilute molecular crystals. The process can be monitored by cw EPR.

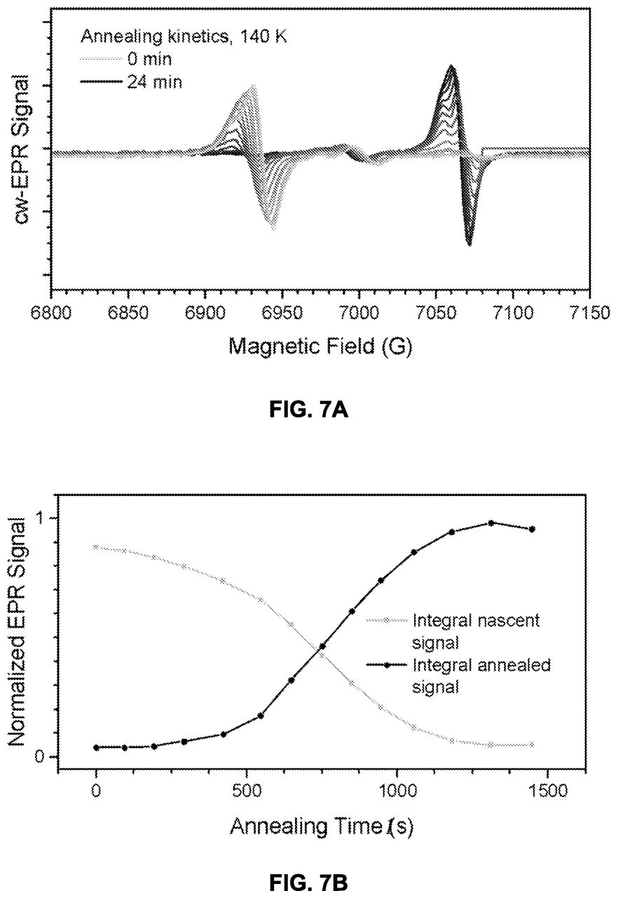

FIG. 7A shows exemplary cw EPR signals associated with the conversion of freshly photoactivated di(naphthalen-2-yl) carbene (340 ppm) in di(naphthalen-2-yl) methanone to an annealed form at a temperature of 140 K. The annealing process is observed as a disappearance of the cw EPR signals at 6925 G and the emergence of new signals at 7065 G. FIG. 7B shows the double integral of the cw EPR signals from FIG. 7A as a function of the annealing time. The process is typically accompanied by line sharpening and can, thus, be used to further control the inhomogeneous broadening within the specimen, required for efficient single molecule manipulation via optical control. FIG. 7B illustrates the emergence and disappearance of annealed and non-annealed signals, respectively, at specific times.

### Example 13: Spin-Lattice (T₁) and spin-Spin (T₂) relaxation times for di(Naphthalen-2-Yl) carbene-d₁₄ in di(Napthalen-2-Yl) methanone-d₁₄

Spin-lattice (T₁) relaxation times were measured for a sample of di(naphthalen-2-yl) carbene-d₁₄ (5400 ppm) in di(naphthalen-2-yl) methanone-d₁₄ at 466.6 mT where the magnetic field is approximately parallel to one principal axis of the zero-field splitting tensor B₀∥Dₓ. For the T₁ measurements, an inversion recovery sequence with Hahn echo-based detection (π-T-π/2-τ-π-τ-echo) was used. The measurements used rectangular 10 ns π/2 pulses and 20 ns π pulses and 16-step phase cycling. The data were fit using a stretched exponential function to extract an average and a maximum value of T₁. Deviations from monoexponential behavior of the recorded T₁ curves can be associated to the inhomogeneity of the microscopic spin environments in the sample, e.g., by the non-uniform distribution of the carbene spins. Briefly, a stretched exponential curve

$$exp - {( \frac{T}{{T}_{1 , char}} )}^{β}$$

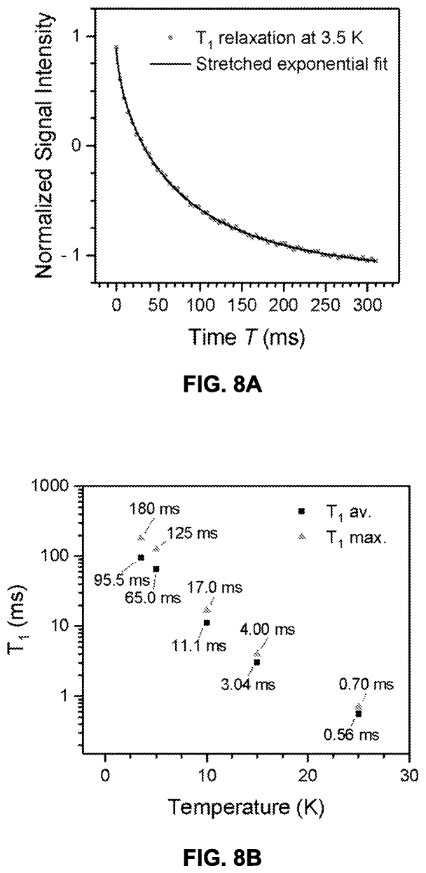

can be rewritten as a continuous distribution of monoexponential functions of which an average (T_{1.av}) and a most likely value (T_{1.max}) can be evaluated, dependent on T_{1.char} and the exponent beta. FIG. 8A shows an exemplary decay curve together with the stretched exponential fit curve used to extract the average and maximum T₁ times at a temperature of 3.5 K. FIG. 8B shows an exemplary plot of the temperature dependence of the average and most likely T₁ times in the temperature range of 3.5 K to 25 K.

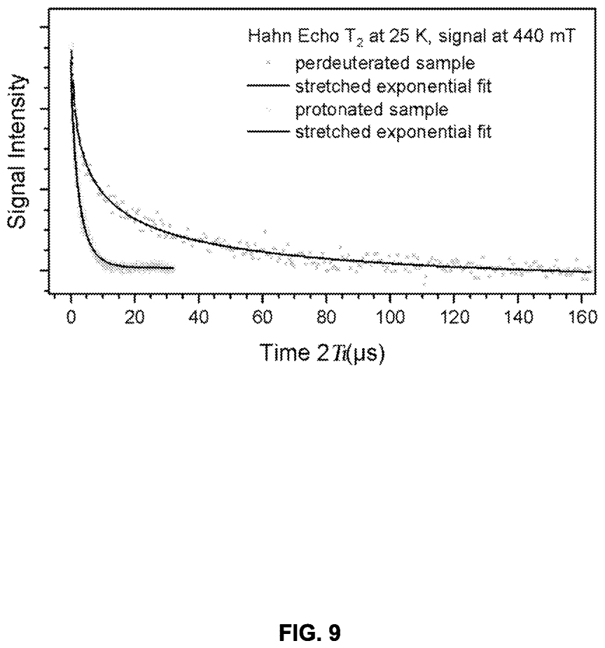

Spin-spin (T₂) relaxation times were measured using the Hahn echo pulse sequence (π/2-τ-π-τ-echo) and fit to a stretched exponential decay, analogous to the procedure described above. The measurements used rectangular 10 ns π/2 pulses and 20 ns π pulses and four-step phase cycle. FIG. 9 shows decay curves for protonated and deuterated dilute molecular crystals and highlights the drastic increase in T₂ upon perdeuteration of the dilute molecular crystal. As an example, a most likely T_{2.max} of 4.78 μs and an average T_{2.av} of 2.67 μs was observed for a protonated sample ((di(naphthalen-2-yl) carbene (5400 ppm) in di(naphthalen-2-yl) methanone), whereas a perdeuterated sample of di(naphthalen-2-yl) carbene-d₁₄ (5400 ppm) in di(naphthalen-2-yl) methanone-d₁₄ gave a most likely T_{2.max} of 53.6 μs and an average T_{2.av} of 16.0 μs. We note that distortions to the lineshapes of these spectra may occur due to inhomogeneous broadening and electron spin echo envelope modulation (ESEEM) effects arising from the coupling of the electronic spin to nearby hydrogen and deuterium nuclei, respectively.

### Example 14: Intermolecular Coupling Strengths for di(naphthalen-2-yl) carbene-d₁₄ in di(napthalen-2-yl) methanone-d₁₄

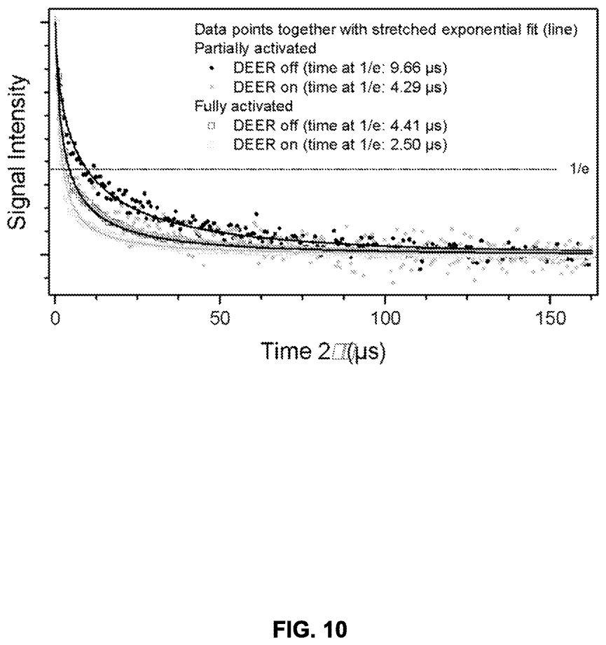

Double electron-electron resonance (DEER) experiments were conducted to probe the intermolecular coupling between the randomly distributed carbenes in the dilute molecular crystal. Echo-detected field swept spectra were collected using a Hahn echo pulse sequence with a fixed τ value while sweeping the magnetic field. A large coupling of 214.6 MHz observed for the crystal orientation B₀∥D_{y} was used due to hyperfine coupling (HFC) with the ¹³C carbene carbon to selectively address probe and pump pulses in the DEER experiments. A π pump pulse, optimized by an adiabatic inversion chirped pulse, flips the coupling partner and thus the probe spins experience an additional decoherence due to the static dipolar coupling to the pump spins throughout the whole evolution time of the sequence. As an example, FIG. 10 shows the decay of curves for experiments with pump pulse off and on together with the time elapsed for each decay where the initial signal had dropped to 1/e. The two sets refer to different photoactivation steps (partial and full activation) which additionally highlights the tunability of the intermolecular coupling.

### Example 15: Preparation, Photoactivation, and Annealing Nitrenes in Host Materials

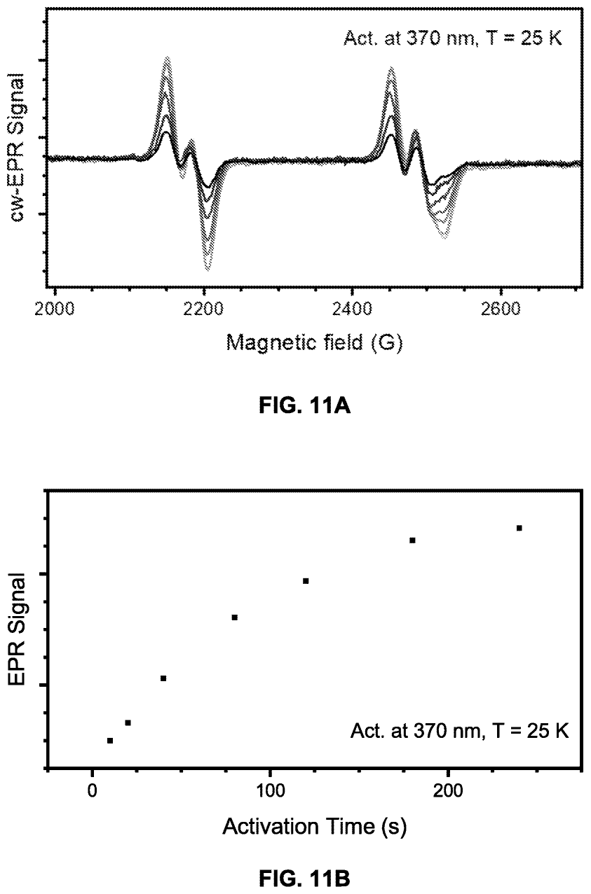

FIG. 11A shows exemplary continuous wave (cw) EPR signals associated with stepwise photoactivation of 4-nitrenebenzoic acid in 4-iodobenzoic acid at a temperature of 25 K using light with a wavelength of λ=370 nm. The emergence of ground state triplet nitrenes can be seen. FIG. 11B shows the double integral of the cw EPR signals from FIG. 11A as a function of the activation time and depicts the activation process for obtaining activated nitrenes in a dilute molecular crystal. Such a plot can be used as a calibration curve for activating dopant molecules (e.g., nitrene dopant molecules) in the dilute molecular crystals. By using such calibration curves (i.e., amount of nitrenes activated per time of irradiation), a well-defined density of nitrenes can be generated within a doped molecular crystal. Lithographic methods can be used to write patterns of qubits into the specimen (e.g., gradients, connected regions, lattices).

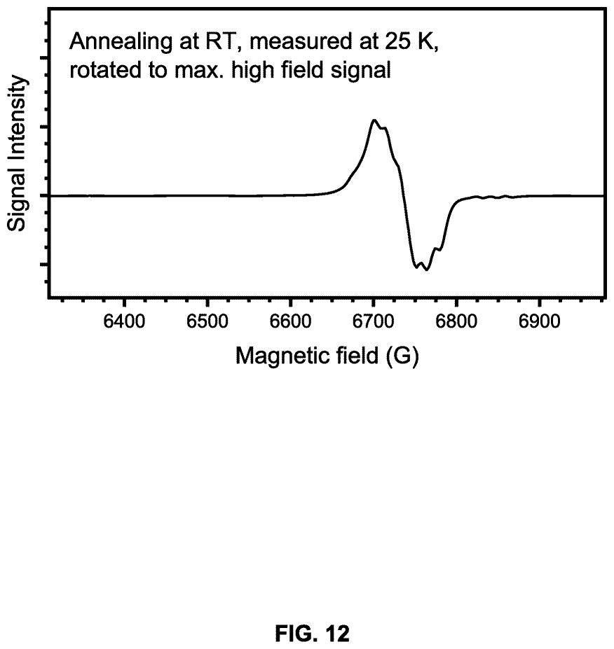

FIG. 12 shows an exemplary cw EPR signal associated with the conversion of freshly photoactivated 4-nitrenebenzoic acid in 4-iodobenzoic acid to an annealed form at RT.

The foregoing description has been presented for purposes of illustration. It is not exhaustive and is not limited to precise forms or embodiments disclosed. Modifications and adaptations of the embodiments will be apparent from consideration of the specification and practice of the disclosed embodiments. For example, the described implementations include hardware, but systems and methods consistent with the present disclosure can be implemented with hardware and software. In addition, while certain components have been described as being coupled to one another, such components may be integrated with one another or distributed in any suitable fashion.

Moreover, while illustrative embodiments have been described herein, the scope includes any and all embodiments having equivalent elements, modifications, omissions, combinations (e.g., of aspects across various embodiments), adaptations or alterations based on the present disclosure. The elements in the claims are to be interpreted broadly based on the language employed in the claims and not limited to examples described in the present specification or during the prosecution of the application, which examples are to be construed as nonexclusive. Further, the steps of the disclosed methods can be modified in any manner, including reordering steps or inserting or deleting steps.

The features and advantages of the disclosure are apparent from the detailed specification, and thus, it is intended that the appended claims cover all systems and methods falling within the true spirit and scope of the disclosure. As used herein, the indefinite articles “a” and “an” mean “one or more.” Similarly, the use of a plural term does not necessarily denote a plurality unless it is unambiguous in the given context. Further, since numerous modifications and variations will readily occur from studying the present disclosure, it is not desired to limit the disclosure to the exact construction and operation illustrated and described, and accordingly, all suitable modifications and equivalents may be resorted to, falling within the scope of the disclosure.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Other embodiments will be apparent from consideration of the specification and practice of the embodiments disclosed herein. It is intended that the specification and examples be considered as an example only, with a true scope and spirit of the disclosed embodiments being indicated by the following claims.

What is claimed is:

1. A method for generating a non-classical computer, comprising:
preparing at least one host material;
embedding at least one precursor to at least one dopant molecule in the at least one host material, the at least one precursor comprising at least one cleavable moiety;
cleaving the at least one cleavable moiety to thereby generate the at least one dopant molecule and at least one cleaved molecule in the at least one host material, wherein:
the at least one dopant molecule comprises a qubit having at least a first qubit state and a second qubit state;
the at least one dopant molecule is associated with an electronic energy level structure that includes a triplet electronic manifold;
the triplet electronic manifold comprises a first triplet state, a second triplet state, and a third triplet state;
the first qubit state comprises a first linear combination of the first triplet state, the second triplet state, and the third triplet state;
the second qubit state comprises a second linear combination of the first triplet state, the second triplet state, and the third triplet state; and
the first qubit state is different from the second qubit state.

2. The method of claim 1, wherein the at least one cleavable moiety comprises at least one photocleavable moiety.

3. The method of claim 1, wherein the at least one photocleavable moiety comprises at least one diazo, azido, isocyanato, or iminoiodinane moiety.

4. The method of claim 3, wherein the at least one cleaved molecule comprises at least one dinitrogen molecule, carbon monoxide molecule, or aryl iodide molecule.

5. The method of any one of claims 1-4, wherein cleaving the at least one cleavable moiety comprises exposing the at least one precursor to light.

6. The method of claim 5, wherein the light has a central wavelength between about 200 nanometers (nm) and about 500 nm.

7. The method of any one of claims 1-6, wherein the at least one dopant molecule comprises a plurality of dopant molecules.

8. The method of any one of claims 1-7, wherein the host material comprises at least one organic molecule.

9. The method of any one of claims 1-8, wherein the host material comprises a crystalline host material, a single crystalline host material, a polycrystalline host material, a liquid crystalline host material, a powder host material, an amorphous host material, or a frozen solution host material.

10. The method of any one of claims 1-9, wherein the host material comprises a C4-C20 linear or branched alkane; an aromatic hydrocarbon; a polyaromatic hydrocarbon optionally substituted with a methylene, nitrile, carbonyl, carboxylate, alkyl, deuterated alkyl, aryl, deuterated aryl, heteroaryl, deuterated heteroaryl, borane, imine, amine, nitro, phosphine, thioether, ether, fluoro, chloro, bromo, iodo, or thiocarbonyl group; a diarylketone; naphthalene; anthracene; pare-terphenyl; benzoic acid; fluorene; biphenyl; benzene; n-hexane; biphenylene; ortho-terphenylene; meta-terphenylene; para-terphenylene; phenanthrene; di(naphthalen-2-yl) methanone; di(phenyl) methanone; or any partially or fully isotopically labeled derivative thereof.

11. The method of any one of claims 1-10, wherein the host material comprises a thin film having a thickness of at most 100 nanometers (nm).

12. The method of any one of claims 1-11, wherein the at least one dopant molecule comprises an organic molecule.

13. The method of any one of claims 1-12, wherein the at least one precursor comprises a derivative of a carbene molecule; a derivative of a nitrene molecule; a diazo derivative of a carbene molecule; an azido derivative of a nitrene molecule; an isocyanato derivative of a nitrene molecule; an imidoiodinane derivative of a nitrene; (diazomethylene)dinaphthalene; (diazomethylene)dibenzene; 4-azidobenzoic acid; or any partially or fully isotopically labeled derivative thereof.

14. The method of any one of claims 1-13, wherein the at least one dopant molecule comprises a carbene molecule; a nitrene molecule; a di(napthalen-2-yl) carbene molecule; a di(phenyl) carbene molecule; or any partially or fully isotopically labeled derivative thereof.

15. The method of any one of claims 1-14, wherein the plurality of dopant molecules are arranged in a pseudo-two-dimensional (pseudo-2D) layer.

16. The method of claim 15, wherein the pseudo-2D layer comprises a self-assembled monolayer (SAM).

17. The method of any one of claims 1-16, wherein an average distance between dopant molecules is at most 20 nm.

18. The method of any one of claims 1-17, wherein the at least one dopant molecule is contained in the at least one host material at a concentration of at least 10⁶ dopant molecules per cubic micrometer (μm³).

19. The method of any one of claims 1-18, wherein:
the at least one dopant molecule comprises a plurality of dopant molecules;
a first dopant molecule of the plurality of dopant molecules is configured to absorb first electromagnetic energy having a first central wavelength or a first central frequency;
a second dopant molecule of the plurality of dopant molecules is configured to absorb second electromagnetic energy having a second central wavelength or a second central frequency; and
the first central wavelength or the first central frequency is different from the second central wavelength or the second central frequencies.

20. The method of claim 19, wherein:
the first central wavelength or the first central frequency is associated with a first range of wavelengths or a first range of frequencies having a first full width at half maximum (FWHM) bandwidth;
the second central wavelength or the second central frequency is associated with a second range of wavelengths or a second range of frequencies having a second FWHM bandwidth; and
the first range of wavelengths or the first range of frequencies within the first FWHM bandwidth and the second range of wavelengths or the second range of frequencies within the second FWHM bandwidth do not overlap.

21. The method of claim 20, wherein the first FWHM bandwidth or the second FWHM bandwidth is at most 100 megahertz (MHz).

22. The method of any one of claims 19-21, wherein the first central wavelength or the second central wavelength is between 200 nm and 1,000 nm.

23. The method of claim 21, wherein the first FWHM bandwidth or the second FWHM bandwidth is at most 100 gigahertz (GHz).

24. The method of claim 23, wherein the first central frequency or the second central frequency is between 1 MHz and 100 GHz.

25. The method of any one of claims 1-24, wherein the triplet electronic manifold comprises a ground state triplet (GST) electronic manifold.

26. A system for performing a non-classical computation, comprising:
at least one host material;
at least one dopant molecule contained in the at least one host material; and
at least one cleaved molecule contained in the at least one host material, wherein:
the at least one dopant molecule comprises a qubit having at least a first qubit state and a second qubit state;
the at least one dopant molecule is associated with an electronic energy level structure that includes a triplet electronic manifold;
the triplet electronic manifold comprises a first triplet state, a second triplet state, and a third triplet state;
the first qubit state comprises a first linear combination of the first triplet state, the second triplet state, and the third triplet state;
the second qubit state comprises a second linear combination of the first triplet state, the second triplet state, and the third triplet state; and
the first qubit state is different from the second qubit state.

27. The system of claim 26, wherein the at least one dopant molecule and the at least one cleaved molecule are generated by cleaving at least one precursor to the at least one dopant molecule, the at least one precursor comprising at least one cleavable moiety.

28. The system of claim 27, wherein the at least one cleavable moiety comprises at least one photocleavable moiety.

29. The system of claim 28, wherein the at least one photocleavable moiety comprises at least one diazo moiety, azido moiety, isocyanato moiety, or iminoiodinane moiety.

30. The system of claim 29, wherein the cleaved molecule comprises at least one dinitrogen molecule, carbon monoxide molecule, or aryl iodide molecule.

31. The system of any one of claims 27-30, wherein cleaving the at least one precursor comprises exposing the at least one precursor to light.

32. The system of claim 31, wherein the light has a central wavelength between about 200 nanometers (nm) and about 500 nm.

33. The system of any one of claims 26-32, wherein the at least one dopant molecule comprises a plurality of dopant molecules.

34. The system of any one of claims 26-33, wherein the host material comprises at least one organic molecule.

35. The system of any one of claims 26-34, wherein the host material comprises a crystalline host material, a single crystalline host material, a polycrystalline host material, a liquid crystalline host material, a powder host material, an amorphous host material, or a frozen solution host material.

36. The system of any one of claims 26-35, wherein the host material comprises a C4-C20 linear or branched alkane; an aromatic hydrocarbon; a polyaromatic hydrocarbon optionally substituted with a methylene, nitrile, carbonyl, carboxylate, alkyl, deuterated alkyl, aryl, deuterated aryl, heteroaryl, deuterated heteroaryl, borane, imine, amine, nitro, phosphine, thioether, ether, fluoro, chloro, bromo, iodo, or thiocarbonyl group; a diarylketone; naphthalene; anthracene; para-terphenyl; benzoic acid; fluorene; biphenyl; benzene; n-hexane; biphenylene; ortho-terphenylene; meta-terphenylene; para-terphenylene; phenanthrene; di(naphthalen-2-yl) methanone; di(phenyl) methanone; or any partially or fully isotopically labeled derivative thereof.

37. The system of any one of claims 26-36, wherein the host material comprises a thin film having a thickness of at most 100 nanometers (nm).

38. The system of any one of claims 26-37, wherein the at least one dopant molecule comprises an organic molecule.

39. The system of any one of claims 26-38, wherein the at least one precursor comprises a derivative of a carbene molecule; a derivative of a nitrene molecule; a diazo derivative of a carbene molecule; an azido derivative of a nitrene molecule; an isocyanato derivative of a nitrene molecule; an imidoiodinane derivative of a nitrene molecule; (diazomethylene)dinaphthalene; (diazomethylene)dibenzene; 4-azidobenzoic acid; or any partially or fully isotopically labeled derivative thereof.

40. The system of any one of claims 26-39, wherein the at least one dopant molecule comprises a carbene molecule; a nitrene molecule; a di(napthalen-2-yl) carbene molecule; a di(phenyl) carbene molecule; or any partially or fully isotopically labeled derivative thereof.

41. The system of any one of claims 26-40, wherein the plurality of dopant molecules are arranged in a pseudo-two-dimensional (pseudo-2D) layer.

42. The system of claim 41, wherein the pseudo-2D layer comprises a self-assembled monolayer (SAM).

43. The system of any one of claims 26-42, wherein an average distance between dopant molecules is at most 20 nm.

44. The system of any one of claims 26-43, wherein the at least one dopant molecule is contained in the at least one host material at a concentration of at least 10⁶ dopant molecules per cubic micrometer (μm³).

45. The system of any one of claims 26-44, wherein:
the at least one dopant molecule comprises a plurality of dopant molecules;
a first dopant molecule of the plurality of dopant molecules is configured to absorb first electromagnetic energy having a first central wavelength or a first central frequency;
a second dopant molecule of the plurality of dopant molecules is configured to absorb second electromagnetic energy having a second central wavelength or a second central frequency; and
the first central wavelength or the first central frequency is different from the second central wavelength or the second central frequencies.

46. The system of claim 45, wherein:
the first central wavelength or the first central frequency is associated with a first range of wavelengths or a first range of frequencies having a first full width at half maximum (FWHM) bandwidth;
the second central wavelength or the second central frequency is associated with a second range of wavelengths or a second range of frequencies having a second FWHM bandwidth; and
the first range of wavelengths or the first range of frequencies within the first FWHM bandwidth and the second range of wavelengths or the second range of frequencies within the second FWHM bandwidth do not overlap.

47. The system of claim 46, wherein the first FWHM bandwidth or the second FWHM bandwidth is at most 100 megahertz (MHz).

48. The system of any one of claims 45-47, wherein the first central wavelength or the second central wavelength is between 200 nm and 1,000 nm.

49. The system of claim 48, wherein the first FWHM bandwidth or the second FWHM bandwidth is at most 100 gigahertz (GHz).

50. The system of claim 49, wherein the first central frequency or the second central frequency is between 1 MHz and 100 GHz.

51. The system of any one of claims 26-50, wherein the triplet electronic manifold comprises a ground state triplet (GST) electronic manifold.

52. The system of any one of claims 26-51, further comprising at least one initialization unit configured to direct third electromagnetic energy to the at least one dopant molecule to thereby initialize a quantum state of the at least one dopant molecule into the first qubit state or the second qubit state.

53. The system of claim 52, wherein the third electromagnetic energy comprises at least one wavelength between 200 nm and 1,000 nm.

54. The system of any one of claims 26-53, further comprising at least one non-classical operation unit configured to apply fourth electromagnetic energy to the at least one dopant molecule to thereby perform at least one non-classical operation on the at least one dopant molecule.

55. The system of claim 54, wherein the at least one non-classical operation comprises at least one quantum operation, at least one quantum computing operation, at least one quantum gate operation, at least one quantum simulation operation, or at least one quantum annealing operation.

56. The system of claim 54 or 55, wherein the fourth electromagnetic energy comprises at least one frequency between 1 MHz and 100 GHz.

57. The system of any one of claims 54-56, wherein, subsequent to performing the at least one non-classical operation, a result of the at least one non-classical operation is correlated with an electronic state of the at least one dopant molecule.

58. The system of claim 57, further comprising at least one storage unit configured to apply fifth electromagnetic energy and sixth electromagnetic energy to the at least one dopant molecule, wherein the fifth electromagnetic energy and sixth electromagnetic energy are jointly configured to transfer information from the electronic state to a nuclear spin state of the at least one dopant molecule.

59. The system of claim 58, wherein the fifth electromagnetic energy and the sixth electromagnetic energy are configured to jointly apply a swap gate to the at least one dopant molecule to thereby transfer the information from the electronic state to the nuclear spin state of the at least one dopant molecule.

60. The system of claim 58 or 59, wherein the fifth electromagnetic energy comprises at least one frequency between 1 kHz and 100 MHz and wherein the sixth electromagnetic energy comprises at least one frequency between 1 MHz and 100 GHz.

61. The system of any one of claims 26-60, further comprising at least one detection unit configured to detect the electronic state of the at least one dopant molecule or the nuclear spin state of the at least one dopant molecule to thereby obtain a result of the at least one non-classical operation.

62. The system of claim 61, wherein the at least one detection unit is configured to apply seventh electromagnetic energy to the at least one dopant molecule to thereby obtain the result of the at least one non-classical operation.

63. The system of claim 61 or 62, wherein the at least one detection unit comprises at least one optical detector configured to detect light emitted by the at least one dopant molecule in response to the seventh electromagnetic energy.

64. The system of claim 63, wherein the light emitted by the at least one dopant molecule has a first optical property associated with the first qubit state and a second optical property associated with the second qubit state, and wherein the first optical property is different from the second optical property.

65. The system of claim 64, wherein the first optical property or the second optical property comprises an intensity, polarization, wavelength, or frequency of the light.

66. The system of any one of claims 26-65, further comprising a cryogenic unit configured to contain the at least one host material and to cool the at least one host material to a temperature of at most 20 K.

67. The system of claim 66, wherein the cryogenic unit comprises a helium cryocooler or a closed-cycle helium cryocooler.
